(19) United States
(12) Patent Application Publication
(10) Pub. No.: US 2025/0301669 A1
(43) Pub. Date: Sep. 25, 2025

(54) SEMICONDUCTOR DEVICE

(71) Applicant: Kioxia Corporation, Tokyo (JP)

(72) Inventors: Takashi TERADA, Yokkaichi (JP); Yuya YOMOGIZAWA, Mie (JP)

(73) Assignee: Kioxia Corporation, Tokyo (JP)

(21) Appl. No.: 19/029,378

(22) Filed: Jan. 17, 2025

(30) Foreign Application Priority Data
Mar. 19, 2024 (JP) 2024-043567

(51) Int. Cl. H10B 80/00; H01L 23/00; H01L 25/065; H01L 25/18

(52) U.S. Cl. CPC H10B 80/00; H01L 24/08; H01L 25/0657; H01L 25/18; H01L 2224/08145; H01L 2924/1431; H01L 2924/14511

(57) ABSTRACT

A semiconductor device includes: a first wafer including die regions; conductive layers provided in a device region on the first wafer, and stacked in a stacking direction; and first layers provided in an edge region on the first wafer and arranged in the stacking direction. First die regions positioned within the device region include respective terrace regions in which a part of the conductive layers are provided. The number of the first layers arranged in the stacking direction at positions within second die regions corresponding to positions at which the first die regions include at least partial region of the terrace regions within a region in which the second die regions overlap with the edge region when viewed in the stacking direction is greater than the number of the conductive layers provided at the positions including the at least partial region of the terrace regions.

### CROSS-REFERENCE TO RELATED APPLICATIONS

This application is based upon and claims the benefit of Japanese Patent Application No. 2024-043567, filed on Mar. 19, 2024, the entire contents of which are incorporated herein by reference.

### BACKGROUND

### Field

Embodiments described herein relate generally to a semiconductor device.

### Description of the Related Art

There has been known a semiconductor device including a plurality of conductive layers and a plurality of insulating layers alternately stacked in a stacking direction, a semiconductor column extending in the stacking direction and opposed to the plurality of conductive layers, and a gate insulating film provided between the plurality of conductive layers and the semiconductor column. The gate insulating film includes a memory portion that is able to store data, and the memory portion is, for example, an insulating electric charge accumulating film of silicon nitride (SiN) or the like or a conductive electric charge accumulating film of a floating gate or the like.

### BRIEF DESCRIPTION OF THE DRAWINGS

FIG. 1 is a schematic perspective view illustrating a configuration of a semiconductor memory device according to a first embodiment;

FIG. 2 is a schematic exploded perspective view illustrating the configuration of the same semiconductor memory device;

FIG. 3 is a schematic bottom view illustrating a part of the configuration of the same semiconductor memory device;

FIG. 4 is a schematic bottom view illustrating a part of the configuration of the same semiconductor memory device;

FIG. 5 is a schematic bottom view illustrating a part of the configuration of the same semiconductor memory device;

FIG. 6 is a schematic bottom view illustrating a part of the configuration of the same semiconductor memory device;

FIG. 7 is a schematic bottom view illustrating a part of the configuration of the same semiconductor memory device;

FIG. 8 is a schematic bottom view illustrating a part of the configuration of the same semiconductor memory device;

FIG. 9 is a schematic cross-sectional view illustrating a part of the configuration of the same semiconductor memory device;

FIG. 10 is a schematic cross-sectional view illustrating a part of the configuration of the same semiconductor memory device;

FIG. 11 is a schematic cross-sectional view illustrating a part of the configuration of the same semiconductor memory device;

FIG. 12 is a schematic cross-sectional view illustrating a part of the configuration of the same semiconductor memory device;

FIG. 13 is a schematic bottom view illustrating a part of the configuration of the same semiconductor memory device;

FIG. 14 is a schematic cross-sectional view illustrating a part of the configuration of the same semiconductor memory device;

FIG. 15 is a schematic cross-sectional view illustrating a part of the configuration of the same semiconductor memory device;

FIG. 16 is a schematic cross-sectional view illustrating a part of the configuration of the same semiconductor memory device;

FIG. 17 is a schematic cross-sectional view illustrating a part of the configuration of the same semiconductor memory device;

FIG. 18 is a schematic cross-sectional view illustrating a part of the configuration of the same semiconductor memory device;

FIG. 19 is a schematic bottom view illustrating a part of the configuration of the same semiconductor memory device;

FIG. 20 is a schematic cross-sectional view illustrating a part of the configuration of the same semiconductor memory device;

FIG. 21 is a schematic cross-sectional view illustrating a part of the configuration of the same semiconductor memory device;

FIG. 22 is a schematic bottom view illustrating a part of the configuration of the same semiconductor memory device;

FIG. 23 is a schematic cross-sectional view illustrating a part of the configuration of the same semiconductor memory device;

FIG. 24 is a schematic cross-sectional view illustrating a part of the configuration of the same semiconductor memory device;

FIG. 25 is a schematic cross-sectional view illustrating a part of the configuration of the same semiconductor memory device;

FIG. 26 is a schematic cross-sectional view illustrating a part of the configuration of the same semiconductor memory device;

FIG. 27 is a schematic cross-sectional view illustrating a part of the configuration of the same semiconductor memory device;

FIG. 28 is a schematic cross-sectional view for describing a method for manufacturing the same semiconductor memory device;

FIG. 29 is a schematic cross-sectional view for describing the same manufacturing method;

FIG. 30 is a schematic cross-sectional view for describing the same manufacturing method;

FIG. 31 is a schematic bottom view for describing the same manufacturing method;

FIG. 32 is a schematic bottom view for describing the same manufacturing method;

FIG. 33 is a schematic cross-sectional view for describing the same manufacturing method;

FIG. 34 is a schematic cross-sectional view for describing the same manufacturing method;

FIG. 35 is a schematic cross-sectional view for describing the same manufacturing method;

FIG. 36 is a schematic cross-sectional view for describing the same manufacturing method;

FIG. 37 is a schematic cross-sectional view for describing the same manufacturing method;

FIG. 38 is a schematic cross-sectional view for describing the same manufacturing method;

FIG. 39 is a schematic cross-sectional view for describing the same manufacturing method;

FIG. 40 is a schematic cross-sectional view for describing the same manufacturing method;

FIG. 41 is a schematic cross-sectional view for describing the same manufacturing method;

FIG. 42 is a schematic cross-sectional view for describing the same manufacturing method;

FIG. 43 is a schematic cross-sectional view for describing the same manufacturing method;

FIG. 44 is a schematic cross-sectional view for describing the same manufacturing method;

FIG. 45 is a schematic cross-sectional view for describing the same manufacturing method;

FIG. 46 is a schematic perspective view for describing the same manufacturing method;

FIG. 47 is a schematic perspective view for describing the same manufacturing method;

FIG. 48 is a schematic cross-sectional view for describing the same manufacturing method;

FIG. 49 is a schematic cross-sectional view for describing the same manufacturing method;

FIG. 50 is a schematic cross-sectional view for describing the same manufacturing method;

FIG. 51 is a schematic cross-sectional view for describing the same manufacturing method;

FIG. 52 is a schematic cross-sectional view for describing the same manufacturing method;

FIG. 53 is a schematic cross-sectional view for describing the same manufacturing method;

FIG. 54 is a schematic cross-sectional view for describing the same manufacturing method;

FIG. 55 is a schematic cross-sectional view for describing the same manufacturing method;

FIG. 56 is a schematic cross-sectional view for describing the same manufacturing method;

FIG. 57 is a schematic cross-sectional view for describing the same manufacturing method;

FIG. 58 is a schematic cross-sectional view for describing the same manufacturing method;

FIG. 59 is a schematic cross-sectional view for describing the same manufacturing method;

FIG. 60 is a schematic cross-sectional view for describing the same manufacturing method;

FIG. 61 is a schematic cross-sectional view for describing the same manufacturing method;

FIG. 62 is a schematic cross-sectional view for describing the same manufacturing method;

FIG. 63 is a schematic cross-sectional view for describing the same manufacturing method;

FIG. 64 is a schematic cross-sectional view for describing the same manufacturing method;

FIG. 65 is a schematic cross-sectional view for describing the same manufacturing method;

FIG. 66 is a schematic cross-sectional view for describing the same manufacturing method;

FIG. 67 is a schematic cross-sectional view for describing the same manufacturing method;

FIG. 68 is a schematic cross-sectional view for describing the same manufacturing method;

FIG. 69 is a schematic cross-sectional view for describing the same manufacturing method;

FIG. 70 is a schematic cross-sectional view for describing the same manufacturing method;

FIG. 71 is a schematic cross-sectional view for describing the same manufacturing method;

FIG. 72 is a schematic cross-sectional view for describing the same manufacturing method;

FIG. 73 is a schematic cross-sectional view for describing a semiconductor memory device according to a comparative example;

FIG. 74 is a schematic cross-sectional view for describing the semiconductor memory device according to the comparative example;

FIG. 75 is a schematic cross-sectional view for describing the semiconductor memory device according to the comparative example;

FIG. 76 is a schematic cross-sectional view for describing the semiconductor memory device according to the comparative example;

FIG. 77 is a schematic cross-sectional view for describing a semiconductor memory device according to the first embodiment;

FIG. 78 is a schematic cross-sectional view for describing the semiconductor memory device according to the first embodiment;

FIG. 79 is a schematic cross-sectional view for describing the semiconductor memory device according to the first embodiment;

FIG. 80 is a schematic cross-sectional view illustrating a part of a configuration of a semiconductor memory device according to a second embodiment;

FIG. 81 is a schematic cross-sectional view illustrating a part of the configuration of the semiconductor memory device according to the second embodiment;

FIG. 82 is a schematic cross-sectional view illustrating a part of the configuration of the semiconductor memory device according to the second embodiment;

FIG. 83 is a schematic cross-sectional view illustrating a part of the configuration of the semiconductor memory device according to the second embodiment;

FIG. 84 is a schematic cross-sectional view illustrating a part of a configuration of a semiconductor memory device according to a third embodiment;

FIG. 85 is a schematic perspective view for describing a manufacturing method according to a fourth embodiment;

FIG. 86 is a schematic cross-sectional view for describing the manufacturing method according to the fourth embodiment;

FIG. 87 is a schematic cross-sectional view illustrating a part of a configuration of a semiconductor memory device according to a fifth embodiment;

FIG. 88 is a schematic cross-sectional view illustrating a part of the configuration of the semiconductor memory device according to the fifth embodiment;

FIG. 89 is a schematic cross-sectional view illustrating a part of the configuration of the semiconductor memory device according to the fifth embodiment; and

FIG. 90 is a schematic cross-sectional view illustrating a part of the configuration of the semiconductor memory device according to the fifth embodiment.

### DETAILED DESCRIPTION

A semiconductor device according to one embodiment comprises: a first wafer including a plurality of die regions arranged in a first direction and a second direction intersecting with the first direction; a plurality of conductive layers and a plurality of insulating layers provided in a device region on the first wafer outside of a predetermined distance range from an outer edge of the first wafer, and alternately stacked in a stacking direction intersecting with the first direction and the second direction; and a plurality of first layers and a plurality of second layers provided in an edge region on the first wafer within the predetermined distance range from the outer edge of the first wafer, the plurality of first layers being arranged in the stacking direction corresponding to the plurality of conductive layers, the plurality of second layers being arranged in the stacking direction corresponding to the plurality of insulating layers. A plurality of first die regions positioned within the device region among the plurality of die regions include respective terrace regions in which a part of the plurality of conductive layers are provided and another part of the plurality of conductive layers are not provided. A first number of the plurality of first layers arranged in the stacking direction at positions within a plurality of second die regions among the plurality of die regions corresponding to positions at which the respective plurality of first die regions include at least partial region of the terrace regions within a region in which the plurality of second die regions overlap with the edge region when viewed in the stacking direction is greater than a second number of the plurality of conductive layers provided at the positions at which the respective plurality of first die regions include the at least partial region of the terrace regions and arranged in the stacking direction.

Next, the semiconductor devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, a direction parallel to a surface of the substrate is referred to as an X-direction, a direction parallel to the surface of the substrate and perpendicular to the X-direction is referred to as a Y-direction, and a direction perpendicular to the surface of the substrate is referred to as a Z-direction.

In this specification, a direction intersecting with a surface of the substrate is referred to as a stacking direction in some cases. A direction along a predetermined plane intersecting with the stacking direction may be referred to as a first direction, and a direction along the plane and intersecting with the first direction may be referred to as a second direction. The stacking direction may correspond to the Z-direction and need not correspond to the Z-direction. The first direction and the second direction may and need not each correspond to any of the X-direction or the Y-direction.

### First Embodiment

### [Overall Configuration]

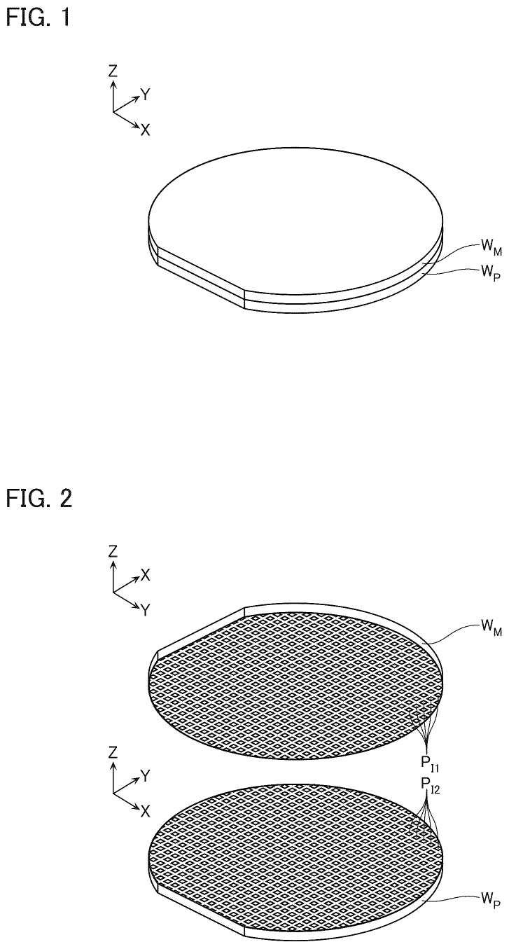

FIG. 1 is a schematic perspective view illustrating a configuration of a semiconductor memory device according to a first embodiment. As illustrated in FIG. 1, the semiconductor memory device according to the embodiment includes a wafer W_{M} and a wafer W_{P}. The wafer W_{M} includes, for example, a memory cell array of a NAND flash memory. The wafer W_{P} includes a peripheral circuit of the NAND flash memory.

Note that, in the following description, a surface of the wafer W_{M} on a side of the wafer W_{P} is referred to as a “lower surface” or a “front surface”, and a surface on a side opposite to the wafer W_{P} is referred to as an “upper surface” or a “back surface”. A surface of the wafer W_{P} on a side of the wafer W_{M} is referred to as an “upper surface” or a “front surface”, and a surface on a side opposite to the wafer W_{M} is referred to as a “lower surface” or a “back surface”.

FIG. 2 is a schematic exploded perspective view illustrating the configuration of the semiconductor memory device according to the embodiment. As illustrated in FIG. 2, the lower surface of the wafer W_{M} is provided with a plurality of bonding electrodes Pr. The upper surface of the wafer W_{P} is provided with a plurality of bonding electrodes P_{I2}. A plurality of configurations in the wafer W_{M} and a plurality of configurations in the wafer W_{P} are electrically connected to one another via the plurality of bonding electrodes P_{I1}, P_{I2}.

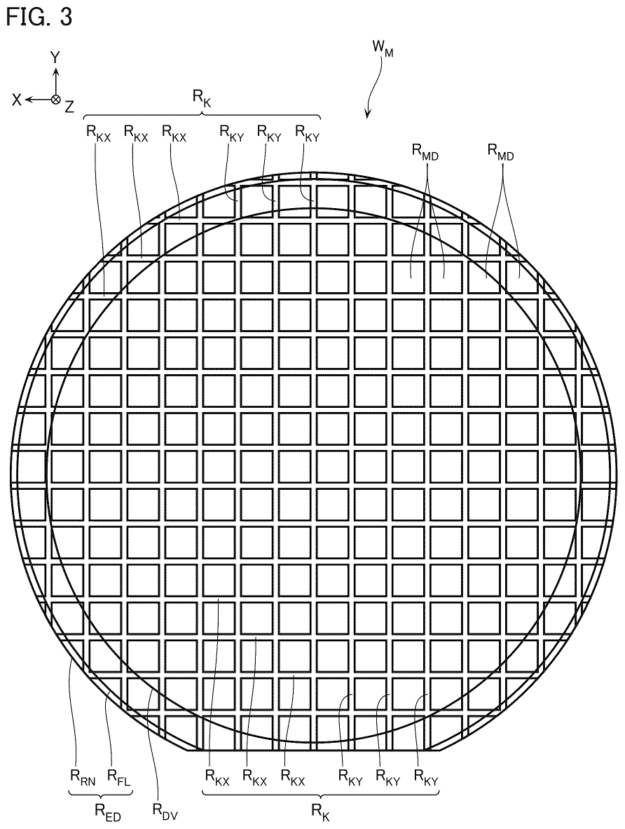

FIG. 3 is a schematic bottom view illustrating a part of the configuration of the semiconductor memory device according to the embodiment and illustrates a configuration of the wafer W_{M}. Note that FIG. 3 omits a part of the configurations, such as the plurality of bonding electrodes P₁ (FIG. 2).

The wafer W_{M} is provided with a plurality of die regions R_{MD} and a kerf region R_{K} provided between these plurality of die regions R_{MD}. The plurality of die regions R_{MD} will be each individualized by dicing. The kerf region R_{K} includes dicing lines. The kerf region R_{K} includes a plurality of kerf regions R_{K}y extending in the Y-direction and arranged in the X-direction, and a plurality of kerf regions Rx extending in the X-direction and arranged in the Y-direction. The configurations in the kerf region R_{K} are not used for inputting/outputting a voltage to/from the memory cell array or inputting/outputting a data signal or another signal to/from the memory cell array.

The wafer W_{M} is provided with a device region R_{DV} and an edge region R_{ED}. The device region R_{DV} is provided outside of a predetermined distance range from an outer edge of the wafer W_{M} (within a predetermined distance range from the center of a circumscribed circle of the wafer W_{M}). The edge region R_{ED} is provided within a predetermined distance range from the outer edge of the wafer W_{M} (outside of the predetermined distance range from the center of the circumscribed circle of the wafer W_{M}). Among the above-described die regions R_{MD}, those provided in the device region R_{DV} will be, after being individualized, mounted on a memory card, a Solid State Drive (SSD), or the like, and function as a device.

The edge region R_{ED} is provided with a flat region R_{FL} and a round region R_{RN}. The flat region R_{FL} is provided outside of another predetermined distance range from the outer edge of the wafer W_{M} (within another predetermined distance range from the center of the circumscribed circle of the wafer W_{M}) in the edge region R_{ED}. The round region R_{RN} is provided within the another predetermined distance range from the outer edge of the wafer W_{M} (outside of the another predetermined distance range from the center of the circumscribed circle of the wafer W_{M}) in the edge region R_{ED}.

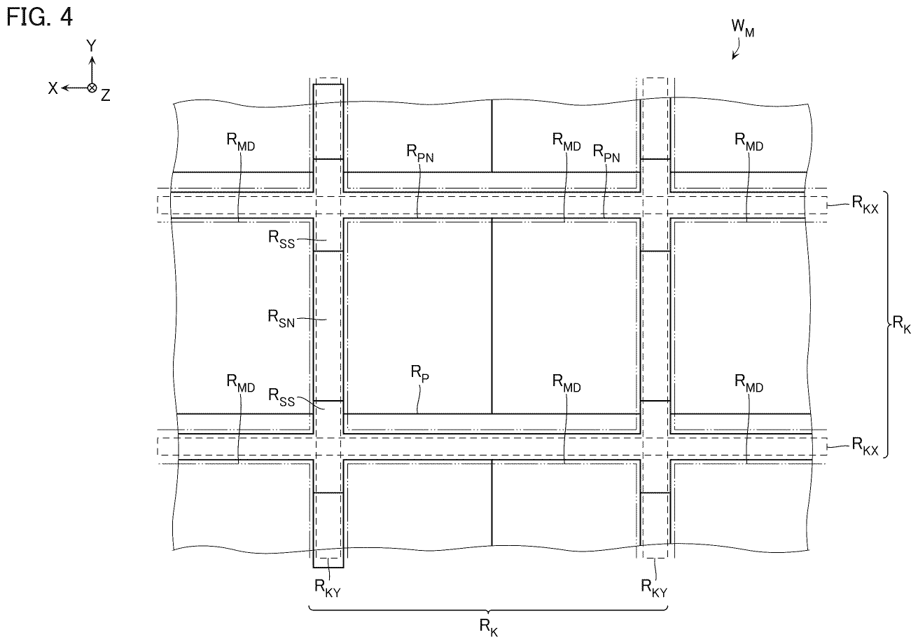

FIG. 4 is a schematic bottom view illustrating a part of the configuration of the semiconductor memory device according to the embodiment and enlarges and illustrates a part of the device region R_{DV} in FIG. 3. As illustrated in FIG. 4, the die region R_{MD} in the device region R_{DV} includes two plane regions R_{PN} arranged in the X-direction and a peripheral circuit region R_{P} provided on one side in the Y-direction with respect to these two plane regions R_{PN}. Note that the configuration in the die region R_{MD} is adjustable as appropriate. For example, the die region R_{MD} may include four plane regions R_{PN} arranged in the X-direction and the Y-direction, or may include four plane regions R_{PN} arranged in the X-direction. Note that the plane regions R_{PN} here are controlled independently from one another by a peripheral circuit, and thus, are allowed to be associated with units of operations that allow respective parallel operations. The kerf region R_{KY} includes two stacked body regions R_{SS} arranged in the Y-direction and a non-stacked body region R_{SN} provided between the two stacked body regions R_{SS}. The stacked body regions R_{SS} and the non-stacked body region R_{SN} are each arranged with a plurality of finger structures FS, which is described later, in the X-direction.

### [Device Region R_{DV}]

[Plane Region R_{PN} in Device Region R_{DV}]

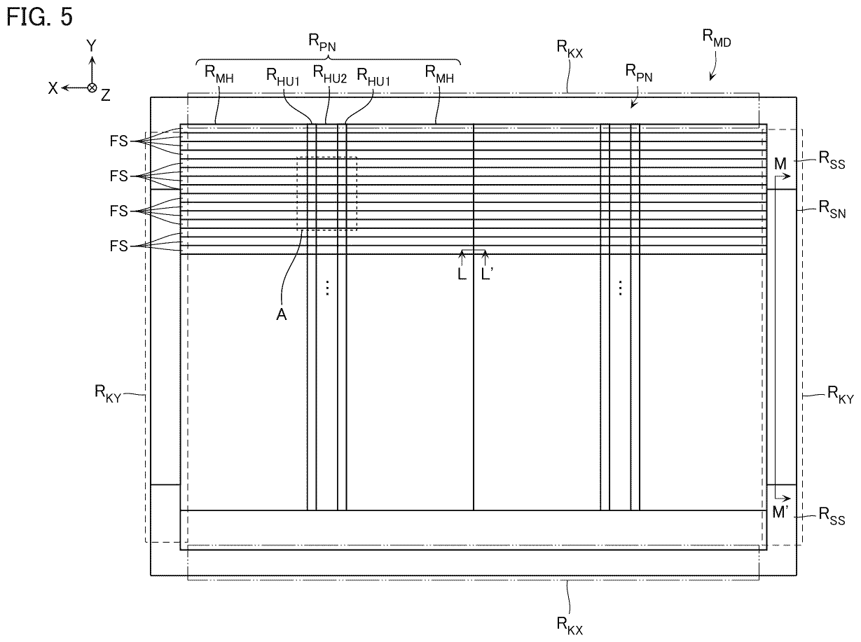

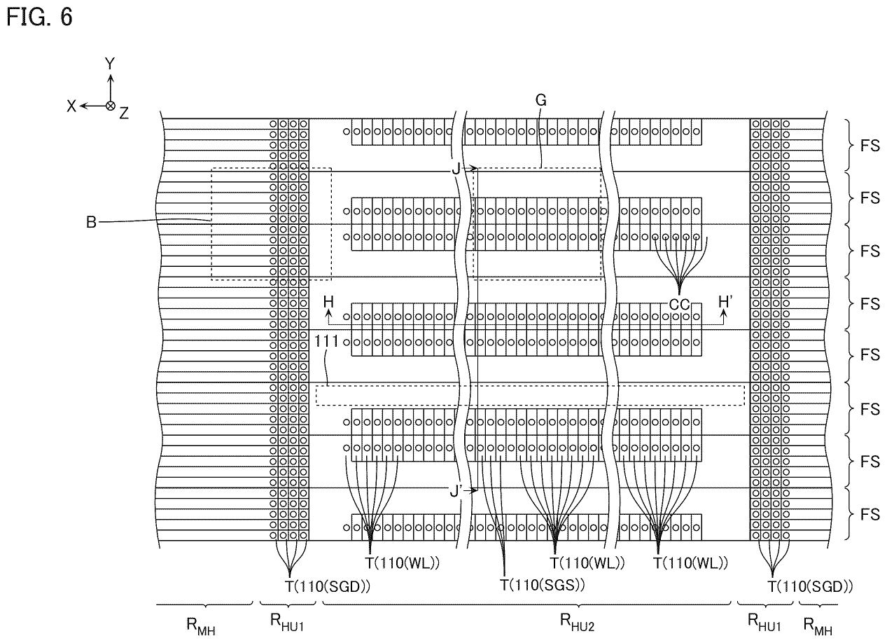

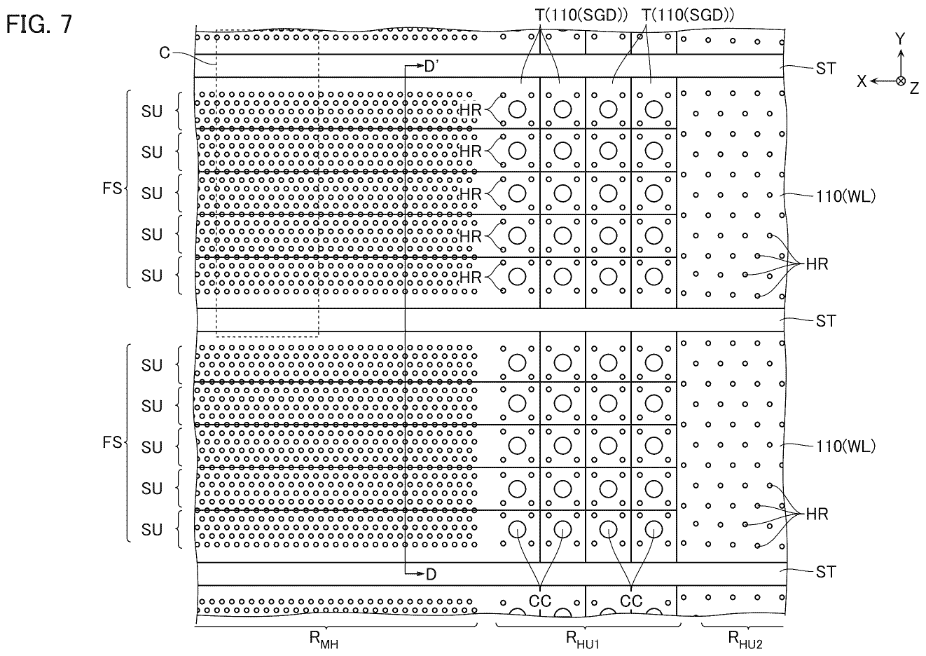

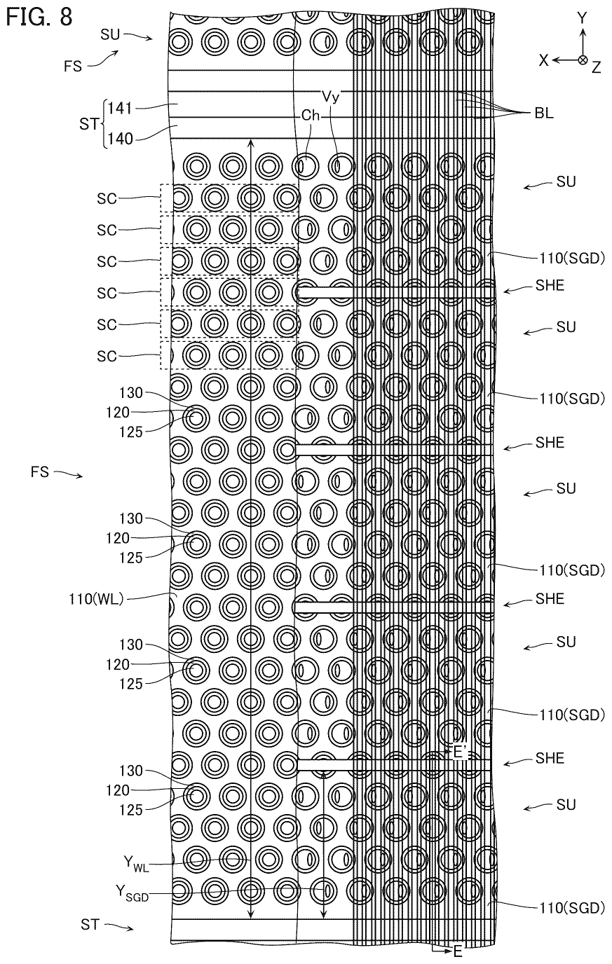

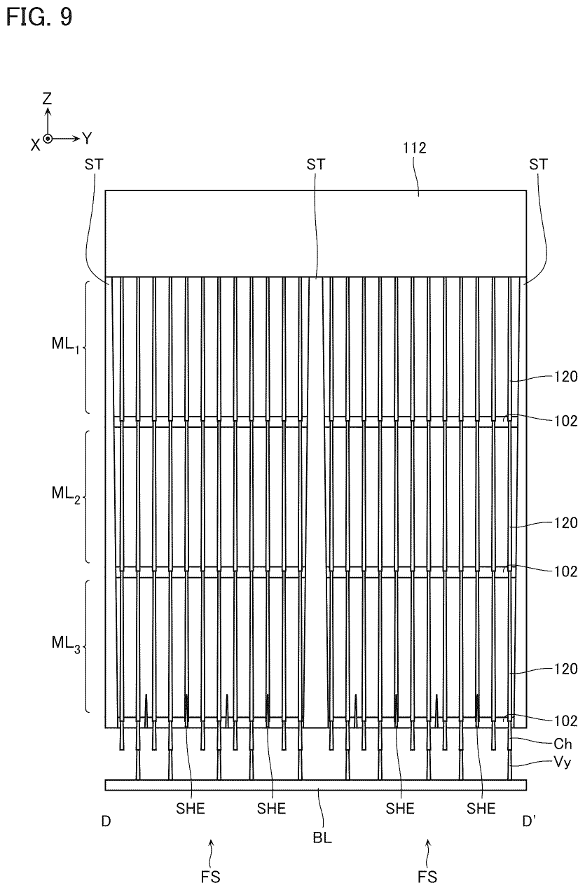

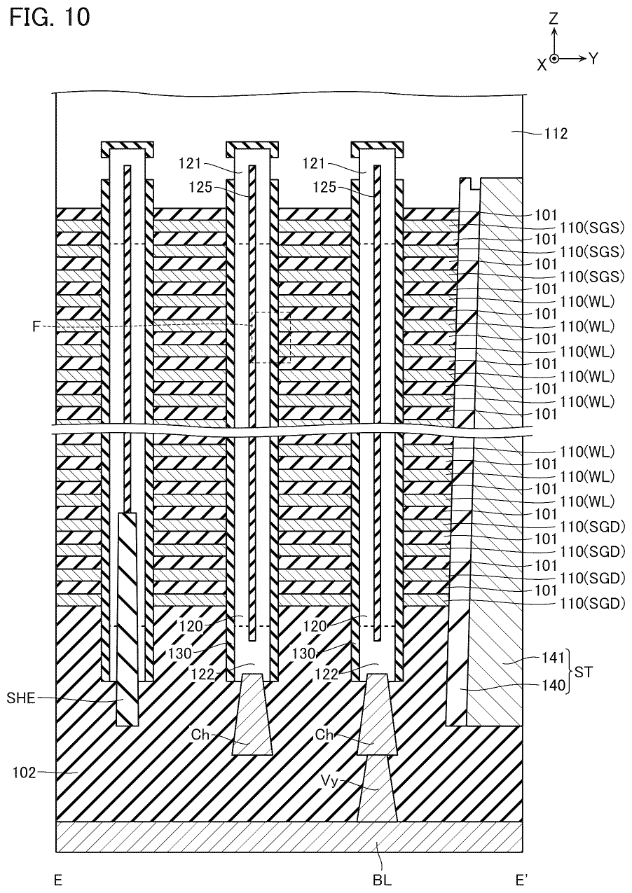

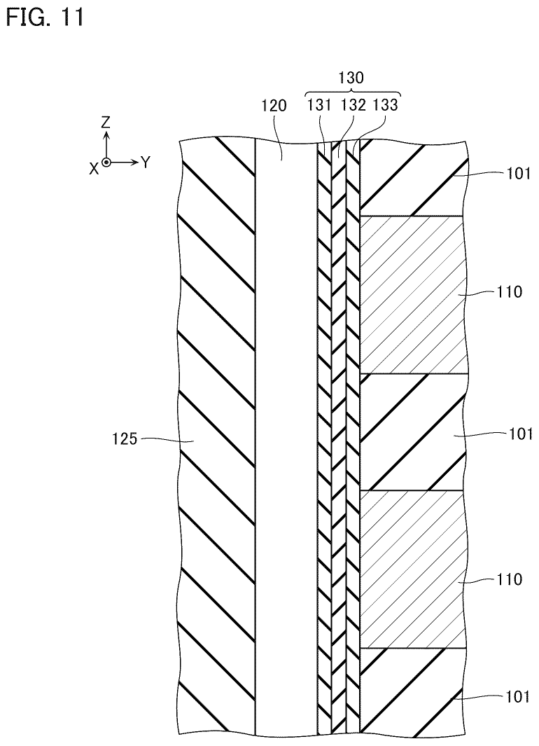

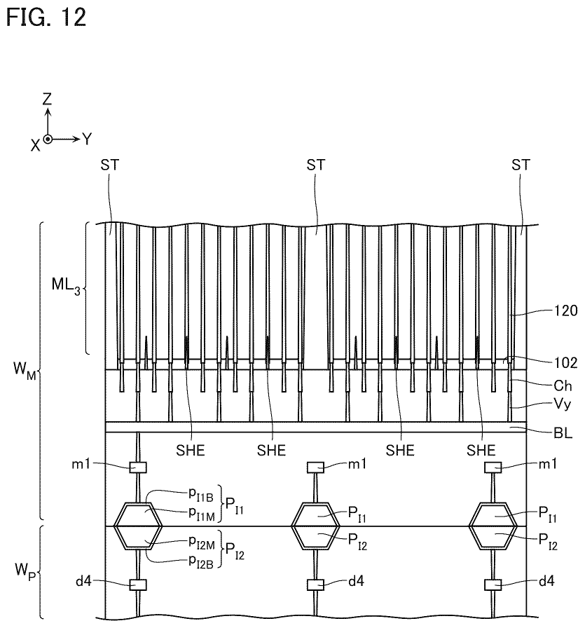

FIG. 5 is a schematic bottom view illustrating a part of the configuration of the semiconductor memory device according to the embodiment, and enlarges and illustrates a part of FIG. 4. FIG. 6 is a schematic bottom view illustrating a part of the configuration of the same semiconductor memory device, and enlarges and illustrates a portion illustrated by A in FIG. 5. FIG. 7 is a schematic bottom view illustrating a part of the configuration of the same semiconductor memory device, and enlarges and illustrates a portion illustrated by B in FIG. 6. FIG. 8 is a schematic bottom view illustrating a part of the configuration of the same semiconductor memory device, and enlarges and illustrates a portion illustrated by C in FIG. 7. Note that a part of FIG. 8 illustrates an XY cross-sectional surface at a height position corresponding to a conductive layer 110 (WL) described later. A part of FIG. 8 illustrates a plane on which bit lines BL, described later, and insulating layers 102, described later, are omitted. A part of FIG. 8 illustrates the bit lines BL described later. FIG. 9 is a schematic cross-sectional view illustrating a part of the configuration of the same semiconductor memory device, and illustrates a cross-sectional surface taking the structure illustrated in FIG. 7 along the line D-D′ and viewed along the direction of the arrow. FIG. 10 is a schematic cross-sectional view illustrating a part of the configuration of the same semiconductor memory device, and illustrates a cross-sectional surface taking the structure illustrated in FIG. 8 along the line E-E′ and viewed along the direction of the arrow. FIG. 11 is a schematic cross-sectional view illustrating a part of the configuration of the same semiconductor memory device, and enlarges and illustrates a portion illustrated by F in FIG. 10. Note that while FIG. 11 illustrates a YZ cross-sectional surface, a structure similar to that in FIG. 11 is observed also when a cross-sectional surface other than the YZ cross-sectional surface (for example, an XZ cross-sectional surface) taken along a central axis of a semiconductor column 120, described later, is observed. FIG. 12 is a schematic cross-sectional view illustrating a part of the configuration of the same semiconductor memory device.

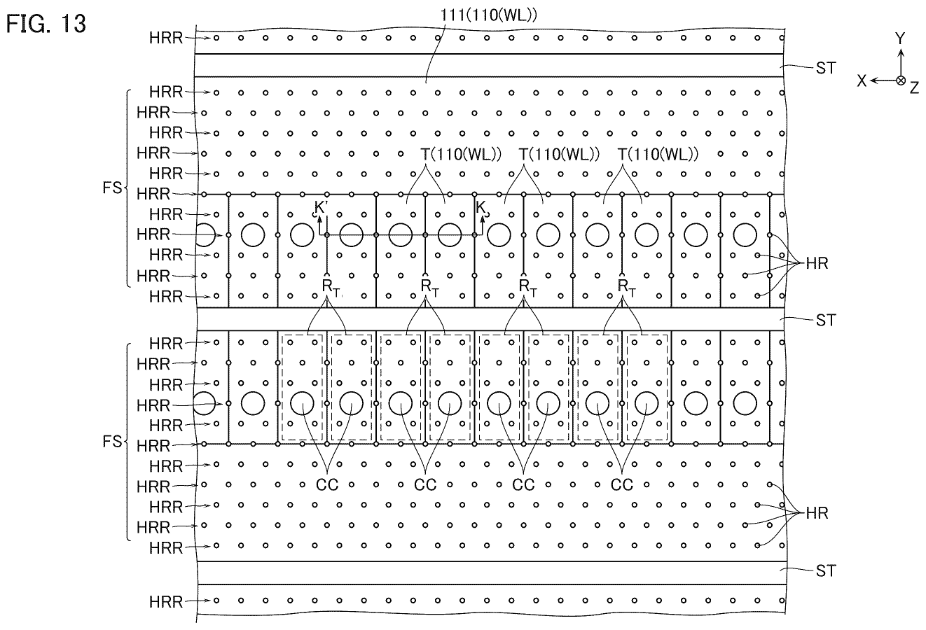

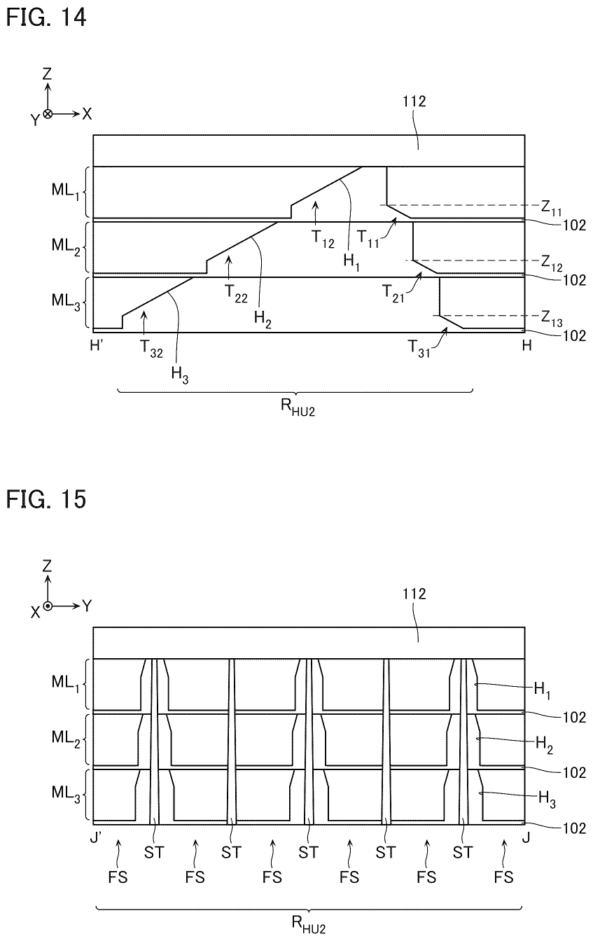

FIG. 13 is a schematic bottom view illustrating a part of the configuration of the same semiconductor memory device, and enlarges and illustrates a portion illustrated by G in FIG. 6. FIG. 14 is a schematic cross-sectional view illustrating a part of the configuration of the same semiconductor memory device, and illustrates a cross-sectional surface taking the structure illustrated in FIG. 6 along the line H-H′ and viewed along the direction of the arrow. FIG. 15 is a schematic cross-sectional view illustrating a part of the configuration of the same semiconductor memory device, and illustrates a cross-sectional surface taking the structure illustrated in FIG. 6 along the line J-J′ and viewed along the direction of the arrow. FIG. 16 is a schematic cross-sectional view illustrating a part of the configuration of the same semiconductor memory device, and illustrates a cross-sectional surface taking the structure illustrated in FIG. 13 along the line K-K′ and viewed along the direction of the arrow.

As illustrated in FIG. 5, the plane region R_{PN} includes two memory regions R_{MH} arranged in the X-direction, two hook-up regions R_{HU1} arranged in the X-direction between these two memory regions R_{MH}, and a hook-up region R_{HU2} provided between these two hook-up regions R_{HU1}. Note that the configuration in the plane region R_{PN} is adjustable as appropriate. For example, the plane region R_{PN} may include only one memory region R_{MH}. The hook-up regions R_{HU1}, R_{HU2} may be provided on one side in the X-direction of the memory region R_{MH} or on both sides in the X-direction.

As illustrated in FIG. 5, the plane region R_{PN} includes the plurality of finger structures FS arranged in the Y-direction. Each of the finger structures FS extends in the X-direction across the two memory regions R_{MH}, the two hook-up regions R_{HU1}, and the hook-up region R_{HU2}. As illustrated in FIG. 7, each of the finger structures FS includes a plurality of string units SU arranged in the Y-direction. An inter-finger structure ST is provided between two finger structures FS adjacent in the Y-direction. As illustrated in FIG. 8, an inter-string unit insulating member SHE of silicon oxide (SiO₂) or the like is provided between two string units SU adjacent in the Y-direction.

In this embodiment, one finger structure FS functions as one memory block. Each of the finger structures FS includes five string units SU arranged in the Y-direction. However, the plurality of finger structures FS may function as one memory block. The finger structure FS may include one to four string units SU or may include six or more string units SU.

[Memory Region R_{MH} in Device Region R_{DV}]

In the memory region R_{MH} in the device region R_{DV}, the finger structure FS includes a plurality (three in the illustrated example) of structures ML₁, ML₂, ML₃ arranged in the Z-direction, for example, as illustrated in FIG. 9. A semiconductor layer 112 is provided above these plurality of structures ML₁, ML₂, ML₃. The plurality of bit lines BL are provided below the plurality of structures ML₁, ML₂, ML₃.

Each of the plurality of structures ML₁, ML₂, ML₃ includes, for example, as illustrated in FIG. 9 and FIG. 10, a plurality of the conductive layers 110 stacked in the Z-direction, a plurality of the semiconductor columns 120 (sub semiconductor columns) extending in the Z-direction, and gate insulating films 130 provided between the plurality of conductive layers 110 and the plurality of semiconductor columns 120.

The conductive layer 110 has an approximately plate shape extending in the X-direction. The conductive layer 110 may include, for example, a stacked film of a barrier conductive film of titanium nitride (TiN) or the like and a metal film of tungsten (W) or the like. For example, the conductive layer 110 may contain polycrystalline silicon containing impurities, such as phosphorus (P) or boron (B), or the like. Between the plurality of conductive layers 110 arranged in the Z-direction, insulating layers 101 of silicon oxide (SiO₂) or the like are disposed. As illustrated in FIG. 9, the insulating layers 102 of silicon oxide (SiO₂) or the like are disposed on respective lower surfaces of lowermost conductive layers 110 in the structures ML₁, ML₂, ML₃.

Among the plurality of conductive layers 110 included in the structure ML₁ (FIG. 9), one or a plurality of conductive layers 110 disposed at uppermost layers function as a select gate line on a source side and gate electrodes of a plurality of select transistors connected to the select gate line of the NAND flash memory. In the following description, such conductive layers 110 are referred to as conductive layers 110 (SGS) (FIG. 10) in some cases.

Among the plurality of conductive layers 110 included in the structure ML₃ (FIG. 9), one or a plurality of conductive layers 110 disposed at lowermost layers function as a select gate line on a drain side and gate electrodes of a plurality of select transistors connected to the select gate line of the NAND flash memory. In the following description, such conductive layers 110 are referred to as conductive layers 110 (SGD) (FIG. 10) in some cases.

The rest of conductive layers 110 included in the structures ML₁, ML₃ (FIG. 9) and the plurality of conductive layers 110 included in the structure ML₂ (FIG. 9) function as word lines and gate electrodes of a plurality of memory cells connected to the word lines of the NAND flash memory. In the following description, such conductive layers 110 are referred to as conductive layers 110 (WL) (FIG. 10) in some cases.

The plurality of conductive layers 110 (SGS) and the plurality of conductive layers 110 (WL) are each electrically independent for each finger structure FS. When two finger structures FS adjacent in the Y-direction are focused on, the one or the plurality of conductive layers 110 (SGS), the plurality of conductive layers 110 (WL), and a plurality of insulating layers 101 disposed on upper surfaces and lower surfaces of the one or the plurality of conductive layers 110 (SGS) and the plurality of conductive layers 110 (WL) in these two finger structures FS are divided in the Y-direction via the inter-finger structure ST.

As illustrated in FIG. 8, the conductive layer 110 (SGD) has a width Y_{SGD} in the Y-direction smaller than a width Y_{WL} of the conductive layer 110 (WL) in the Y-direction.

The plurality of conductive layers 110 (SGD) are each electrically independent for each string unit SU. When two string units SU adjacent in the Y-direction are focused on in each finger structure FS, the one or the plurality of conductive layers 110 (SGD) and a plurality of insulating layers 101 disposed on upper surfaces and lower surfaces of the one or the plurality of conductive layers 110 (SGD) in these two string units SU are divided in the Y-direction via the inter-string unit insulating member SHE. In the two finger structures FS adjacent in the Y-direction, when one closest to one finger structure FS among a plurality of string units SU included in the other finger structure FS and one closest to the other finger structure FS among a plurality of string units SU included in the one finger structure FS are focused on, the one or the plurality of conductive layers 110 (SGD) and a plurality of insulating layers 101 disposed on upper surfaces and lower surfaces of the one or the plurality of conductive layers 110 (SGD) in these two string units SU are divided in the Y-direction via the inter-finger structure ST.

For example, as illustrated in FIG. 8, the semiconductor columns 120 are arranged in the X-direction and the Y-direction in a predetermined pattern. For example, the finger structure FS includes 24 semiconductor column rows SC disposed from one side in the Y-direction toward the other side in the Y-direction. Each of these 24 semiconductor column rows SC includes the plurality of semiconductor columns 120 arranged in the X-direction.

The semiconductor column 120 contains, for example, polycrystalline silicon (Si). For example, as illustrated in FIG. 10, the semiconductor column 120 has an approximately cylindrical shape, and an insulating column 125 of silicon oxide (SiO₂) or the like is provided in a center portion of the semiconductor column 120. The semiconductor columns 120 function as channel regions of the memory cells and the select transistors.

The semiconductor column 120 included in the structure ML₁ includes an upper end portion provided with an impurity region 121 (FIG. 10). The semiconductor column 120 included in the structure ML₁ includes a lower end portion continuous with an upper end portion of the semiconductor column 120 included in the structure ML₂. The semiconductor column 120 included in the structure ML₂ includes a lower end portion continuous with an upper end portion of the semiconductor column 120 included in the structure ML₃. The semiconductor column 120 included in the structure ML₃ includes a lower end portion provided with an impurity region 122 (FIG. 10).

An outer diameter and a cross-sectional area of the lower end portion of the semiconductor column 120 included in the structure ML₁ is larger than an outer diameter and a cross-sectional area of the upper end portion of the semiconductor column 120 included in the structure ML₂. An outer diameter and a cross-sectional area of the lower end portion of the semiconductor column 120 included in the structure ML₂ is larger than an outer diameter and a cross-sectional area of the upper end portion of the semiconductor column 120 included in the structure ML₃.

The impurity region 121 contains N-type impurities, such as phosphorus (P). The impurity region 121 has an approximately cylindrical shape. The impurity region 121 is connected to the semiconductor layer 112.

The impurity region 122 contains N-type impurities, such as phosphorus (P). The impurity region 122 has an approximately columnar shape. The impurity region 122 is connected to a via-contact electrode Ch. The semiconductor column 120 is electrically connected to the bit lines BL via via-contact electrodes Ch, Vy.

The gate insulating film 130 has an approximately cylindrical shape that covers an outer peripheral surface of the semiconductor column 120. For example, as illustrated in FIG. 11, the gate insulating film 130 includes a tunnel insulating film 131, an electric charge accumulating film 132, and a block insulating film 133 stacked between the semiconductor column 120 and the conductive layers 110. The tunnel insulating film 131 and the block insulating film 133 contain, for example, silicon oxide (SiO₂). The electric charge accumulating film 132, for example, includes a film of silicon nitride (SiN) or the like that allows accumulation of electric charge. The tunnel insulating film 131, the electric charge accumulating film 132, and the block insulating film 133 have approximately cylindrical shapes, and for example, as illustrated in FIG. 10, extend in the Z-direction along an outer peripheral surface of the semiconductor column 120 excluding a contact portion of the semiconductor column 120 with the semiconductor layer 112.

FIG. 11 illustrates an example of the gate insulating film 130 including the electric charge accumulating film 132 of silicon nitride or the like. However, the electric charge accumulating film included in the gate insulating film 130 may be, for example, floating gates of polycrystalline silicon or the like containing N-type or P-type impurities.

The semiconductor layer 112 (FIG. 10) may contain, for example, polycrystalline silicon or the like containing N-type impurities, such as phosphorus (P). At an upper surface of the semiconductor layer 112, a conductive member of a metal, such as tungsten (W), tungsten silicide, or the like, or another conductive member may be disposed. The semiconductor layer 112 functions as a part of a source line of the NAND flash memory.

For example, as illustrated in FIG. 8 to FIG. 10, the inter-string unit insulating member SHE extends in the X-direction and the Z-direction. The inter-string unit insulating member SHE contains, for example, silicon oxide (SiO₂). The inter-string unit insulating member SHE has an upper end positioned below an upper surface of the conductive layer 110 (WL) positioned at the lowermost layer. The upper end of the inter-string unit insulating member SHE is positioned above an upper surface of the conductive layer 110 (SGD) positioned at the uppermost layer. The inter-string unit insulating member SHE has a lower end positioned below a lower surface of the conductive layer 110 (SGD) positioned at the lowermost layer.

For example, as illustrated in FIG. 8 to FIG. 10, the inter-finger structure ST extends in the X-direction and the Z-direction. The inter-finger structure ST includes an inter-finger insulating member 140 extending in the X-direction and the Z-direction, and an inter-finger electrode 141 disposed inside the inter-finger insulating member 140. The inter-finger insulating member 140 contains silicon oxide (SiO₂) or the like. The inter-finger electrode 141 is spaced from the plurality of conductive layers 110 arranged in the Z-direction, the plurality of insulating layers 101 disposed between the plurality of conductive layers 110, and the insulating layer 102 in the Y-direction via the inter-finger insulating member 140. Upper ends of the inter-finger insulating member 140 and the inter-finger electrode 141 are connected to the semiconductor layer 112. The inter-finger electrode 141 may be a conductive member including, for example, a stacked film of a barrier conductive film of titanium nitride (TiN) or the like and a metal film of tungsten (W) or the like. The inter-finger electrode 141 may be, for example, a semiconductor member of polycrystalline silicon containing impurities, such as phosphorus (P) or boron (B). The inter-finger electrode 141 may contain both the conductive member and the semiconductor member. The inter-finger electrode 141 functions as a part of the source line of the NAND flash memory.

For example, as illustrated in FIG. 8, the via-contact electrodes Ch are arranged in the X-direction and the Y-direction in a predetermined pattern corresponding to the semiconductor columns 120. As illustrated in FIG. 10, the via-contact electrode Ch extends in the Z-direction, has an upper end connected to the impurity region 122 of the semiconductor column 120, and has a lower end connected to the via-contact electrode Vy.

As illustrated in FIG. 8, the bit lines BL extend in the Y-direction, and are arranged in the X-direction. The bit lines BL are arranged in the X-direction at pitches a quarter of pitches in the X-direction of the plurality of semiconductor columns 120 arranged in the X-direction. The bit line BL may include, for example, a stacked film of a barrier conductive film of titanium nitride (TiN) or the like and a metal film of copper (Cu) or the like. The via-contact electrodes Vy described above are disposed at positions at which the bit lines BL overlap with the via-contact electrodes Ch when viewed in the Z-direction.

As illustrated in FIG. 12, the plurality of bit lines BL are electrically connected to respective configurations, such as the transistors, which are not illustrated, in the wafer W_{P} via a plurality of wirings m1 provided below the plurality of bit lines BL, the plurality of bonding electrodes P_{I1} provided below the plurality of wirings m1, the plurality of bonding electrodes P_{I2} provided below the plurality of bonding electrodes P_{I1}, a plurality of wirings d4 provided below the plurality of bonding electrodes P_{I2} and the like.

The plurality of wirings m1, d4 may include, for example, a stacked film or the like including a barrier conductive film, such as titanium nitride (TiN), and a metal film, such as tungsten (W) or copper (Cu).

The plurality of bonding electrodes P_{I1} may include, for example, a stacked film or the like of a barrier conductive film p_{I1B}, such as titanium nitride (TiN), and a metal film p_{I1M}, such as copper (Cu). The plurality of bonding electrodes P_{I2} may include, for example, a stacked film or the like of a barrier conductive film p_{I2B}, such as titanium nitride (TiN), and a metal film p_{I2M}, such as copper (Cu).

Here, when the metal films p_{I1M}, P_{I2M} of, for example, copper (Cu) are used for the bonding electrode P_{I1} and the bonding electrode P_{I2}, the metal film p_{I1M} and the metal film p_{I2M} are integrated, making it difficult to confirm a mutual boundary. However, a bonding structure can be confirmed by distortion of a shape of the bonding electrode P_{I1} bonded to the bonding electrode P_{I2} due to misalignment of the bonding and by the misalignment of the barrier conductive films p_{I1B}, p_{I2B} (generation of discontinuous sections on side surfaces). When the bonding electrode P_{I1} and the bonding electrode P_{I2} are formed by damascene method, the respective side surfaces have tapered shapes. In view of this, a shape of a cross-sectional surface along the Z-direction in a part where the bonding electrode P_{I1} and the bonding electrode P_{I2} are bonded is a non-rectangular shape without sidewalls becoming linear. In addition, when the bonding electrode P_{I1} and the bonding electrode P_{I2} are bonded, a structure is provided in which a barrier metal covers a bottom surface, side surfaces, and an upper surface of each Cu forming the bonding electrode P_{I1} and the bonding electrode P_{I2}. In contrast to this, in a general wiring layer using Cu, an insulating layer (for example, SiN or SiCN) having an oxidation prevention function of Cu is disposed on an upper surface of the Cu, and a barrier metal is not disposed. In view of this, even when misalignment of bonding is not generated, distinction from a general wiring layer is possible.

Note that the configurations of the bonding electrodes P_{I1}, P_{I2}, and the like are formed not only in the memory region R_{MH}, but also in the hook-up regions R_{HU1}, R_{HU2}. The configurations of the bonding electrodes P_{I1}, P_{I2}, and the like are formed not only in the device region R_{DV} but also in the edge region R_{ED}.

[Hook-Up Region R_{HU1} in Device Region R_{DV}]

As illustrated in FIG. 7, in the hook-up region R_{HU1} in the device region R_{DV}, a plurality of terrace portions T corresponding to the plurality of conductive layers 110 (SGD) are disposed. For example, the terrace portions T are portions of the lower surfaces of the conductive layers 110 not overlapping with the other conductive layers 110 when viewed from below. The terrace portions T of the conductive layers 110 (SGD) are disposed at end portions of the conductive layers 110 (SGD) in the X-direction. In the example of FIG. 7, four terrace portions T corresponding to the first to the fourth conductive layers 110 (SGD) counting from below are arranged in the X-direction from a memory region R_{MH} side to a hook-up region R_{HU2} side. These plurality of terrace portions T are covered with the above-described insulating layer 102.

In the hook-up region R_{HU1}, a plurality of via-contact electrodes CC are disposed correspondingly to the plurality of terrace portions T. The via-contact electrode CC may include, for example, a stacked film including a barrier conductive film of titanium nitride (TiN) or the like and a metal film of tungsten (W) or the like. The via-contact electrode CC penetrates the insulating layer 102 and extends in the Z-direction, and has an upper end connected to the terrace portion T of the conductive layer 110.

In the hook-up region R_{HU1}, a plurality of supporting insulating members HR are disposed. The supporting insulating member HR contains, for example, silicon oxide (SiO₂). The supporting insulating member HR penetrates the plurality of conductive layers 110 and insulating layers 101 and extends in the Z-direction. Each of outer peripheral surfaces of the supporting insulating members HR are surrounded by a through-hole provided at the conductive layers 110. In the example of FIG. 7, supporting insulating members HR are disposed at each of four corners of each terrace portion T.

[Hook-Up Region R_{HU2} in Device Region R_{DV}]

In the hook-up region R_{HU2}, as illustrated in FIG. 6, a plurality of terrace portions T corresponding to the plurality of conductive layers 110 (WL) and the one or plurality of conductive layers 110 (SGS), and a connecting portion 111 connecting the conductive layers 110 between two memory regions R_{MH} arranged in the X-direction are disposed. The connecting portion 111 extends from one end to the other end of the hook-up region R_{HU2} in the X-direction. Portions of the plurality of conductive layers 110 (WL) and the one or plurality of conductive layers 110 (SGS) provided in the memory region R_{MH} at one side in the X-direction, opposed to the outer peripheral surface of the semiconductor column 120, and functioning as gate electrodes of the memory cells or the like (hereinafter sometimes referred to as “electrode portions”) are continuous with portions provided in the memory region R_{MH} at the other side in the X-direction (electrode portions) via the connecting portion 111. These plurality of terrace portions T and the connecting portion 111 are covered with the above-described insulating layer 102.

In the example in FIG. 14, a plurality of terrace portions T corresponding to those provided below a height position Z₁₁ among the plurality of conductive layers 110 included in the structure ML₁ (hereinafter sometimes referred to as “terrace portions T₁₁”) have, for example, those provided in a positive side in the X-direction corresponding to the conductive layers 110 in the lower side and those provided in a negative side in the X-direction corresponding to the conductive layers 110 in the upper side. A plurality of terrace portions T corresponding to those provided above the height position Z₁₁ among the plurality of conductive layers 110 included in the structure ML₁ (hereinafter sometimes referred to as “terrace portions T₁₂”) have, for example, those provided in the negative side in the X-direction corresponding to the conductive layers 110 in the lower side and those provided in the positive side in the X-direction corresponding to the conductive layers 110 in the upper side.

In the illustrated example, the structure ML₁ is provided with a hole portion H₁ that penetrates the stacked structure formed of the plurality of conductive layers 110 and the plurality of insulating layers 101. A part of the hole portion H₁ is configured of the terrace portions T₁₁, T₁₂. The hole portion H₁ has a width in the X-direction increasing towards the portion provided in the lower side. The hole portion H₁ is filled with a part of the insulating layer 102. Accordingly, the insulating layer 102 in the structure ML₁ is in contact with the semiconductor layer 112.

A plurality of terrace portions T corresponding to those provided below a height position Z₁₂ among the plurality of conductive layers 110 included in the structure ML₂ (hereinafter sometimes referred to as “terrace portions T₂₁”) have, for example, those provided in the positive side in the X-direction corresponding to the conductive layers 110 in the lower side and those provided in the negative side in the X-direction corresponding to the conductive layers 110 in the upper side. A plurality of terrace portions T corresponding to those provided above the height position Z₁₂ among the plurality of conductive layers 110 included in the structure ML₂ (hereinafter sometimes referred to as “terrace portions T₂₂”) have, for example, those provided in the negative side in the X-direction corresponding to the conductive layers 110 in the lower side and those provided in the positive side in the X-direction corresponding to the conductive layers 110 in the upper side.

In the illustrated example, the structure ML₂ is provided with a hole portion H₂ that penetrates the stacked structure formed of the plurality of conductive layers 110 and the plurality of insulating layers 101. A part of the hole portion H₂ is configured of the terrace portions T₂₁, T₂₂. The hole portion H₂ has a width in the X-direction increasing towards the portion provided in the lower side. The hole portion H₂ is filled with a part of the insulating layer 102. Accordingly, the insulating layer 102 in the structure ML₂ is in contact with the insulating layer 102 in the structure ML₁.

A plurality of terrace portions T corresponding to those provided below a height position Z₁₃ among the plurality of conductive layers 110 (WL) included in the structure ML₃ (hereinafter sometimes referred to as “terrace portions T₃₁”) have, for example, those provided in the positive side in the X-direction corresponding to the conductive layers 110 (WL) in the lower side and those provided in the negative side in the X-direction corresponding to the conductive layers 110 (WL) in the upper side. A plurality of terrace portions T corresponding to those provided above the height position Z₁₃ among the plurality of conductive layers 110 (WL) included in the structure ML₃ (hereinafter sometimes referred to as “terrace portions T₃₂”) have, for example, those provided in the negative side in the X-direction corresponding to the conductive layers 110 (WL) in the lower side and those provided in the positive side in the X-direction corresponding to the conductive layers 110 (WL) in the upper side.

In the illustrated example, the structure ML₃ is provided with a hole portion H₃ that penetrates the stacked structure formed of the plurality of conductive layers 110 (WL) and the plurality of insulating layers 101. A part of the hole portion H₃ is configured of the terrace portions T₃₁, T₃₂. The hole portion H₃ has a width in the X-direction increasing towards the portion provided in the lower side. The hole portion H₃ is filled with a part of the insulating layer 102. Accordingly, the insulating layer 102 in the structure ML₃ is in contact with the insulating layer 102 in the structure ML₂.

The hook-up region R_{HU2} is provided with the plurality of via-contact electrodes CC corresponding to the plurality of terrace portions T. As exemplarily illustrated in FIG. 16, the via-contact electrode CC penetrates the insulating layer 102 and extends in the Z-direction, and has an upper end connected to the terrace portion T of the conductive layer 110.

The hook-up region R_{HU2} is provided with the plurality of supporting insulating members HR. As exemplarily illustrated in FIG. 16, the supporting insulating member HR penetrates the plurality of conductive layers 110 and insulating layers 101 and extends in the Z-direction. For example, as illustrated in FIG. 13, the supporting insulating members HR are arranged in the X-direction and the Y-direction in a predetermined pattern. For example, the finger structure FS includes eleven supporting insulating member rows HRR provided from one side in the Y-direction to the other side in the Y-direction. Each of these eleven supporting insulating member rows HRR includes the plurality of supporting insulating members HR arranged in the X-direction.

[Between Plane Regions R_{PN} in Device Region R_{DV}]

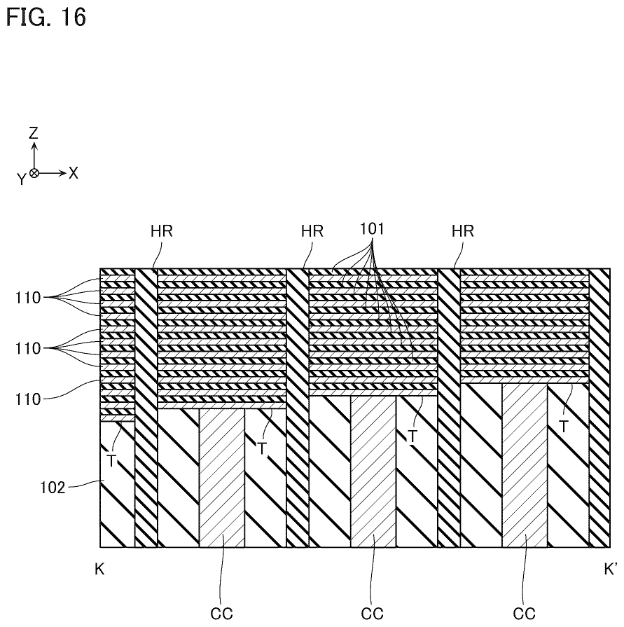

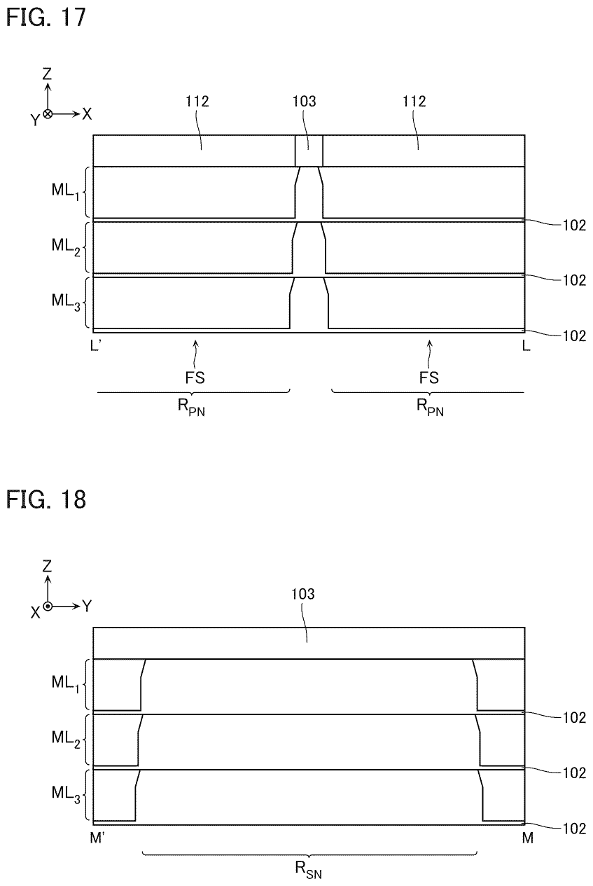

FIG. 17 is a schematic cross-sectional view illustrating a part of the configuration of the semiconductor memory device according to the embodiment, and illustrates a cross-sectional surface taking the configuration illustrated in FIG. 5 along the line L-L′ and viewed along the direction of the arrow.

As illustrated in FIG. 17, the plane region R_{PN} includes an end portion in the X-direction provided with an end portion in the X-direction of the finger structure FS and an end portion in the X-direction of the semiconductor layer 112. A part of the insulating layer 102 is provided between two finger structures FS arranged in the X-direction. An insulating layer 103 is provided between two semiconductor layers 112 arranged in the X-direction.

[Kerf Region R_{K} in Device Region R_{DV}]

As described with reference to FIG. 4, the kerf region R_{KY} includes the stacked body region R_{SS} and the non-stacked body region R_{SN}.

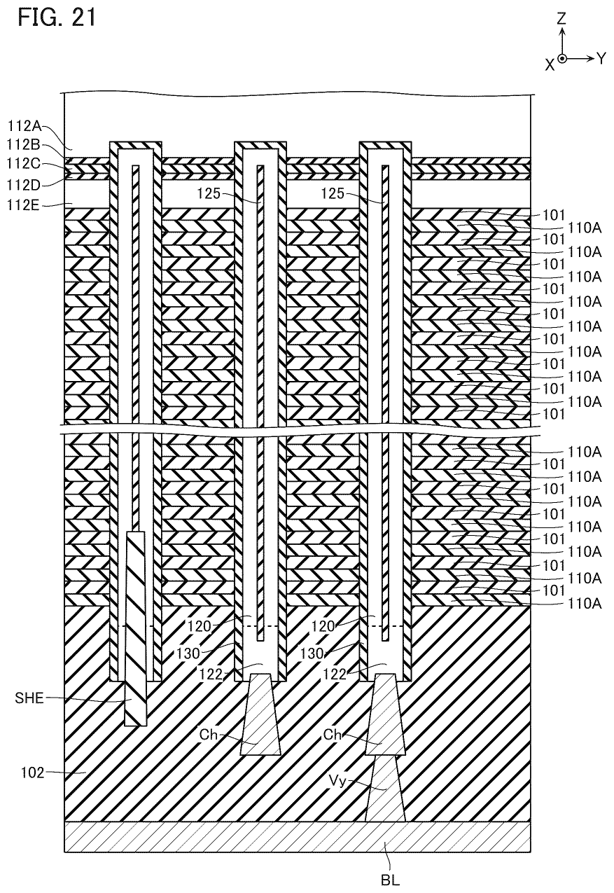

A part of the stacked body region R_{SS} is provided with the plurality of conductive layers 110 and the plurality of insulating layers 101 alternately stacked in the Z-direction, for example, as described with reference to FIG. 10. A part of the stacked body region R_{SS} is provided with a plurality of insulating layers 110A and the plurality of insulating layers 101 alternately stacked in the Z-direction, for example, as is described later with reference to FIG. 21.

FIG. 18 is a schematic cross-sectional view illustrating a part of the configuration of the semiconductor memory device according to the embodiment, and illustrates a cross-sectional surface taking the configuration illustrated in FIG. 5 along the line M-M′ and viewed along the direction of the arrow. As illustrated in FIG. 18, the non-stacked body region R_{SN} is not provided with the plurality of conductive layers 110, the plurality of insulating layers 110A, or the plurality of insulating layers 101. In the non-stacked body region R_{SN}, the insulating layers 102 are provided at height positions corresponding to the structures ML₁, ML₂, ML₃. The insulating layer 103 is provided at a height position corresponding to the semiconductor layer 112.

### [Edge Region R_{ED}]

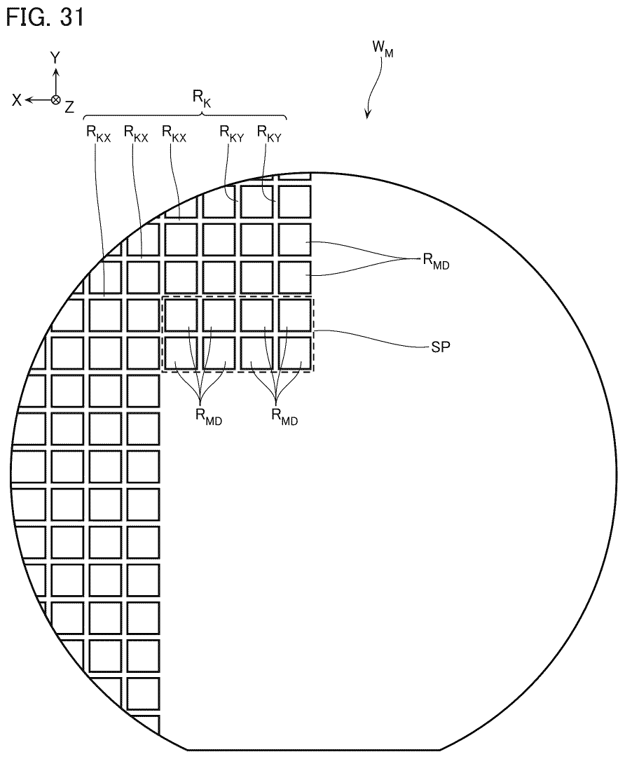

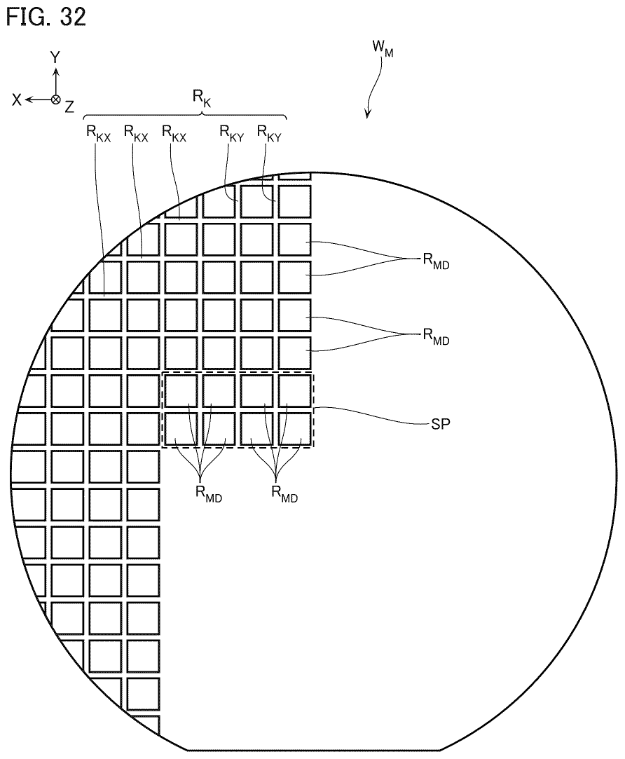

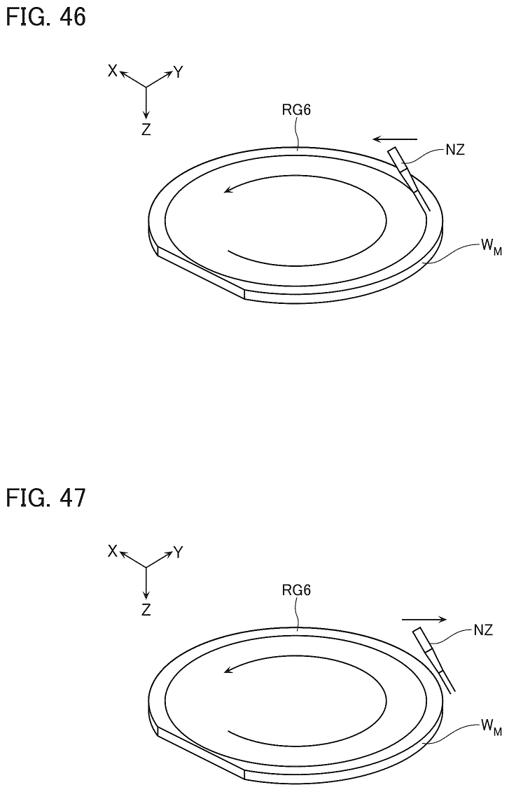

As is described later with reference to FIG. 31 and FIG. 32, common patterns are transferred onto the device region R_{DV} and the edge region R_{ED} described with reference to FIG. 3 in a lithography process. Accordingly, the die regions R_{MD} and the kerf region R_{K} in the edge region R_{ED} include structures similar to those of the die regions R_{MD} and the kerf region R_{K} in the device region R_{DV}. However, as is described later with reference to FIG. 46 and FIG. 47, a part of etching processes is executed with the edge region R_{ED} being protected by a resist RG6. In view of this, the die regions R_{MD} and the kerf region R_{K} in the edge region R_{ED} include configurations different from those of the die regions R_{MD} and the kerf region R_{K} in the device region R_{DV}.

Hereinafter, configurations in the edge region R_{ED} that are different from those in the device region R_{DV} are described.

[Memory Region R_{MH} in Edge Region R_{ED} (Flat Region R_{FL})]

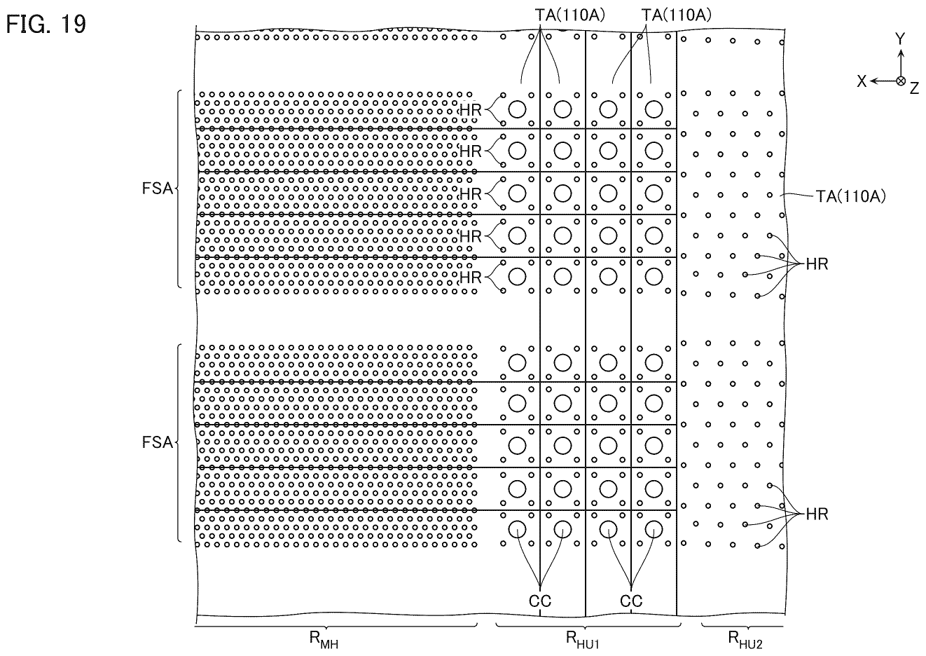

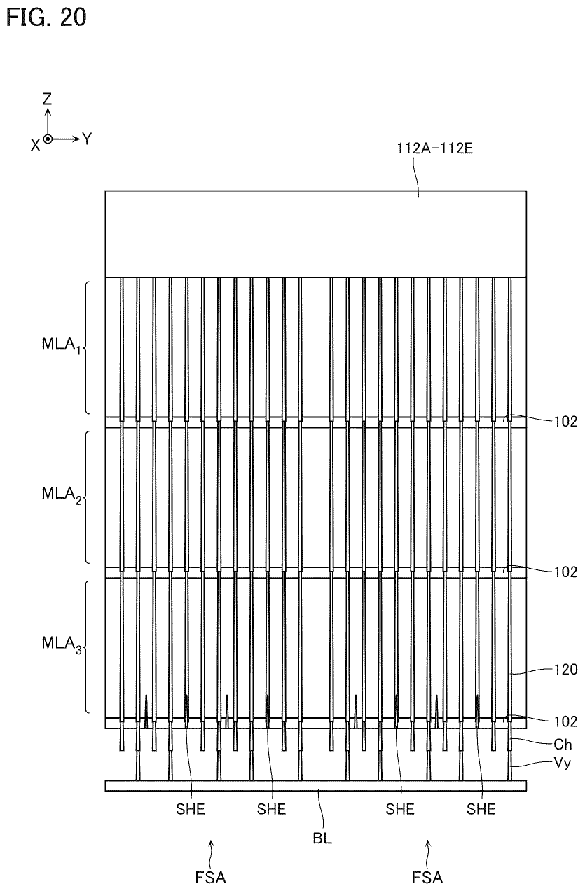

FIG. 19 is a schematic bottom view illustrating a part of the configuration of the semiconductor memory device according to the embodiment. A position in the die region R_{MD} in the edge region R_{ED} of the configuration illustrated in FIG. 19 corresponds to the position in the die region R_{MD} in the device region R_{DV} of the configuration illustrated in FIG. 7. FIG. 20 is a schematic cross-sectional view illustrating a part of the configuration of the semiconductor memory device according to the embodiment. A position in the die region R_{MD} in the edge region R_{ED} of the configuration illustrated in FIG. 20 corresponds to the position in the die region R_{MD} in the device region R_{DV} of the configuration illustrated in FIG. 9. FIG. 21 is a schematic cross-sectional view illustrating a part of the configuration of the semiconductor memory device according to the embodiment. A position in the die region R_{MD} in the edge region R_{ED} of the configuration illustrated in FIG. 21 correspond to the position in the die region R_{MD} in the device region R_{DV} of the configuration illustrated in FIG. 10.

As illustrated in FIG. 19, structures FSA are provided at the positions corresponding to the finger structures FS in the edge region R_{ED}. No inter-finger structure ST is provided in the edge region R_{ED}.

For example, as illustrated in FIG. 20, the structure FSA includes a plurality (three in the illustrated example) of structures MLA₁, MLA₂, MLA₃ arranged in the Z-direction. As illustrated in FIG. 21, above these plurality of structures MLA₁, MLA₂, MLA₃, a semiconductor layer 112A of silicon or the like, an insulating layer 112B of silicon oxide or the like, an insulating layer 112C of silicon nitride (SiN) or the like, an insulating layer 112D of silicon oxide or the like, and a semiconductor layer 112E of silicon or the like are provided in the order from the upper side to the lower side. As illustrated in FIG. 20, the plurality of bit lines BL are provided below the plurality of the structures MLA₁, MLA₂, MLA₃.

For example, as illustrated in FIG. 21, each of the plurality of structures MLA₁, MLA₂, MLA₃ includes a plurality of insulating layers 110A stacked in the Z-direction, a plurality of semiconductor columns 120 extending in the Z-direction, and the gate insulating films 130 provided between the plurality of insulating layers 110A and the plurality of semiconductor columns 120.

The insulating layer 110A has an approximately plate shape extending in the X-direction. The insulating layer 110A may contain, for example, silicon nitride (SiN). The number of the plurality of insulating layers 110A arranged in the Z-direction in the structure FSA is equal to the number of the plurality of conductive layers 110 arranged in the Z-direction in the finger structure FS. The insulating layers 101 of silicon oxide (SiO₂) or the like are provided between the plurality of insulating layers 110A arranged in the Z-direction. As illustrated in FIG. 20, the insulating layers 102 of silicon oxide (SiO₂) or the like are provided on respective lower surfaces of lowermost insulating layers 110A in the structures MLA₁, MLA₂, MLA₃.

Here, as described above, no inter-finger structure ST is provided in the edge region R_{ED}. Accordingly, those provided at the height positions corresponding to the conductive layers 110 (WL) and those provided at height positions corresponding to the conductive layers 110 (SGS) among the plurality of insulating layers 110A continue in the X-direction and the Y-direction across the plurality of structures FSA.

As described above, the device region R_{DV} includes two conductive layers 110 (SGD) adjacent in the Y-direction via the inter-finger structure ST. The two insulating layer 110A provided at the positions corresponding to these two conductive layers 110 (SGD) in the edge region R_{ED} are continuous with one another.

As described with reference to FIG. 10, in the device region R_{DV}, the semiconductor columns 120 included in the structure ML₁ have upper end portions provided with the impurity regions 121. Meanwhile, as illustrated in FIG. 21, in the edge region R_{ED}, the upper end portions of the semiconductor columns 120 included in the structure MLA₁ are not provided with the impurity region 121. In the edge region R_{ED}, the semiconductor columns 120 included in the structure MLA₁ are spaced from the semiconductor layers 112A, 112E and the insulating layers 112B, 112C, 112D via the gate insulating film 130 and are insulated from the semiconductor layers 112A, 112E.

[Hook-Up Region R_{HU}m, R_{HU2} in Edge Region R_{ED} (Flat Region R_{FL})]

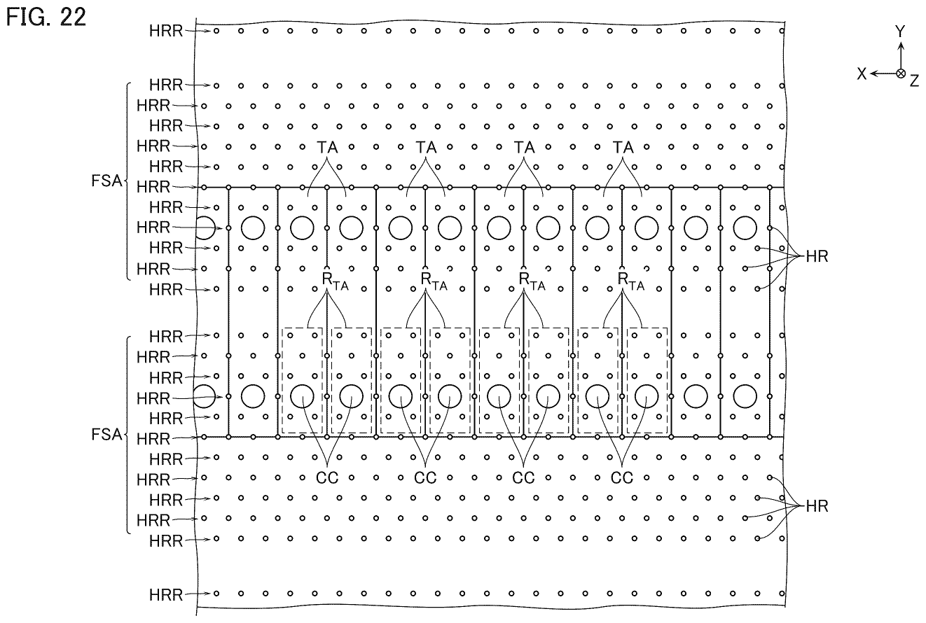

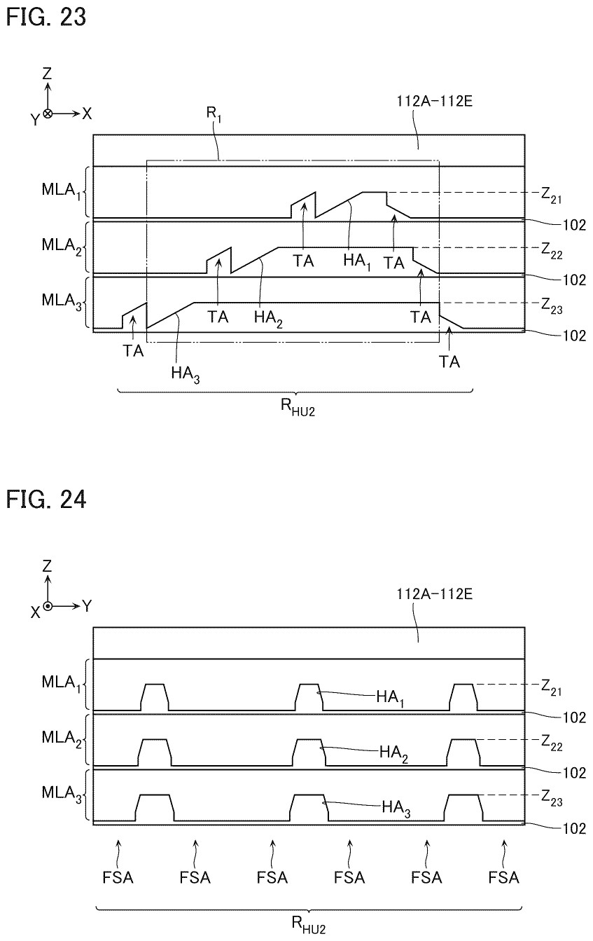

FIG. 22 is a schematic bottom view illustrating a part of the configuration of the semiconductor memory device according to the embodiment. A position in the die region R_{MD} in the edge region R_{ED} of the configuration illustrated in FIG. 22 corresponds to the position in the die region R_{MD} in the device region R_{DV} of the configuration illustrated in FIG. 13. FIG. 23 is a schematic cross-sectional view illustrating a part of the configuration of the semiconductor memory device according to the embodiment. A position in the die region R_{MD} in the edge region R_{ED} of the configuration illustrated in FIG. 23 corresponds to the position in the die region R_{MD} in the device region R_{DV} of the configuration illustrated in FIG. 14. FIG. 24 is a schematic cross-sectional view illustrating a part of the configuration of the semiconductor memory device according to the embodiment. A position in the die region R_{MD} in the edge region R_{ED} of the configuration illustrated in FIG. 24 corresponds to the position in the die region R_{MD} in the device region R_{DV} of the configuration illustrated in FIG. 15.

As illustrated in FIG. 19 and FIG. 23, in the hook-up regions R_{HU1}, R_{HU2} in the edge region R_{ED}, a plurality of terrace portions TA corresponding to the plurality of insulating layers 110A are provided. The terrace portions TA are, for example, portions of the lower surfaces of the insulating layers 110A, provided at positions corresponding to the terrace portions T of the conductive layers 110 provided at the corresponding height position, and not overlapping with at least one of the other insulating layers 110A when viewed from below. These plurality of terrace portions TA are covered with the above-described insulating layers 102.

Here, the plurality of terrace portions T corresponding to all the conductive layers 110 are provided in the hook-up regions R_{HU1}, R_{HU2} in the device region R_{DV}. On the other hand, in this embodiment, only the terrace portions TA of a part of the insulating layers 110A are provided in the hook-up regions R_{HU1}, R_{HU2} in the edge region R_{ED}.

That is, approximately a half of the insulating layers 110A in the structure MLA₁ provided below a height position Z₂₁ each include the terrace portion TA. These plurality of terrace portions TA do not overlap with the other insulating layers 110A in the structure MLA₁ but overlap with parts of the insulating layers 110A in the structures MLA₂, MLA₃ when viewed from below. On the other hand, the rest of the insulating layers 110A in the structure MLA₁ provided above the height position Z₂₁ do not include the terrace portions TA. These rest of the insulating layers 110A each extend in the X-direction and the Y-direction above the insulating layer 102 in the structure MLA₁.

In the illustrated example, the structure MLA₁ is provided with a hole portion HA₁ that does not penetrate the stacked structure formed of the plurality of insulating layers 110A and the plurality of insulating layers 101. A part of the hole portion HA₁ is configured of the terrace portions TA. The hole portion HA₁ is filled with a part of the insulating layer 102. The insulating layer 102 in the structure MLA₁ is not in contact with the semiconductor layer 112.

Similarly, approximately a half of the insulating layers 110A in the structure MLA₂ provided below a height position Z₂₂ each include the terrace portion TA. These plurality of terrace portions TA do not overlap with the other insulating layers 110A in the structure MLA₂, but overlap with parts of the insulating layers 110A in the structure MLA₃ when viewed from below. On the other hand, the rest of the insulating layers 110A in the structure MLA₂ provided above the height position Z₂₂ do not include the terrace portion TA. These rest of the insulating layers 110A each extend in the X-direction and the Y-direction above the insulating layer 102 in the structure MLA₂.

In the illustrated example, the structure MLA₂ is provided with a hole portion HA₂ that does not penetrate the stacked structure formed of the plurality of insulating layers 110A and the plurality of insulating layers 101. A part of the hole portion HA₂ is configured of the terrace portions TA. The hole portion HA₂ is filled with a part of the insulating layer 102. The insulating layer 102 in the structure MLA₂ is not in contact with the insulating layer 102 in the structure MLA₁.

Similarly, approximately a half of the insulating layers 110A in the structure MLA₃ provided below a height position Z₂₃ each include the terrace portion TA. These plurality of terrace portions TA do not overlap with the other insulating layers 110A when viewed from below. On the other hand, the rest of the insulating layers 110A in the structure MLA₃ provided above the height position Z₂₃ do not include the terrace portions TA. These rest of the insulating layers 110A each extend in the X-direction and the Y-direction above the insulating layer 102 in the structure MLA₃.

In the illustrated example, the structure MLA₃ is provided with a hole portion HA₃ that does not penetrate the stacked structure formed of the plurality of insulating layers 110A and the plurality of insulating layers 101. A part of the hole portion HA₃ is configured of the terrace portions TA. The hole portion HA₃ is filled with a part of the insulating layer 102. The insulating layer 102 in the structure MLA₃ is not in contact with the insulating layer 102 in the structure MLA₂.

Here, regions where the terrace portions T of the conductive layers 110 (WL) are provided are illustrated as terrace regions R_{T} in FIG. 13. The terrace region R_{T} exemplarily illustrated in FIG. 13 is provided with a part of the plurality of conductive layers 110 (WL) arranged in the Z-direction but not provided with the other conductive layers 110 (WL). FIG. 22 illustrates regions R_{TA} provided at the positions corresponding to the terrace regions R_{T} in the edge region R_{ED}. The regions R_{TA} exemplarily illustrated in FIG. 22 are provided with a part of the plurality of insulating layers 110A arranged in the Z-direction but not provided with the other insulating layers 110A.

As described with reference to FIG. 14 and FIG. 15, in the hook-up region R_{HU2} in the device region R_{DV}, all the plurality of conductive layers 110 (WL) arranged in the Z-direction include the terrace portions T. Meanwhile, as described with reference to FIG. 23 and FIG. 24, only approximately a half of the plurality of insulating layers 110A arranged in the Z-direction include the terrace portions TA in the hook-up region R_{HU2} in the edge region R_{ED}, and the rest of the plurality of insulating layers 110A do not include the terrace portions TA.

With such a configuration, the number of the plurality of insulating layers 110A stacked in the Z-direction in a predetermined region R_{TA} (FIG. 22) is more than the number of the plurality of conductive layers 110 (WL) stacked in the Z-direction in the terrace region R_{T}(FIG. 13) provided at a position corresponding to this predetermined region R_{TA}. Such a relationship is held true between all the regions R_{TA} included in the region R1 in FIG. 23 and all the terrace regions R_{T} corresponding to these regions R_{TA}.

[Between Regions R_{PNA} in Edge Region R_{ED} (Flat Region R_{FL})]

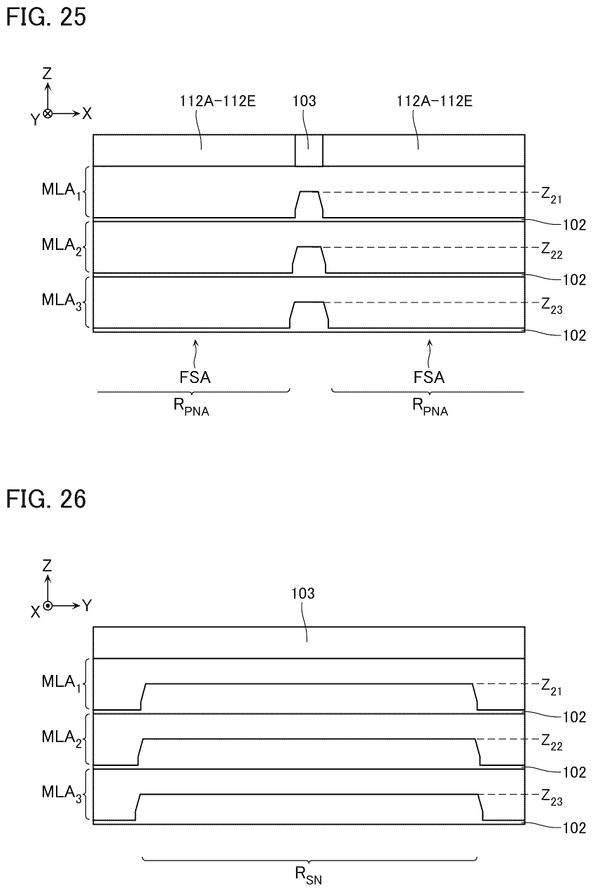

FIG. 25 is a schematic cross-sectional view illustrating a part of the configuration of the semiconductor memory device according to the embodiment. A position in the die region R_{MD} in the edge region R_{ED} of the configuration illustrated in FIG. 25 correspond to the position in the die region R_{MD} in the device region R_{DV} of the configuration illustrated in FIG. 17.

The regions R_{PNA} are provided at the positions corresponding to the plane regions R_{PN}, in the die region R_{MD} in the edge region R_{ED}. The region R_{PNA} includes the plurality of structures FSA instead of the plurality of finger structures FS and the plurality of inter-finger structures ST alternately arranged in the Y-direction.

Here, as described with reference to FIG. 17, all the conductive layers 110 and insulating layers 101 are divided in the X-direction or the Y-direction via the insulating layers 102 between the two plane regions R_{PN} adjacent in the X-direction or the Y-direction in the device region R_{DV}. On the other hand, in this embodiment, only a part of the insulating layers 110A and the insulating layers 101 are divided in the X-direction or the Y-direction via the insulating layers 102 between two regions R_{PNA} adjacent in the X-direction or the Y-direction in the edge region R_{ED}.

That is, approximately a half of the insulating layers 110A in the structure MLA₁ provided below the height position Z₂₁ are each divided via the insulating layer 102 between two regions R_{PNA} adjacent in the X-direction or the Y-direction. On the other hand, the rest of the insulating layers 110A in the structure MLA₁ provided above the height position Z₂₁ continue between two regions R_{PNA} adjacent in the X-direction or the Y-direction, and each extend in the X-direction and the Y-direction above the insulating layer 102 in the structure MLA₁.

Similarly, approximately a half of the insulating layers 110A in the structure MLA₂ provided below the height position Z₂₂ are each divided via the insulating layer 102 between two regions R_{PNA} adjacent in the X-direction or the Y-direction. On the other hand, the rest of the insulating layers 110A in the structure MLA₂ provided above the height position Z₂₂ continue between two regions R_{PNA} adjacent in the X-direction or the Y-direction, and each extend in the X-direction and the Y-direction above the insulating layer 102 in the structure MLA₂.

Similarly, approximately a half of the insulating layers 110A in the structure MLA₃ provided below the height position Z₂₃ are each divided via the insulating layer 102 between two regions R_{PNA} adjacent in the X-direction or the Y-direction. On the other hand, the rest of the insulating layers 110A in the structure MLA₃ provided above the height position Z₂₃ continue between two regions R_{PNA} adjacent in the X-direction or the Y-direction, and each extend in the X-direction and the Y-direction above the insulating layer 102 in the structure MLA₃.

[Kerf Region R_{K} in Edge Region R_{ED} (Flat Region R_{L})]

FIG. 26 is a schematic cross-sectional view illustrating a part of the configuration of the semiconductor memory device according to the embodiment. A position in the kerf region R_{K} in the edge region R_{ED} of the configuration illustrated in FIG. 26 correspond to the position in the kerf region R_{K} in the device region R_{DV} of the configuration illustrated in FIG. 18. Note that the positions in the kerf region R_{K} in the device region R_{DV} and the edge region R_{ED} referred here can be specified by, for example, a positional relationship with the die region R_{MD} closest to these positions.

As described above, in the device region R_{DV}, the plurality of conductive layers 110 and the plurality of insulating layers 101 or the plurality of insulating layers 110A and the plurality of insulating layers 101 alternately stacked in the Z-direction are not provided in the non-stacked body region R_{SN} in the kerf region R_{KY}. On the other hand, in this embodiment, in the edge region R_{ED}, a part of the plurality of insulating layers 110A and the plurality of insulating layers 101 alternately stacked in the Z-direction are provided in the non-stacked body region R_{SN} in the kerf region R_{KY}.

That is, approximately a half of the insulating layers 110A in the structure MLA₁ provided below the height position Z₂₁ are each removed in the non-stacked body region R_{SN}, and the insulating layer 102 is provided in the region in which the insulating layers 110A are removed. On the other hand, the rest of the insulating layers 110A in the structure MLA₁ provided above the height position Z₂₁ are not removed in the non-stacked body region R_{SN}, and each extend in the X-direction and the Y-direction above the insulating layer 102 in the structure MLA₁.

Similarly, approximately a half of the insulating layers 110A in the structure MLA₂ provided below the height position Z₂₂ are each removed in the non-stacked body region R_{SN}, and the insulating layer 102 is provided in the region in which the insulating layers 110A are removed. On the other hand, the rest of the insulating layers 110A in the structure MLA₂ provided above the height position Z₂₂ are not removed in the non-stacked body region R_{SN}, and each extend in the X-direction and the Y-direction above the insulating layer 102 in the structure MLA₂.

Similarly, approximately a half of the insulating layers 110A in the structure MLA₃ provided below the height position Z₂₃ are each removed in the non-stacked body region R_{SN}, and the insulating layer 102 is provided in the region in which the insulating layers 110A are removed. On the other hand, the rest of the insulating layers 110A in the structure MLA₃ provided above the height position Z₂₃ are not removed in the non-stacked body region R_{SN}, and each extend in the X-direction and the Y-direction above the insulating layer 102 in the structure MLA₃.

[Round Region R_{RN} in Edge Region R_{ED}]

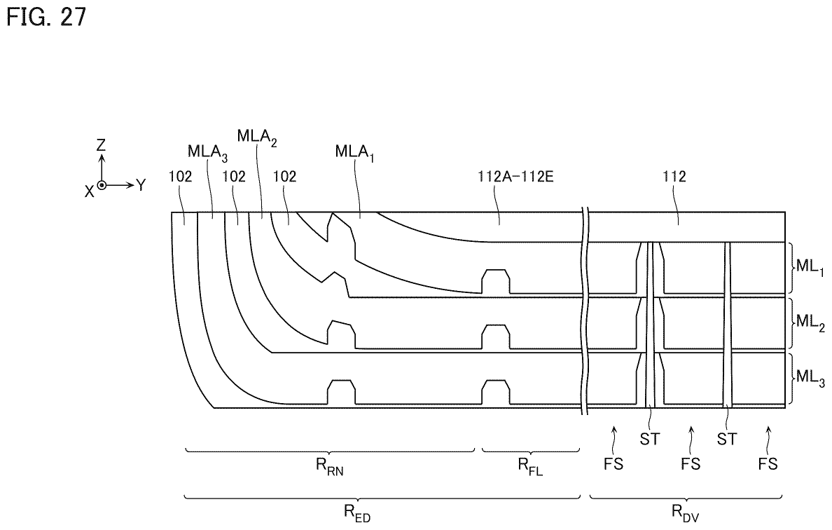

FIG. 27 is a schematic cross-sectional view illustrating a part of the configuration of the semiconductor memory device according to the embodiment.

In the flat region R_{EL} in the edge region R_{ED}, the semiconductor layer 112A is formed in an approximately flat manner along the XY plane and has an approximately uniform length in the Z-direction. The insulating layers 110A and the insulating layers 101 in the structures MLA₁, MLA₂, MLA₃ are also formed in an approximately flat manner along the XY plane.

On the other hand, in the round region R_{RN} in the edge region R_{ED}, the length in the Z-direction of the semiconductor layer 112A decreases in thickness towards the outer edge of the wafer W_{M}. That is, while the upper surface of the semiconductor layer 112A is formed in an approximately flat manner along the XY plane, the lower surface of the semiconductor layer 112A is curved to approach the upper surface of the semiconductor layer 112A as approaching the outer edge of the wafer W_{M}. The insulating layers 110A and the insulating layers 101 in the structures MLA₁, MLA₂, MLA₃ are formed along the curved surface formed on the lower surface of the semiconductor layer 112A and are curved to approach the upper surface of the semiconductor layer 112A as approaching the outer edge of the wafer W_{M}.

In this embodiment, the insulating layers 110A, 101 in the structures MLA₁, MLA₂, MLA₃ reach the round region R_{RN}. In the illustrated example, the outer edge of the semiconductor layer 112A is covered with the structure MLA₁, the outer edge of the structure MLA₁ is covered with the structure MLA₂, and the outer edge of the structure MLA₂ is covered with the structure MLA₃.

### [Manufacturing Method]

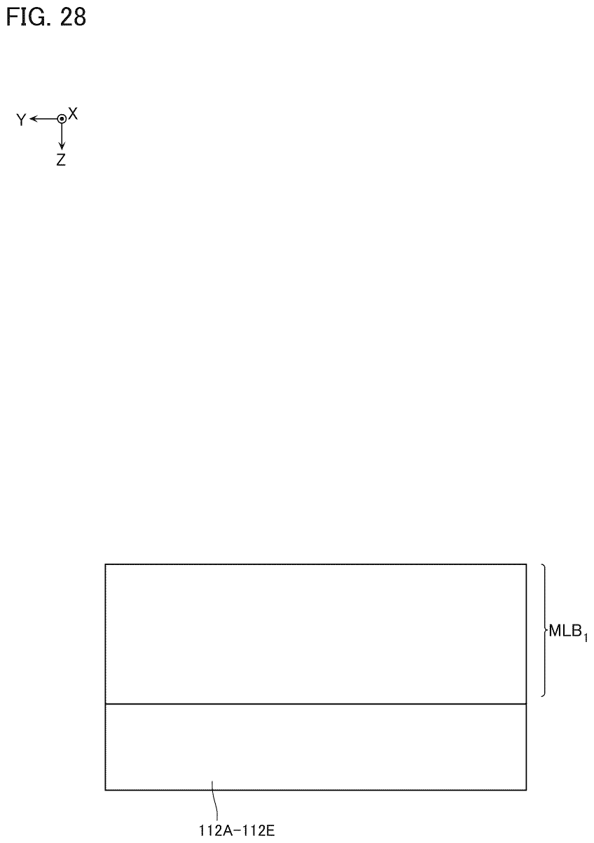

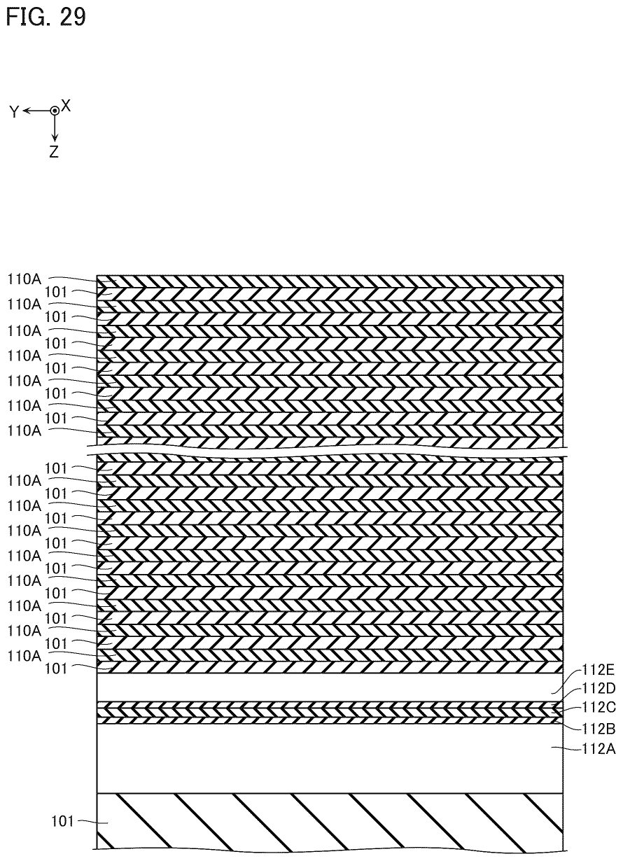

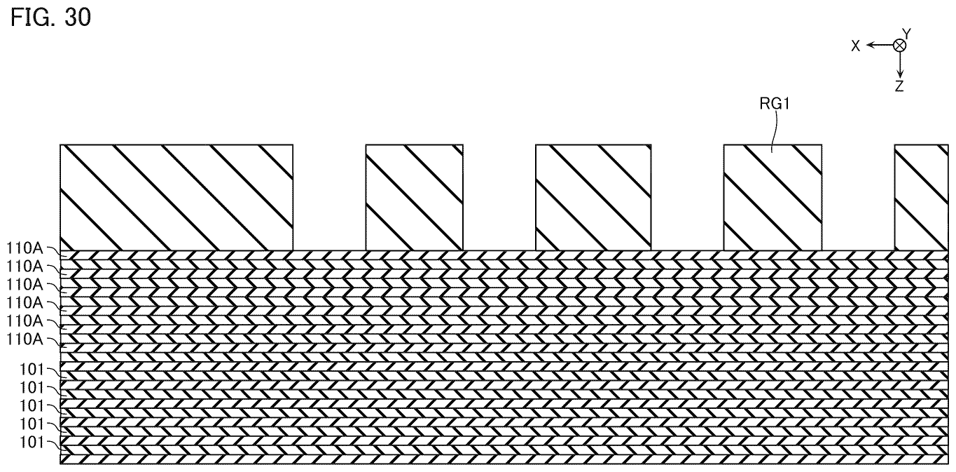

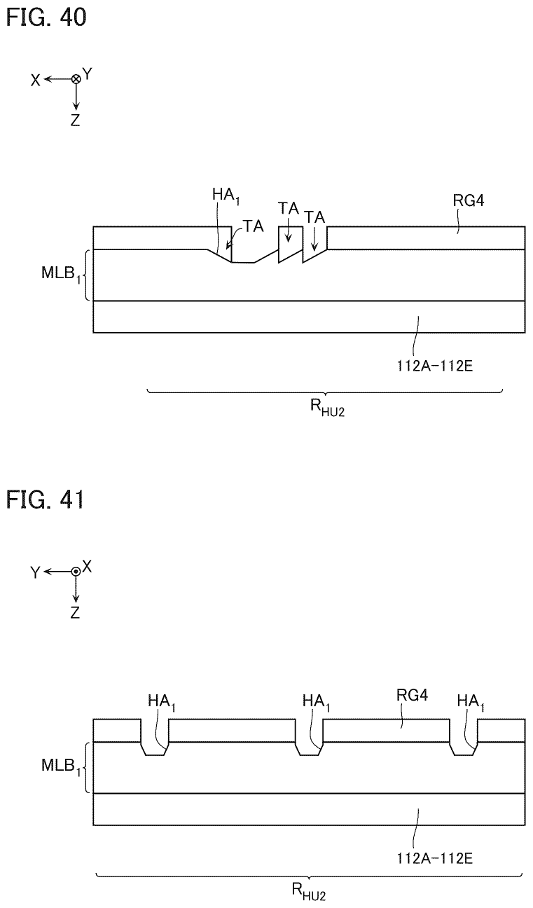

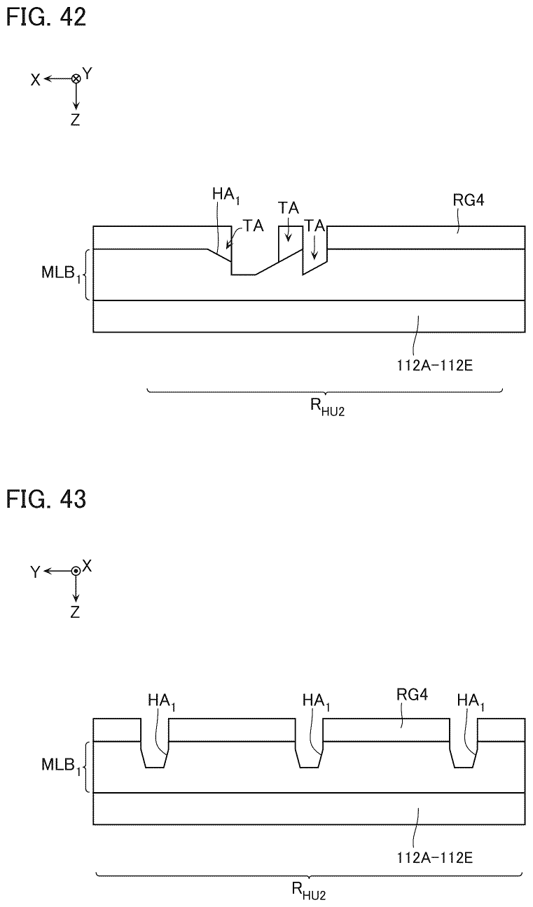

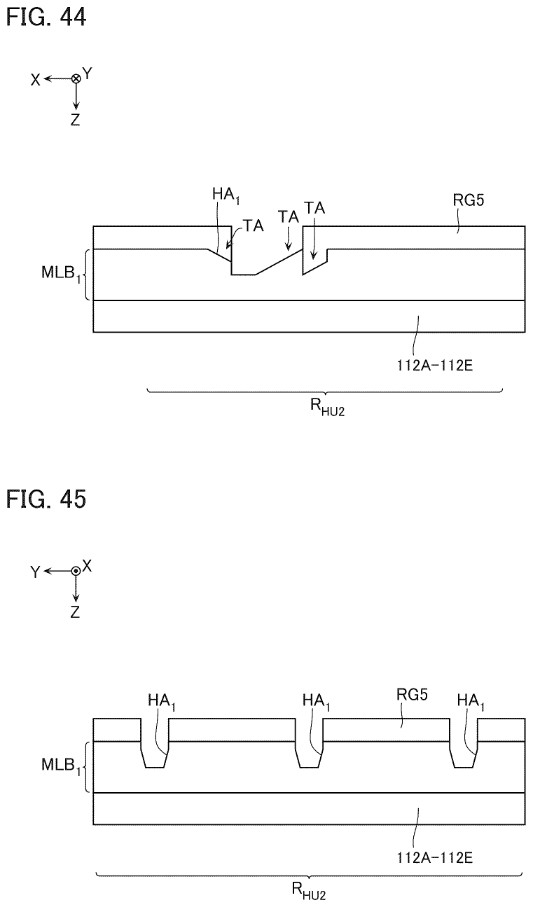

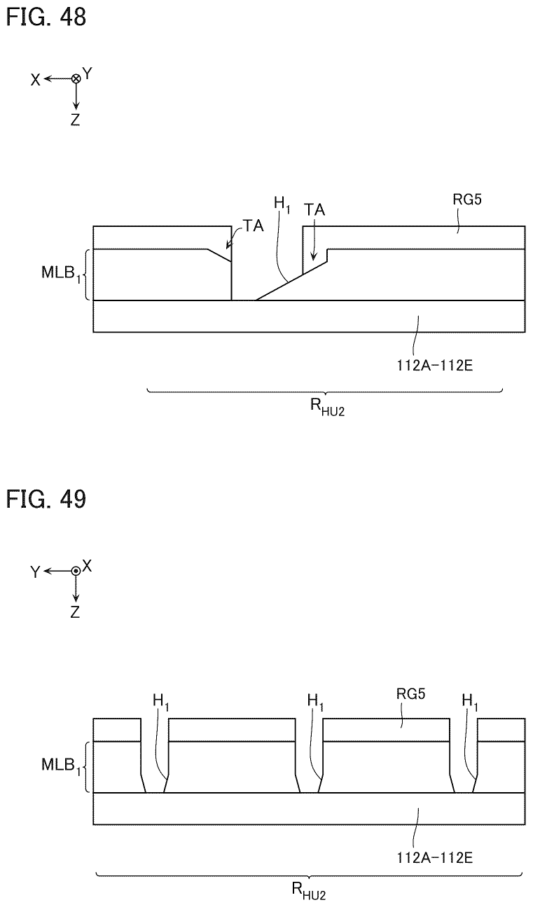

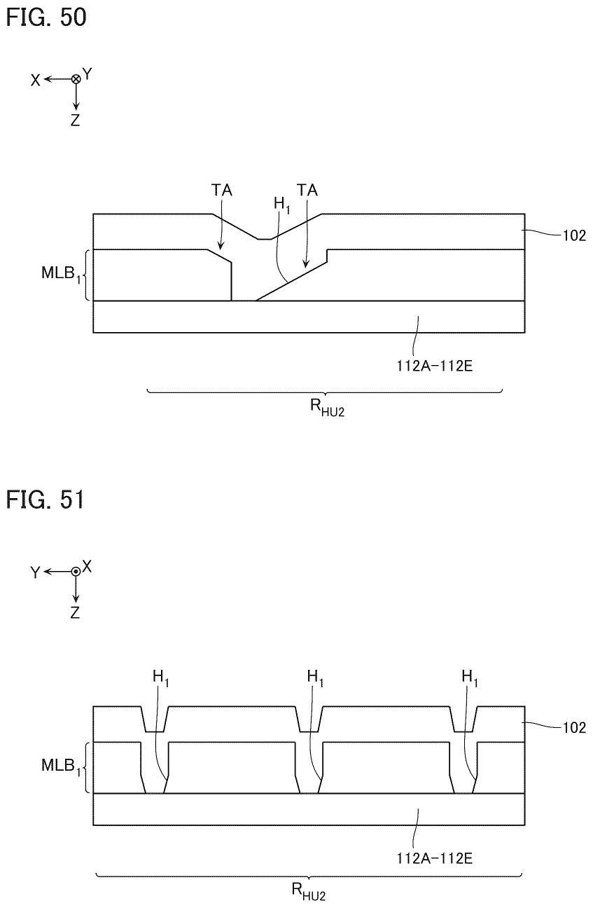

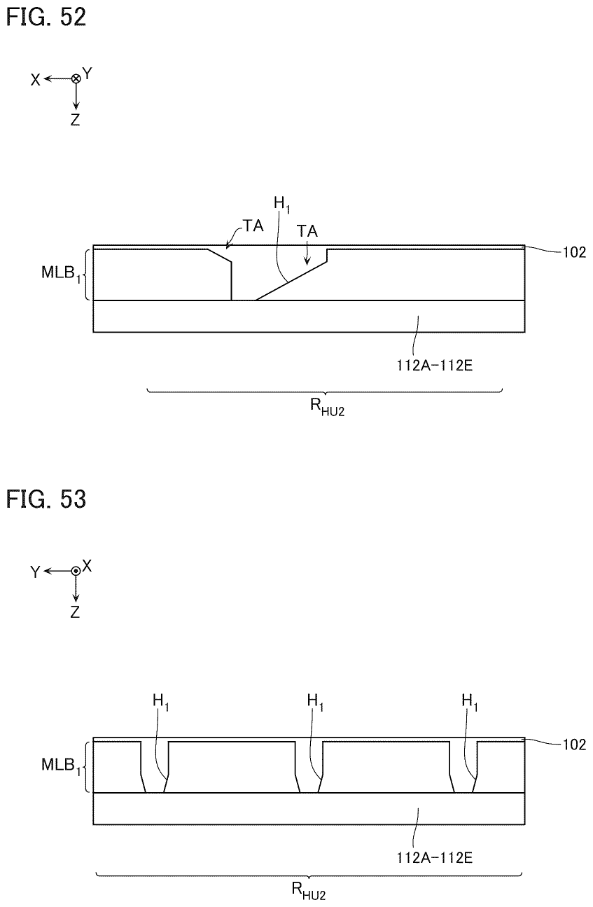

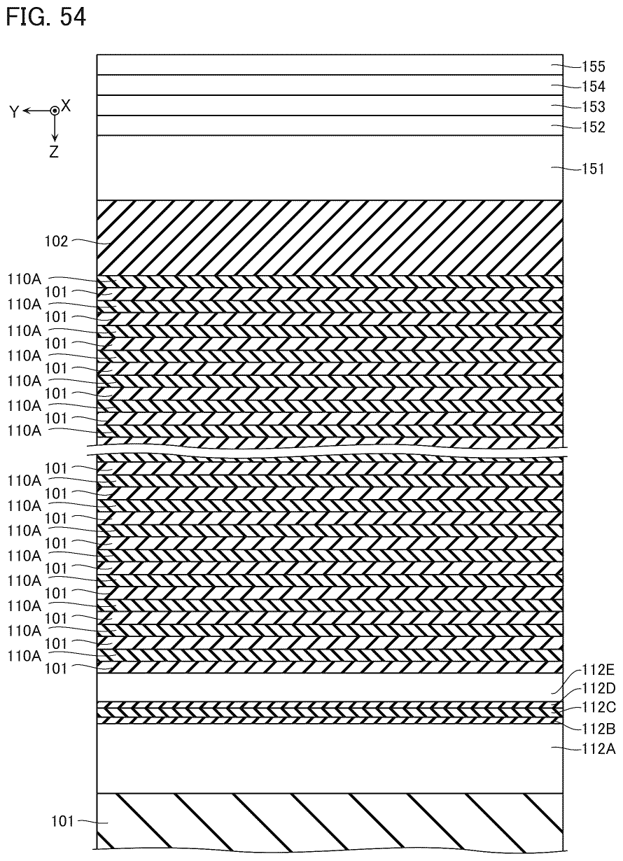

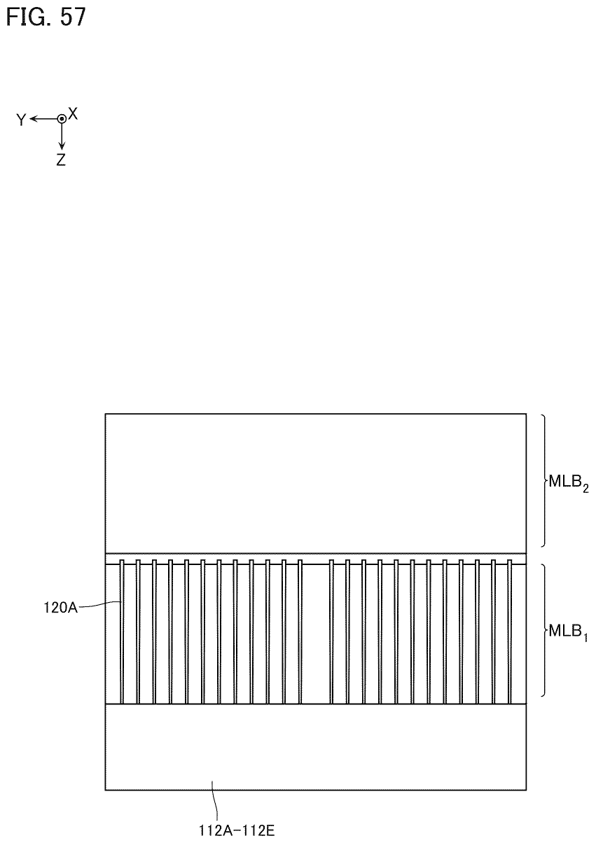

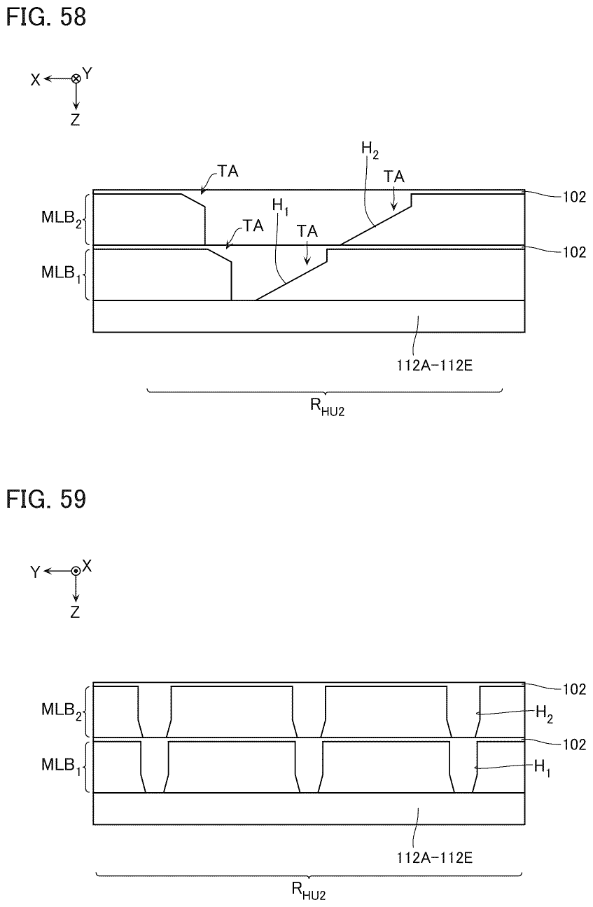

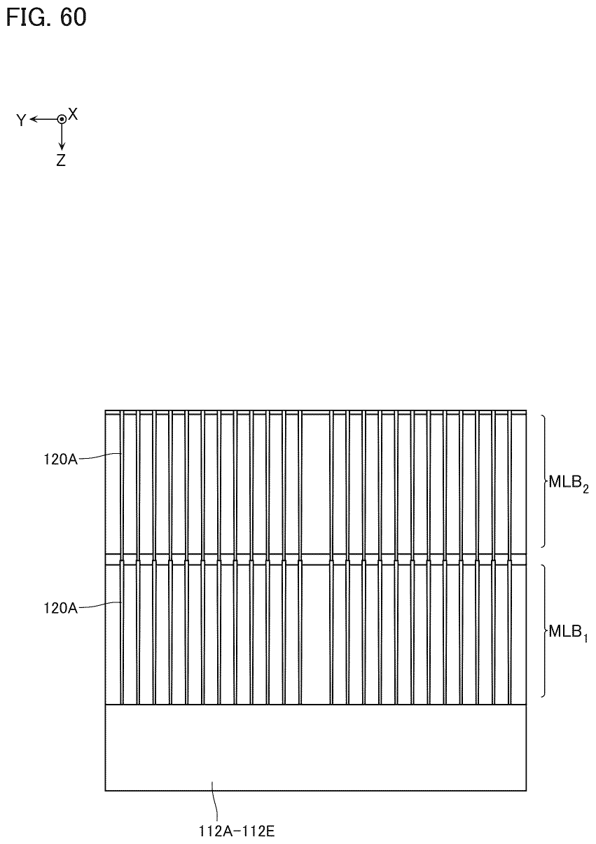

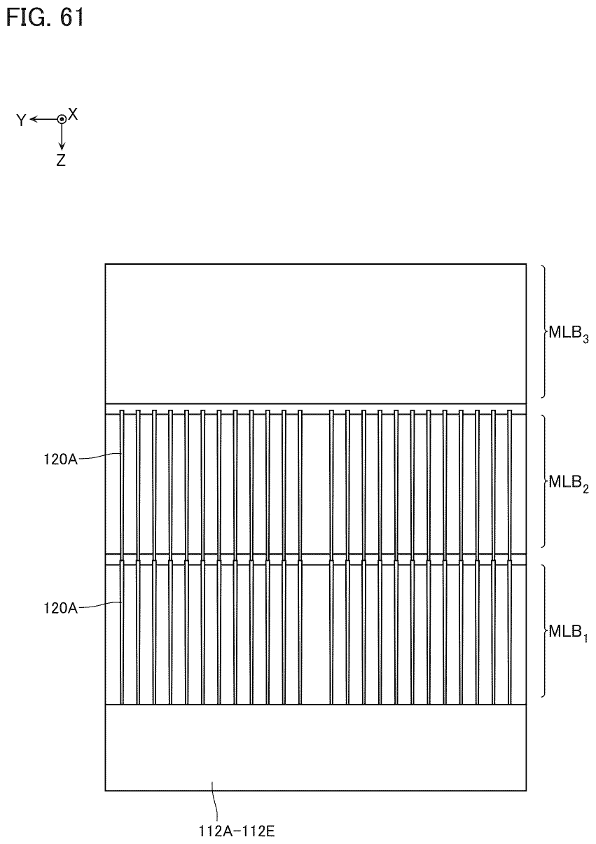

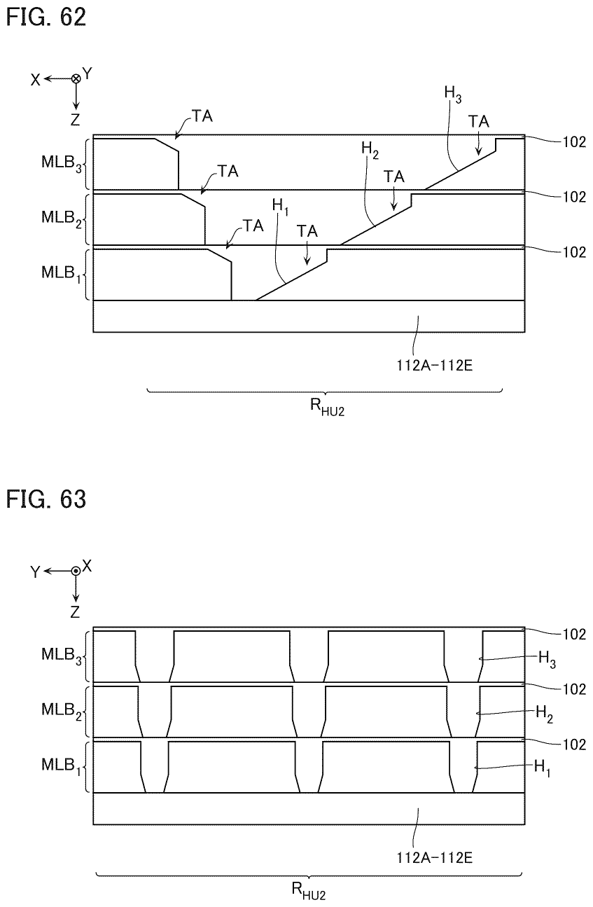

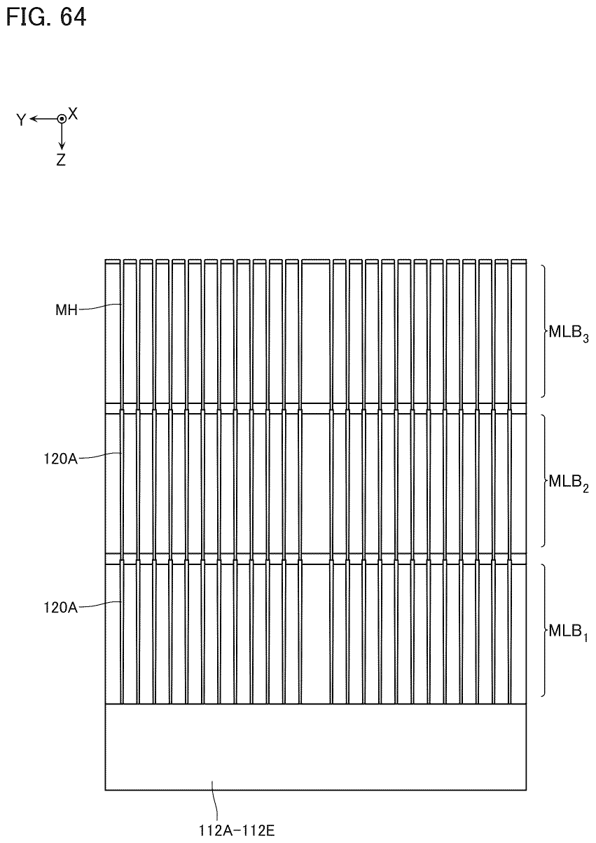

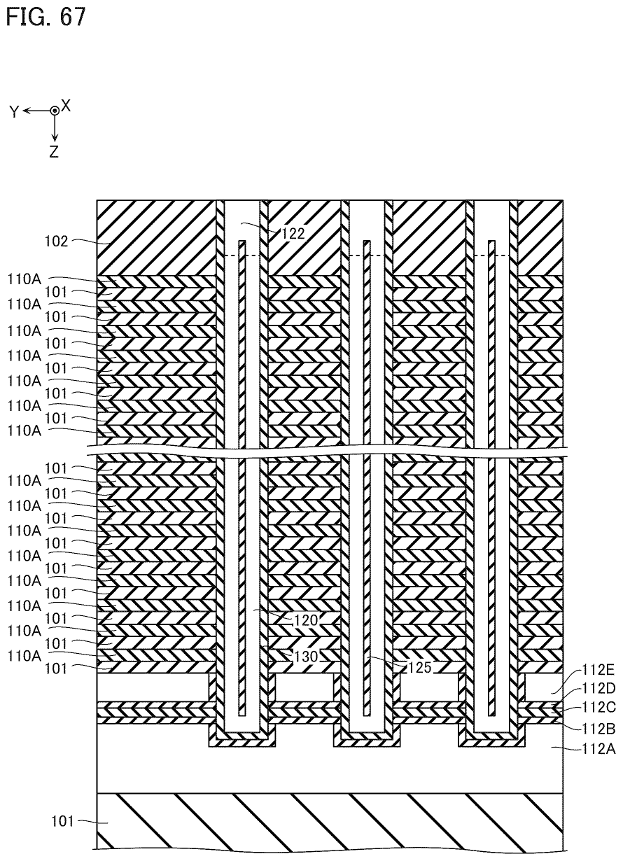

Next, with reference to FIG. 28 to FIG. 72, a method for manufacturing the semiconductor memory device according to the first embodiment is described. FIG. 28, FIG. 57, FIG. 60, FIG. 61, and FIG. 64 to FIG. 66 are schematic cross-sectional views for describing the same manufacturing method, and illustrate configurations corresponding to that in FIG. 9. FIG. 29, FIG. 54 to FIG. 56, and FIG. 67 to FIG. 72 are schematic cross-sectional views for describing the same manufacturing method, and illustrate configurations corresponding to that in FIG. 10. FIG. 31 and FIG. 32 are schematic bottom views for describing the same manufacturing method, and illustrate configurations corresponding to that in FIG. 3. FIG. 30 and FIG. 33 to FIG. 39 are schematic cross-sectional views for describing the same manufacturing method. FIG. 40, FIG. 42, FIG. 44, FIG. 48, FIG. 50, FIG. 52, FIG. 58, and FIG. 62 are schematic cross-sectional views for describing the same manufacturing method, and illustrate configurations corresponding to that in FIG. 14. FIG. 41, FIG. 43, FIG. 45, FIG. 49, FIG. 51, FIG. 53, FIG. 59, and FIG. 63 are schematic cross-sectional views for describing the same manufacturing method, and illustrate configurations corresponding to that in FIG. 15. FIG. 46 and FIG. 47 are schematic perspective views for describing the same manufacturing method.

In manufacturing the semiconductor memory device according to the embodiment, for example, as illustrated in FIG. 28 and FIG. 29, the semiconductor layer 112A, the insulating layers 112B, 112C, 112D, and the semiconductor layer 112E are formed. The plurality of insulating layers 101 and the plurality of insulating layers 110A are alternately formed. This process is performed by a method such as Chemical Vapor Deposition (CVD), for example.

In this process, those included in the structure ML₁ (FIG. 9) and the structure MLA₁ (FIG. 20) among the plurality of insulating layers 101 and those corresponding to the conductive layers 110 in the structure ML₁ and those included in the structure MLA₁ among the plurality of insulating layers 110A are formed. The configuration including these are hereinafter referred to as a structure MLB₁ (FIG. 28).

Next, for example, as illustrated in FIG. 30, a resist RG1 is formed on a front surface side of the configuration described with reference to FIG. 28 and FIG. 29. This resist RG1 exposes, for example, the configurations in a part of the region in the hook-up region R_{HU2}, between the plane regions R_{PN}, between the regions R_{PNA}, and in the non-stacked body region R_{SN}, and covers other configurations.

In forming the resist RG1, for example, a resist is applied, patterning is performed by means of photolithography or the like, and parts of the resist are removed. For photolithography, for example, as illustrated in FIG. 31 and FIG. 32, a pattern (hereinafter referred to as a “shot pattern SP”) corresponding to the plurality of die regions R_{MD} is sequentially transferred onto the resist over the whole region in the wafer W_{M} including the device region R_{DV} and the edge region R_{ED} using a stepper or the like. In the illustrated example, the shot pattern SP includes a pattern corresponding to a total of eight die regions R_{MD}, four in the X-direction and two in the Y-direction. Note that FIG. 31 exemplarily illustrates a state after the execution of the 10th transfer. FIG. 32 exemplarily illustrates a state after the execution of the 11th transfer.

Next, removal of the insulating layers 110A, removal of the insulating layers 101, and removal of parts of the resist RG1 are repeated for a plurality of times to form the plurality of terrace portions TA.

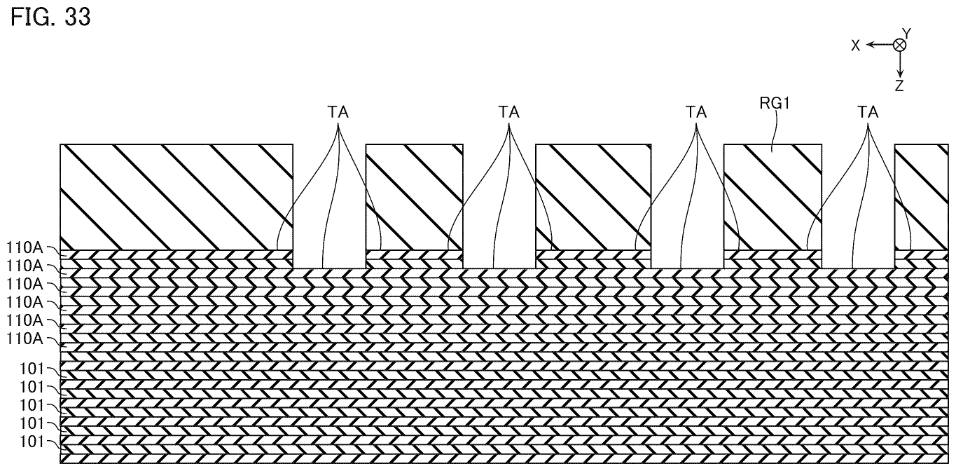

For example, as illustrated in FIG. 33, one layer of the insulating layers 110A is selectively removed by means of dry etching or the like. One layer of the insulating layers 101 is also selectively removed by means of dry etching or the like.

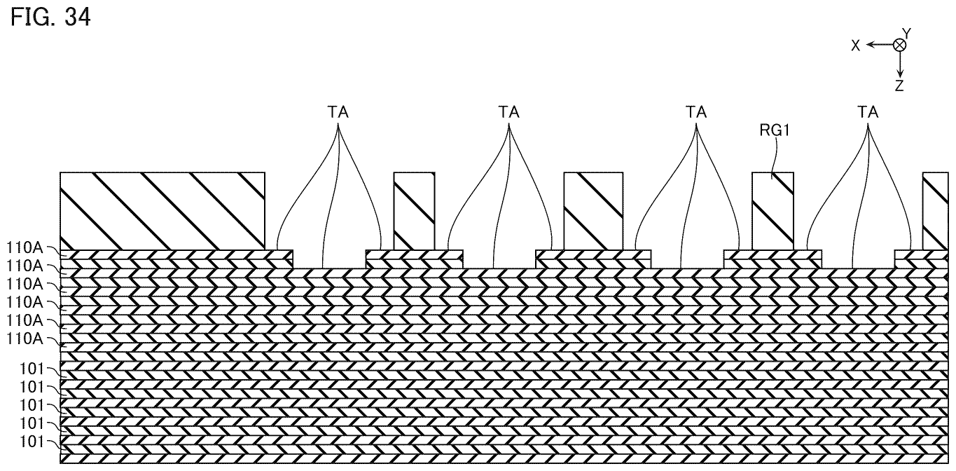

Next, for example, as illustrated in FIG. 34, parts of the resist RG1 are isotropically removed to expose parts of the front surface of the insulating layer 110A covered with the resist RG1. This process is performed by means of dry etching or the like, for example.

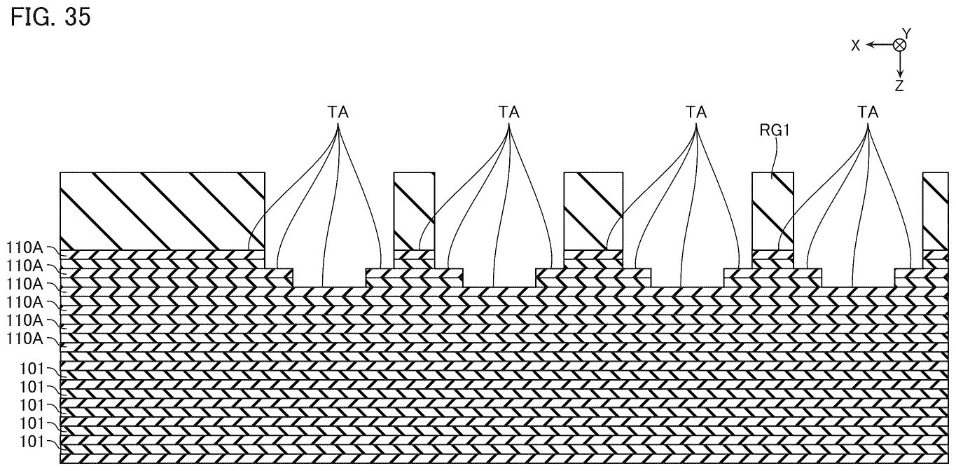

Next, as illustrated in FIG. 35, one layer of the insulating layers 110A is selectively removed by means of dry etching or the like. One layer of the insulating layers 101 is also selectively removed by means of dry etching or the like.

Thereafter, the resist RG1 is removed.

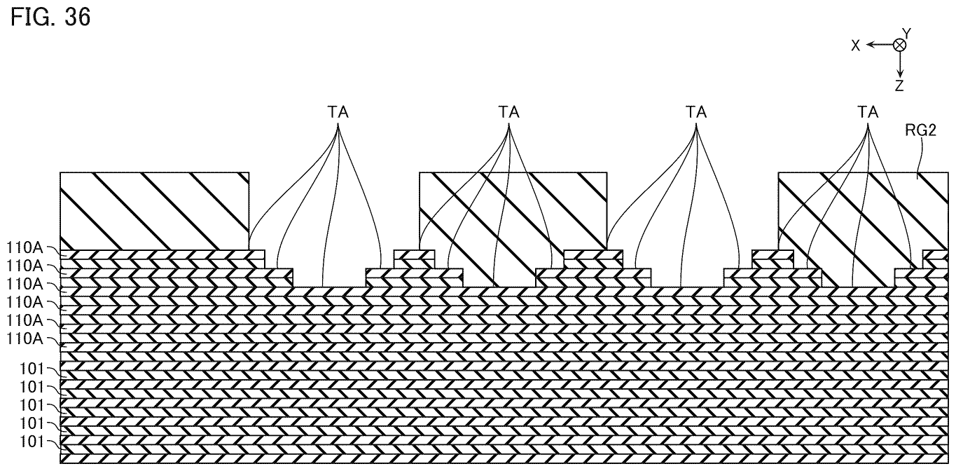

Next, for example, as illustrated in FIG. 36, a resist RG2 is formed on a front surface side of the configuration described with reference to FIG. 35. This resist RG2, for example, exposes the configurations in a part of the region in the hook-up region R_{HU2}, between the plane regions R_{PN}, between the regions R_{PNA}, and in the non-stacked body region R_{SN}, and covers other configurations.

In forming the resist RG2, for example, a resist is applied, patterning is performed by means of photolithography or the like, and parts of the resist are removed. For photolithography, for example, a method similar to the method described with reference to FIG. 31 and FIG. 32 is executed.

Next, removal of the insulating layers 110A and removal of the insulating layers 101 are repeated for a plurality of times to form the plurality of terrace portions TA.

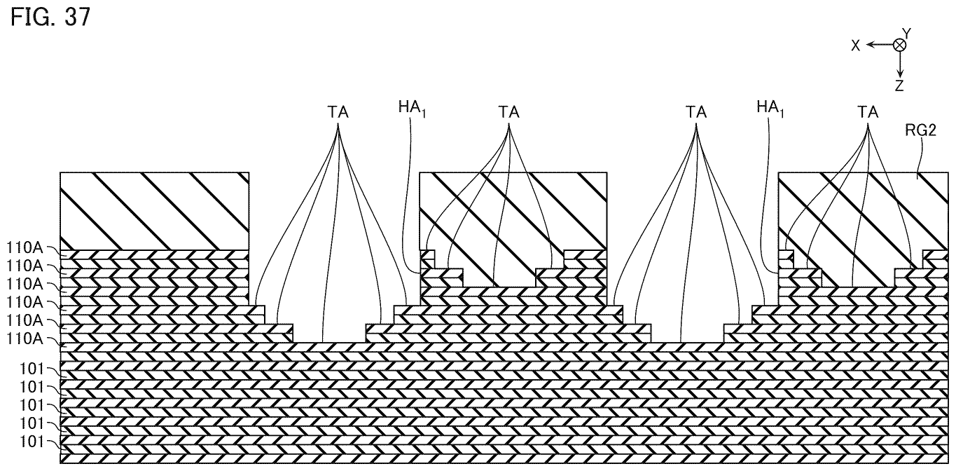

For example, in the example in FIG. 36, the plurality of terrace portions TA corresponding to three insulating layers 110A are formed in the hook-up region R_{HU2}. In such a case, parts of the plurality of terrace portions TA corresponding to these three respective insulating layers 110A are covered with the resist RG2 and parts of the plurality of terrace portions TA corresponding to these three respective insulating layers 110A are exposed. As illustrated in FIG. 37, removal of the insulating layers 110A and removal of the insulating layers 101 are repeated for three times each. This forms the plurality of terrace portions TA corresponding to six insulating layers 110A and the hole portions HA₁ in the hook-up region R_{HU2}. Note that the removal of the insulating layers 110A and the removal of the insulating layers 101 are executed by means of dry etching or the like, for example.

Thereafter, the resist RG2 is removed.

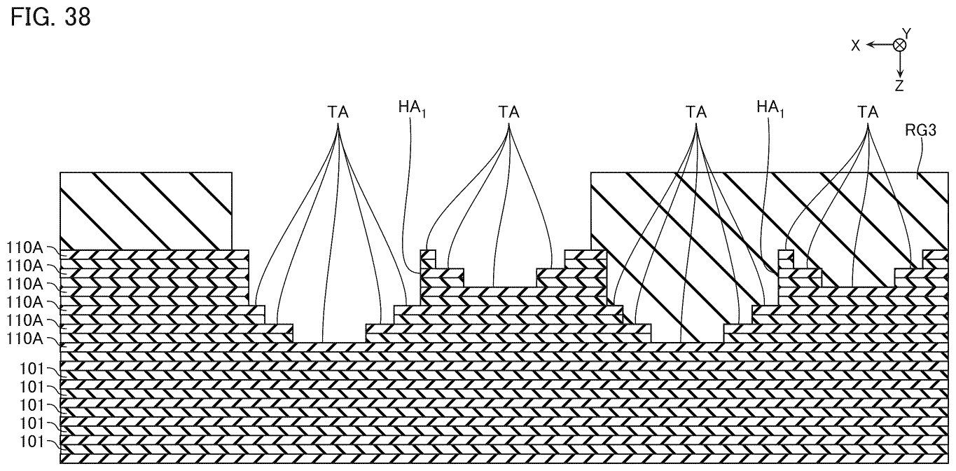

Next, for example, as illustrated in FIG. 38, a resist RG3 is formed on a front surface side of the configuration described with reference to FIG. 37. This resist RG3, for example, exposes the configurations in a part of the region in the hook-up region R_{HU2}, between the plane regions R_{PN}, between the regions R_{PNA}, and in the non-stacked body region R_{SN}, and covers other configurations.

In forming the resist RG3, for example, a resist is applied, patterning is performed by means of photolithography or the like, and parts of the resist are removed. For photolithography, for example, a method similar to the method described with reference to FIG. 31 and FIG. 32 is executed.

Next, removal of the insulating layers 110A and removal of the insulating layers 101 are repeated for a plurality of times to form the plurality of terrace portions TA.

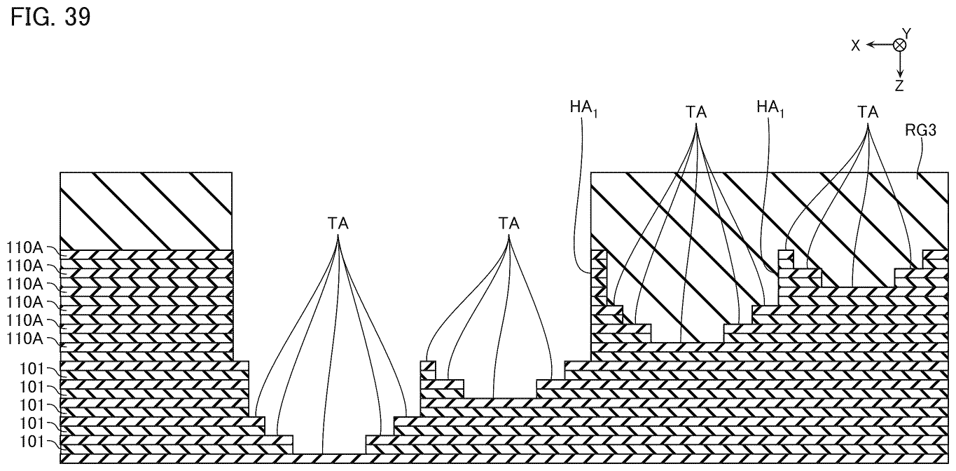

For example, in the example in FIG. 38, the plurality of terrace portions TA corresponding to six insulating layers 110A are formed in the hook-up region R_{HU2}. In such a case, parts of the plurality of terrace portions TA corresponding to these six respective insulating layers 110A are covered with the resist RG3 and parts of the plurality of terrace portions TA corresponding to these six respective insulating layers 110A are exposed. As illustrated in FIG. 39, removal of the insulating layers 110A and removal of the insulating layers 101 are repeated for six times each. This forms the plurality of terrace portions TA corresponding to twelve insulating layers 110A and the hole portions HA₁. Note that the removal of the insulating layers 110A and the removal of the insulating layers 101 are executed by means of dry etching or the like, for example.

Thereafter, the resist RG3 is removed.

Hereinafter, processes similar to the process described with reference to FIG. 36 and FIG. 37 and the process described with reference to FIG. 38 and FIG. 39 are each referred to as a terrace portion formation process.

The terrace portion formation process is similarly executed as appropriate below to further form the plurality of terrace portions TA corresponding to the plurality of insulating layers 110A and the hole portions HA₁.

For example, as illustrated in FIG. 40 and FIG. 41, a resist RG4 is formed on a front surface side of the structure MLB₁. This resist RG4, for example, exposes the configurations in a part of the region in the hook-up region R_{HU2}, between the plane regions R_{PN}, between the regions R_{PNA}, and in the non-stacked body region R_{SN}, and covers other configurations.

Next, removal of the insulating layers 110A and removal of the insulating layers 101 are repeated for a plurality of times to form the plurality of terrace portions TA.

For example, in the examples in FIG. 40 and FIG. 41, the plurality of terrace portions TA corresponding to approximately a quarter of the insulating layers 110A in the structure MLB₁ are formed in the hook-up region R_{HU2}. In such a case, parts of the plurality of terrace portions TA corresponding to approximately a quarter of these respective insulating layers 110A are covered with the resist RG4, parts of the plurality of terrace portions TA corresponding to approximately a quarter of these respective insulating layers 110A are exposed. As illustrated in FIG. 42 and FIG. 43, removal of the insulating layers 110A and removal of the insulating layers 101 are repeated for the number of times equal to the number of approximately a quarter of the insulating layers 110A each. This forms the plurality of terrace portions TA corresponding to approximately a half of the insulating layers 110A in the structure MLB₁ and the hole portions HA₁. Note that the removal of the insulating layers 110A and the removal of the insulating layers 101 are executed by means of dry etching or the like, for example.

Thereafter, the resist RG4 is removed.

Next, as illustrated in FIG. 44 and FIG. 45, a resist RG5 is formed on a front surface side of the structure MLB₁. This resist RG5, for example, exposes the configurations in a part of the region in the hook-up region R_{HU2}, between the plane regions R_{PN}, between the regions R_{PNA}, and in the non-stacked body region R_{SN}, and covers other configurations.

Here, in the final terrace portion formation process corresponding to the structure MLB₁, the resist RG6 is formed in the edge region R_{ED} as illustrated in FIG. 46 and FIG. 47. In forming the resist RG6, for example, as illustrated in FIG. 46, the wafer W_{M} is rotated, and a nozzle NZ is moved to a direction approaching a rotation axis of the wafer W_{M} with a resist being discharged from the nozzle NZ. Next, the nozzle NZ is stopped for a certain period of time at a position where the resist RG6 is applied on the edge region R_{ED} and where the resist RG6 is not applied on the device region R_{DV}. This applies the resist RG6 on the edge region R_{ED}. Next, as illustrated in FIG. 47, the nozzle NZ is moved in a direction moving away from the rotation axis of the wafer W_{M}.

Next, as illustrated in FIG. 48 and FIG. 49, removal of the insulating layers 110A and removal of the insulating layers 101 are repeated for a plurality of times to form the plurality of terrace portions TA.

For example, in the examples in FIG. 44 and FIG. 45, the plurality of terrace portions TA corresponding to approximately a half of the insulating layers 110A are formed in the hook-up region R_{HU2}. In such a case, parts of the plurality of terrace portions TA corresponding to approximately a half of these respective insulating layers 110A are covered with the resist RG5, parts of the plurality of terrace portions TA corresponding to approximately a half of these respective insulating layers 110A are exposed. As illustrated in FIG. 48 and FIG. 49, removal of the insulating layers 110A and removal of the insulating layers 101 are repeated for the number of times equal to the number of approximately a half of the insulating layers 110A each. This forms the plurality of terrace portions TA corresponding to all the insulating layers 110A in the structure MLB₁ and the hole portions H₁ in the hook-up region R_{HU2}. Note that the removal of the insulating layers 110A and the removal of the insulating layers 101 are executed by means of dry etching or the like, for example.

Note that, in this process, the configuration in the edge regions R_{ED} is protected by the resist RG6. Accordingly, in the edge region R_{ED}, the configurations in the hook-up region R_{HU2}, between the regions R_{PNA}, and in the non-stacked body region R_{SN} stay in the states after the execution of the terrace portion formation process executed the second-to-last time.

Thereafter, the resists RG5, RG6 are removed.

Next, as illustrated in FIG. 50 and FIG. 51, the insulating layer 102 is formed on a front surface side of the structure illustrated in FIG. 48 and FIG. 49. This process is performed by CVD or the like, for example. Note that the insulating layer 102 fills the hole portions H₁, HA₁ in the hook-up region R_{HU2} to cover the plurality of terrace portions TA. The insulating layer 102 is also formed between the plane regions R_{PN}, between the regions R_{PNA}, and in the non-stacked body region R_{SN}.

Next, as illustrated in FIG. 52 and FIG. 53, a flattening process is performed on the configurations illustrated in FIG. 50 and FIG. 51 to remove a part of the insulating layer 102. This process is performed by Chemical Mechanical Polishing (CMP), for example.

Next, as illustrated in FIG. 54, resists 151, 152, 153, 154, 155 are formed on a front surface side of the insulating layer 102. Next, patterning is performed by means of photolithography or the like, and parts of the resists 151, 152, 153, 154, 155 are removed. For photolithography, for example, a method similar to the method described with reference to FIG. 31 and FIG. 32 is executed.

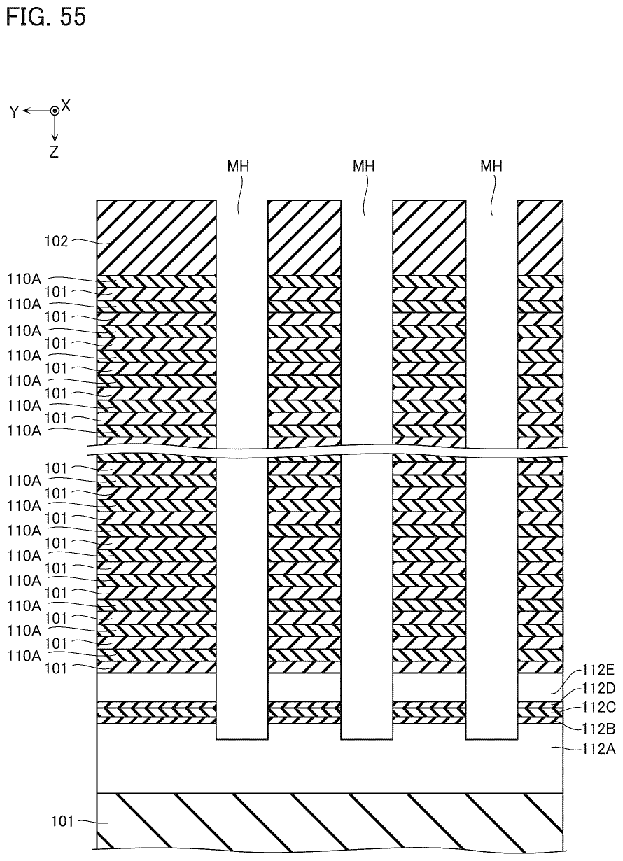

Next, as illustrated in FIG. 55, a plurality of memory holes MH are formed at positions corresponding to the plurality of semiconductor columns 120 described with reference to FIG. 8 to FIG. 10. While the illustration is omitted, a plurality of via holes are formed at positions corresponding to the plurality of supporting insulating member HR described with reference to FIG. 7, FIG. 13, and the like. These memory holes MH and via holes each extend in the Z-direction, penetrate the insulating layer 102, the insulating layers 101 and the insulating layers 110A, the semiconductor layer 112E, the insulating layers 112D, 112C, 112B, and expose the upper surface of the semiconductor layer 112A. This process is performed by a method of Reactive Ion Etching (RIE) or the like using the resists 151, 152, 153, 154, 155 as masks, for example.

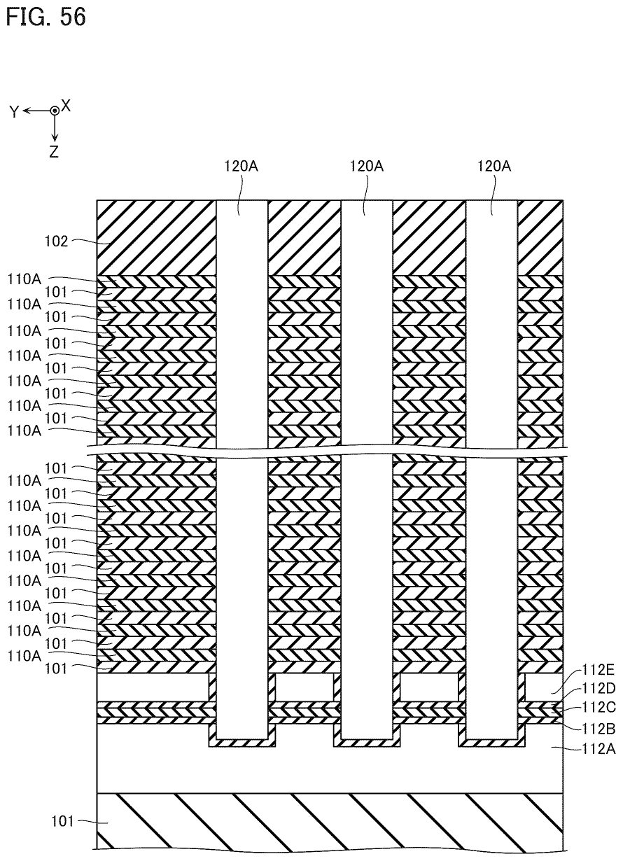

Next, for example, as illustrated in FIG. 56, the semiconductor layer 112A and the semiconductor layer 112E are selectively oxidized inside the plurality of memory holes MH and via holes. Sacrifice columns 120A of silicon (Si) or the like are formed inside the plurality of memory holes MH and via holes. This process is performed by a method such as CVD, for example.

Next, for example, as illustrated in FIG. 57, a structure MLB₂ is formed on the front surface side of the structure MLB₁. The structure MLB₂ includes those included in the structure ML₂ (FIG. 9) and the structure MLA₂ (FIG. 20) among the plurality of insulating layers 101 and those corresponding to the conductive layers 110 in the structures ML₂ and those included in the structure MLA₂ among the plurality of insulating layers 110A.

Next, processes similar to the processes described with reference to FIG. 30 to FIG. 53 are executed, and, as illustrated in FIG. 58 and FIG. 59, the plurality of terrace portions TA corresponding to the plurality of insulating layers 110A included in the structure MLB₂ are formed.

Note that, also in this process, the configurations in the hook-up region R_{HU2}, between the regions R_{PNA}, and the non-stacked body region R_{SN} stay in the states after the execution of the process executed the second-to-last time among the terrace portion formation processes corresponding to the structure MLB₂ in the edge region R_{ED}.

Next, a process approximately similar to the process described with reference to FIG. 54 to FIG. 56 is executed to form the sacrifice columns 120A of silicon (Si) or the like as illustrated in FIG. 60. Note that, while in the process described with reference to FIG. 56, the oxidation process corresponding to the semiconductor layer 112A and the semiconductor layer 112E is executed, no oxidation process corresponding to these is executed in the process corresponding to FIG. 60.

Next, for example, as illustrated in FIG. 61, a structure MLB₃ is formed on a front surface side of the structure MLB₂. The structure MLB₃ includes those included in the structure ML₃ (FIG. 9) and the structure MLA₃ (FIG. 20) among the plurality of insulating layers 101 and those corresponding to the conductive layers 110 in the structures ML₃ and those included in the structure MLA₃ among the plurality of insulating layers 110A.

Next, processes similar to the processes described with reference to FIG. 30 to FIG. 53 are executed to form the plurality of terrace portions TA corresponding to the plurality of insulating layers 110A included in the structure MLB₃ as illustrated in FIG. 62 and FIG. 63.

Note that, also in this process, the configurations in the hook-up region R_{HU2}, between the regions R_{PNA}, and the non-stacked body region R_{SN} stay in the states after the execution of the process executed the second-to-last time among the terrace portion formation processes corresponding to the structure MLB₃ in the edge region R_{ED}.

Next, a process approximately similar to the process described with reference to FIG. 54 and FIG. 55 is executed to form the plurality of memory holes MH and the via holes corresponding to supporting insulating members HR, as illustrated in FIG. 64.

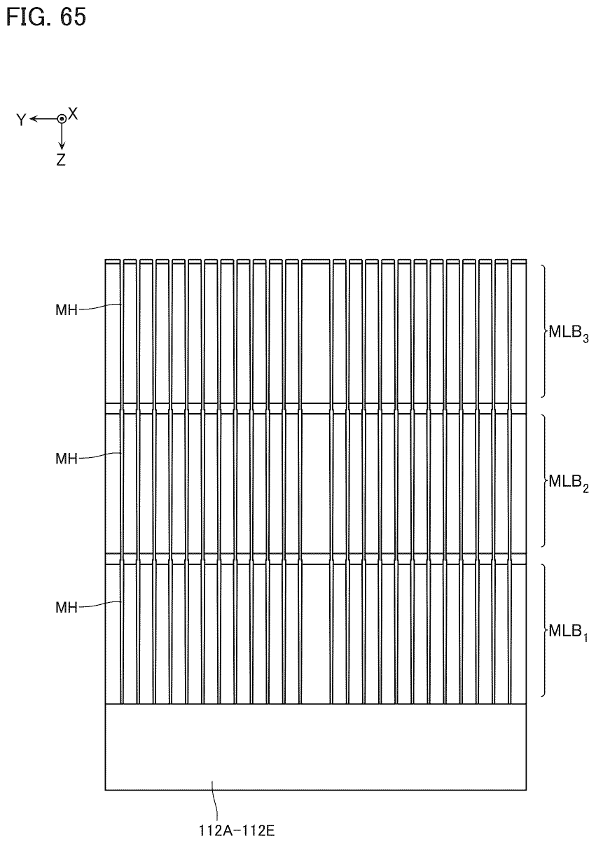

Next, as illustrated in FIG. 65, the sacrifice columns 120A in the structures MLA₁, MLA₂ are removed. This process is performed by wet etching or the like, for example.

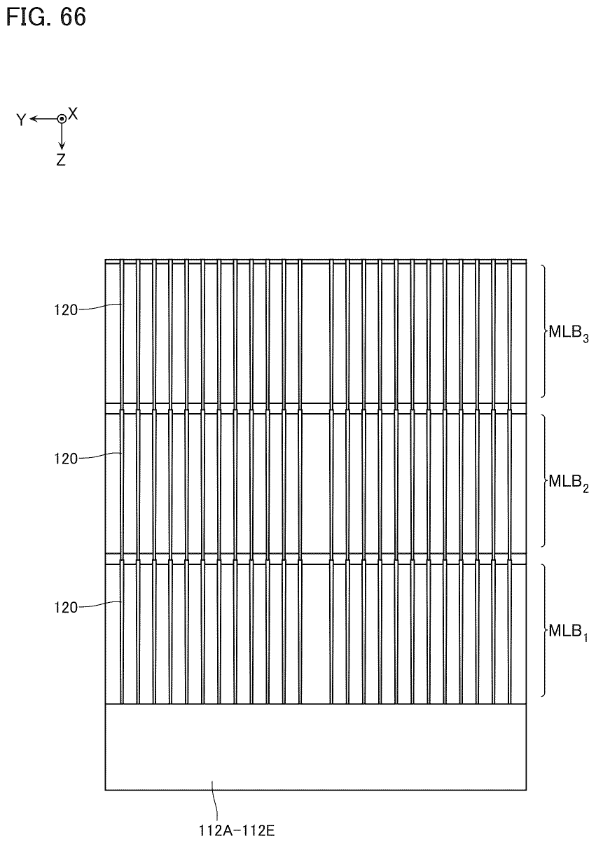

Next, for example, as illustrated in FIG. 66 and FIG. 67, the gate insulating films 130, the semiconductor columns 120, and the insulating columns 125 are formed inside the plurality of memory holes MH. This process is performed by CVD or the like, for example.

While the illustration is omitted, the supporting insulating members HR are formed inside the plurality of via holes corresponding to the plurality of supporting insulating members HR. This process is performed by CVD or the like, for example.

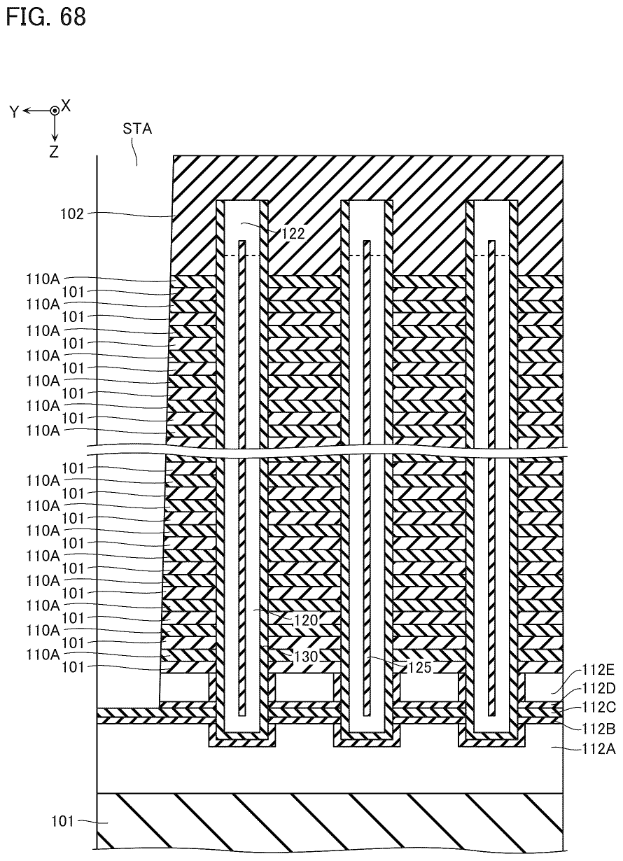

Next, for example, as illustrated in FIG. 68, the insulating layer 102 is further formed. This process is performed by a method such as CVD, for example.

Trenches STA are formed at positions corresponding to the inter-finger structures ST. The trench STA extends in the Z-direction and the X-direction, divides the insulating layer 102, the insulating layers 101 and the insulating layers 110A, the semiconductor layer 112E, and the insulating layer 112D in the Y-direction, and exposes the upper surface of the insulating layer 112C. This process is performed by a method such as RIE, for example.

Note that, in forming the trench STA, the resist is formed in the edge region R_{ED} as described with reference to FIG. 46 and FIG. 47. Accordingly, the trenches STA are formed only in the device region R_{DV} and not formed in the edge region R_{ED}.

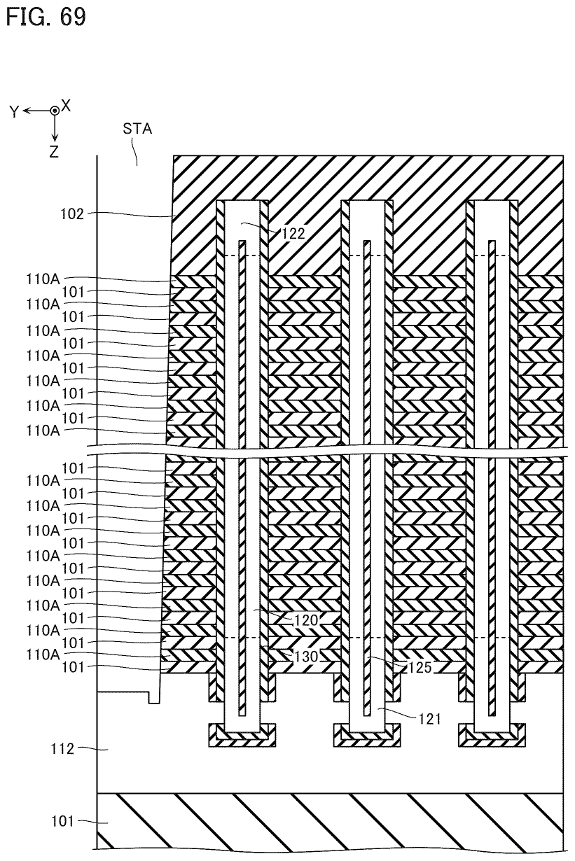

Next, for example, as illustrated in FIG. 69, the semiconductor layer 112 is formed. In this process, the insulating layers 112B, 112C, 112D are removed by a method such as wet etching, for example. Parts of the gate insulating films 130 are removed by a method such as wet etching or the like to expose outer circumferential surfaces of parts of the semiconductor columns 120. The semiconductor layer 112 is formed by a method such as epitaxial growth or the like.

Note that the trench STA is not formed in the edge region R_{ED} as described above. Accordingly, in the edge region R_{ED}, the semiconductor layer 112 is not formed and the semiconductor layer 112A, the insulating layers 112B, 112C, 112D, and the semiconductor layer 112E remain.

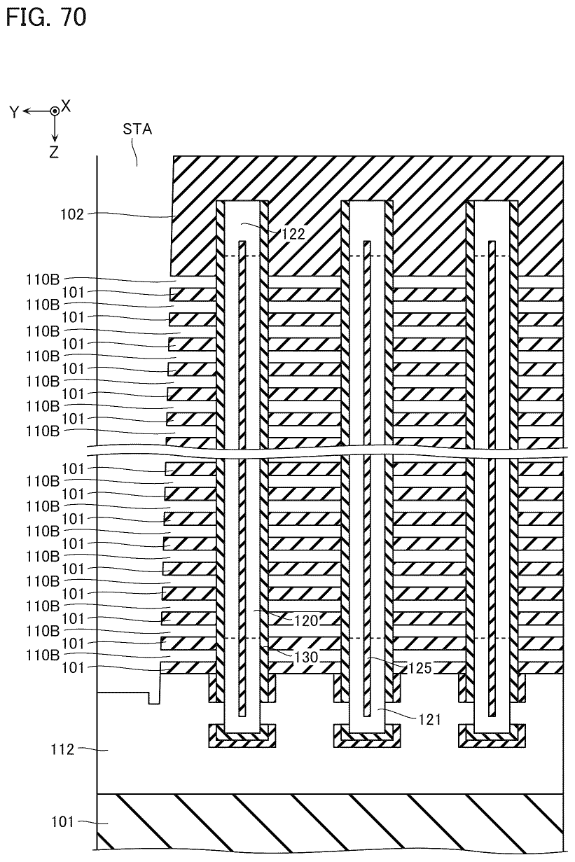

Next, for example, as illustrated in FIG. 70, the insulating layers 110A are removed via the trench STA. This forms a plurality of cavities 110B arranged in the Z-direction. In other words, a hollow structure including the plurality of insulating layers 101 arranged in the Z-direction and the structure supporting these insulating layers 101 is formed. The insulating layers 101 are supported by the structure in the memory hole MH (the semiconductor column 120, the gate insulating film 130, and the insulating column 125) in the memory region R_{MH}. The insulating layers 101 are supported by the supporting insulating members HR in the hook-up regions R_{HU1}, R_{HU2}. This process is performed by a method such as wet etching, for example.

Note that, as described above, the trench STA is not formed in the edge region R_{ED}. Accordingly, in the edge region R_{ED}, the insulating layers 110A are not removed and no cavity 110B is formed.

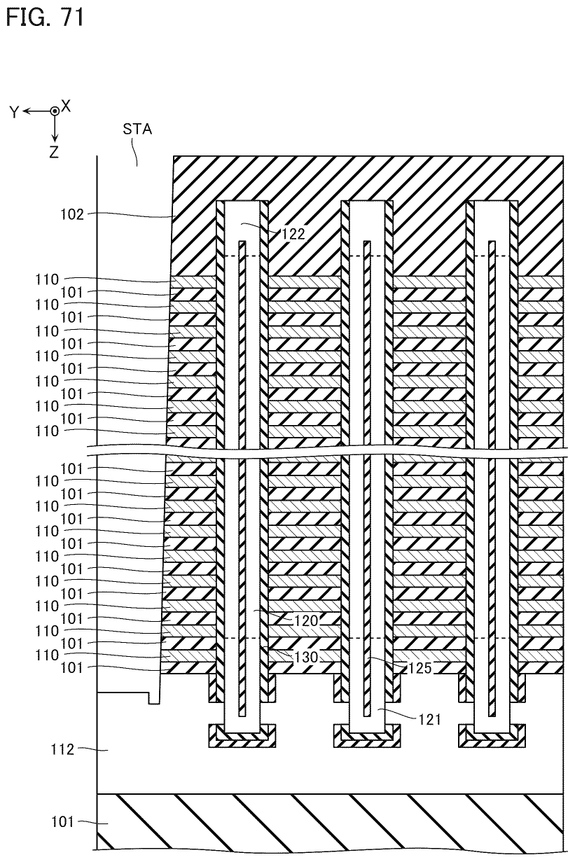

Next, for example, as illustrated in FIG. 71, the plurality of conductive layers 110 are formed in the plurality of cavities 110B arranged in the Z-direction. This process is performed by a method such as CVD, for example.

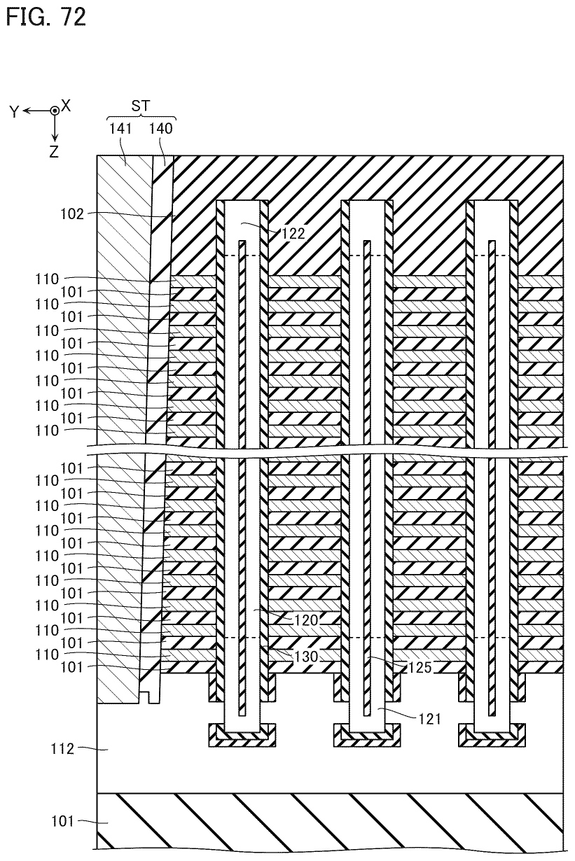

Next, for example, as illustrated in FIG. 72, the inter-finger structure ST is formed inside the trench STA. This process is performed by CVD or the like, for example.

Thereafter, the inter-string unit insulating member SHE described with reference to FIG. 8 to FIG. 10, and the like, the via-contact electrode CC described with reference to FIG. 7, FIG. 13, and the like, the via-contact electrodes Ch, Vy and the bit line BL described with reference to FIG. 8 to FIG. 10, the bonding electrode P_{I2} described with reference to FIG. 12, and the like are formed to form the configurations in the wafer W_{M}, and the wafer W_{M} and the wafer W_{P} are bonded together, thus, the semiconductor memory device according to the first embodiment is formed.

### Comparative Example

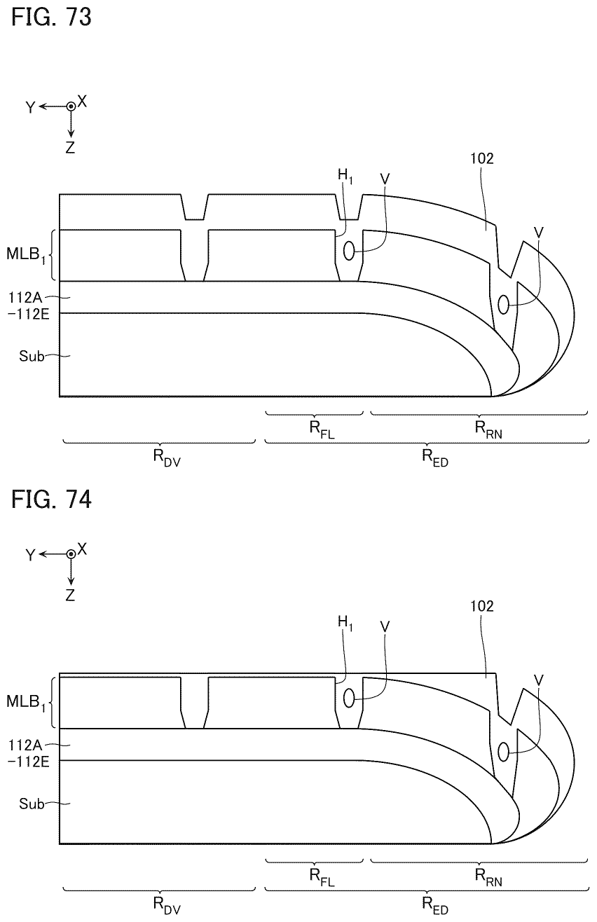

FIG. 73 to FIG. 76 are schematic cross-sectional views for describing a semiconductor memory device according to a comparative example. FIG. 73 to FIG. 76 illustrate a substrate Sub.

In the manufacture of the semiconductor memory device according to the comparative example, the process described with reference to FIG. 46 and FIG. 47 in forming the plurality of terrace portions TA corresponding to the insulating layers 110A in the structures MLB₁, MLB₂, MLB₃ is not executed.

Accordingly, in the comparative example, after the execution of the process described with reference to FIG. 48 and FIG. 49, the plurality of terrace portions TA corresponding to all the insulating layers 110A in the structure MLB₁ and the hole portions H₁ are formed in the hook-up region R_{HU2} also in the edge region R_{ED}. Between the regions R_{PNA}, all the insulating layers 110A are divided in the X-direction and the Y-direction. In the non-stacked body region R_{SN}, all the insulating layers 110A are removed.

Also in the process corresponding to FIG. 58 and FIG. 59, the plurality of terrace portions TA corresponding to all the insulating layers 110A in the structure MLB₂ and the hole portions H₂ are formed in the hook-up region R_{HU2} in the edge region R_{ED}. Between the regions R_{PNA}, all the insulating layers 110A are divided in the X-direction and the Y-direction. In the non-stacked body region R_{SN}, all the insulating layers 110A are removed.

Also in the process corresponding to FIG. 62 and FIG. 63, the plurality of terrace portions TA corresponding to all the insulating layers 110A in the structure MLB₃ and the hole portions H₃ are formed in the hook-up region R_{HU2} in the edge region R_{ED}. Between the regions R_{PNA}, all the insulating layers 110A are divided in the X-direction and the Y-direction. In the non-stacked body region R_{SN}, all the insulating layers 110A are removed.

Here, in the process described with reference to FIG. 50 and FIG. 51 and the like, the hole portions H₁ are filled with the insulating layer 102. In this process, embeddability in the edge region R_{ED} may be poorer than embeddability in the device region R_{DV} depending on the characteristics of the film formation device of CVD or the like, which may form cavities V in the hole portions H₁ as exemplarily illustrated in FIG. 73 and possibly cause a crack or the like.

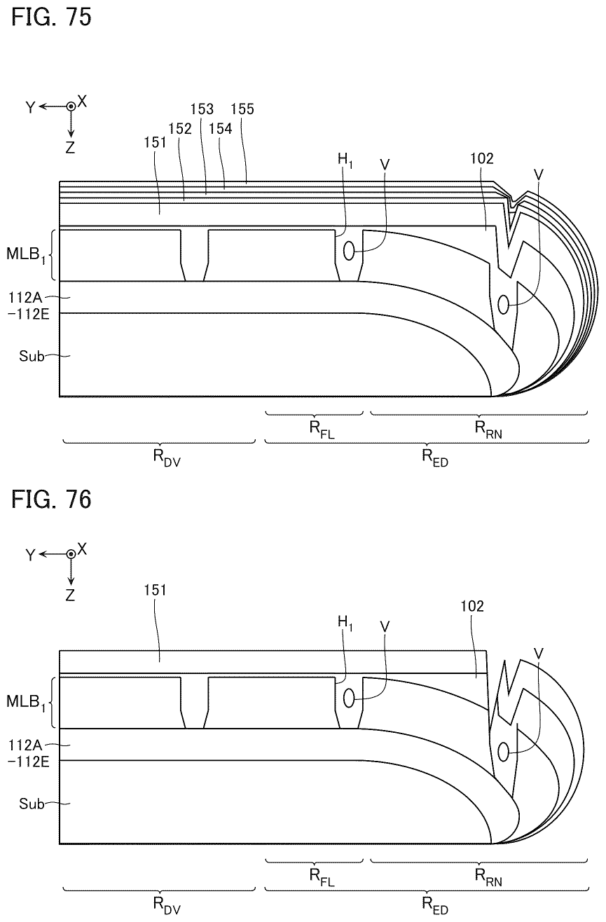

For example, as illustrated in FIG. 51, if unevenness is formed on the upper surface of the insulating layer 102, this unevenness possibly remains in the round region R_{RN} as illustrated in FIG. 74 after the execution of the flattening process described with reference to FIG. 52 and FIG. 53. If the resists 151, 152, 153, 154, 155 are formed on such an uneven portion in the process described with reference to FIG. 54 and the like, parts of the resists 151, 152, 153, 154, 155 become thin at a corner portion, for example, as illustrated in FIG. 75. If the process described with reference to FIG. 55 and the like are executed in this state, as illustrated in FIG. 76, an erroneous formation may occur.

### Effects of First Embodiment

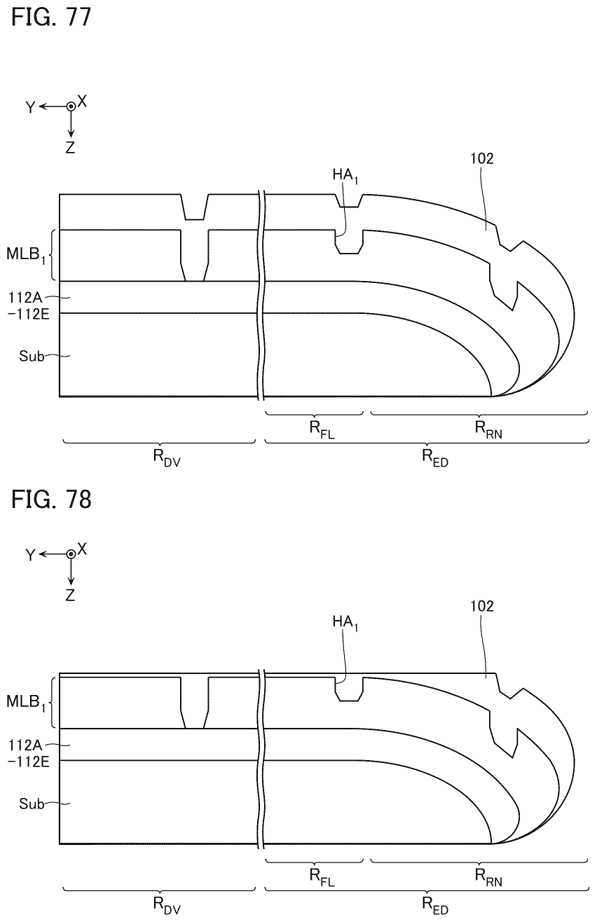

FIG. 77 to FIG. 79 are schematic cross-sectional views for describing the semiconductor memory device according to the first embodiment. FIG. 77 to FIG. 79 illustrate the substrate Sub.

In this embodiment, the configurations in the edge region R_{ED} are protected by the resist RG6 in the process described with reference to FIG. 48 and FIG. 49 (the process executed the last among the terrace portion formation processes corresponding to the structure MLB₁). Accordingly, in the edge region R_{ED}, the configurations in the hook-up region R_{HU2}, between the regions R_{PNA}, and in the non-stacked body region R_{SN} stay in the states after the execution of the process executed the second-to-last time among the terrace portion formation processes corresponding to the structure MLB₁. As the result, as illustrated in FIG. 77, the comparatively shallow hole portions HA₁ are formed in the edge region R_{ED}, and therefore, the formation of the insulating layer 102 without generating the cavities V is relatively easy.

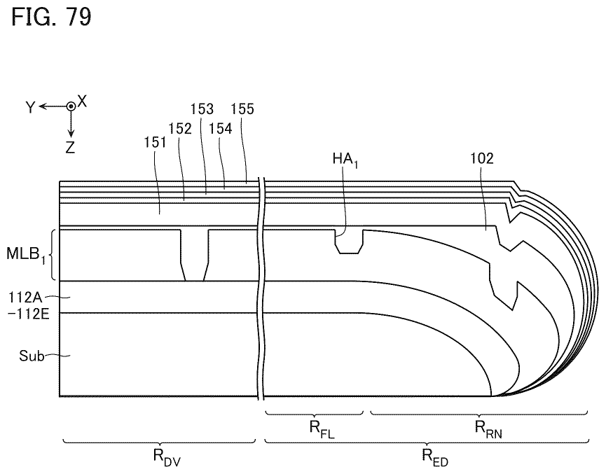

The comparatively shallow hole portions HA₁ are formed in the edge region R_{ED}, and therefore, as illustrated in FIG. 78, the unevenness on the upper surface of the insulating layer 102 remaining in the round region R_{RN} after the execution of the flattening process described with reference to FIG. 52 and FIG. 53 can be made relatively gradual. As the result, as illustrated in FIG. 79, the resists 151, 152, 153, 154, 155 can be formed relatively uniformly, which allows reduction in the erroneous formation described above.

### Second Embodiment

In the first embodiment, the configurations in the edge region R_{ED} are protected by the resist RG6 in the process executed the last among the terrace portion formation processes corresponding to the structure MLB₁. On the other hand, the configurations in the edge region R_{ED} are not protected by the resist RG6 from the process executed the first till the process executed the second-to-last time among the terrace portion formation processes corresponding to the structure MLB₁. The same applies to the terrace portion formation processes corresponding to the structure MLB₂, the structure MLB₃.

However, such a method is merely an example, and it is appropriately adjustable which terrace portion formation process includes the protection of the configurations in the edge region R_{ED}.

Here, as described with reference to FIG. 36 to FIG. 45, FIG. 48, and FIG. 49, the process executed later among the terrace portion formation processes corresponding to the structure MLB₁ removes more insulating layers 110A, 101, and therefore, the hole portions HA₁ are formed more deeply. In order to reduce the number of manufacturing processes, it is more preferred that the number of execution of the processes described with reference to FIG. 46 and FIG. 47 (the processes of applying the resist RG6) is less. With such a reason, with the manufacturing method according to the first embodiment, while the number of execution of the processes of applying the resist RG6 is reduced, the hole portions HA₁ filled with the insulating layer 102 can be efficiently shallowed.

However, depending on the depth and the Y-direction width of the hole portion HA₁, the embeddability of the insulating layer 102, and the like, it is sometimes preferred that the process of applying the resist RG6 is executed, for example, also in the process executed the second-to-last time and in other terrace portion formation processes, not only in the process executed the last, among the terrace portion formation processes corresponding to the structure MLB₁. It is also allowed that the process of applying the resist RG6 is executed in all the terrace portion formation processes.

A manufacturing example of executing the process of applying the resist RG6 in all the terrace portion formation processes is described as a semiconductor memory device according to a second embodiment. In the following description, the parts similar to those in the first embodiment are attached by the same reference numerals to omit the descriptions.

The semiconductor memory device according to the second embodiment is basically formed similarly to the semiconductor memory device according to the first embodiment. However, configurations in the edge region R_{ED} of the semiconductor memory device according to the second embodiment differ from the configurations in the edge region R_{ED} of the semiconductor memory device according to the first embodiment.

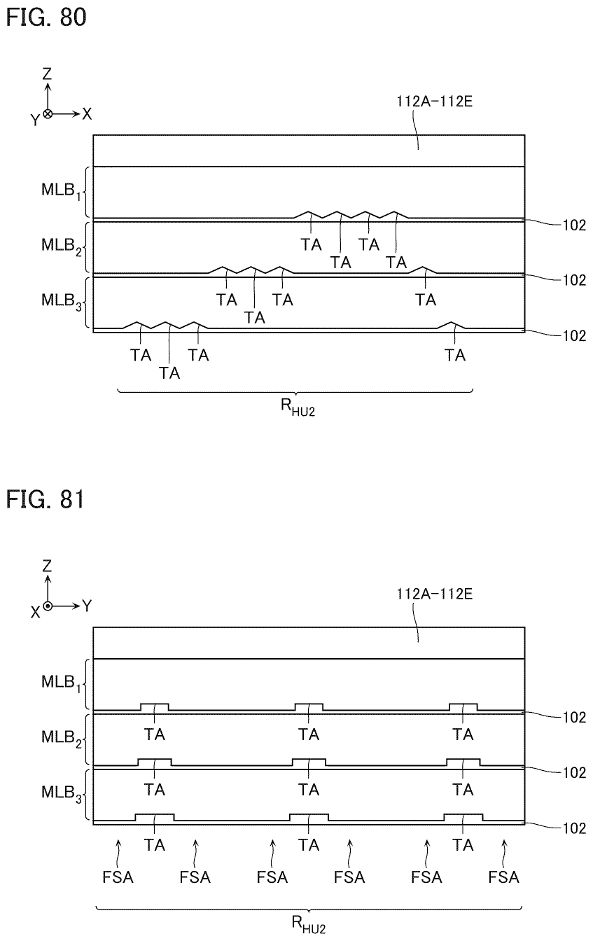

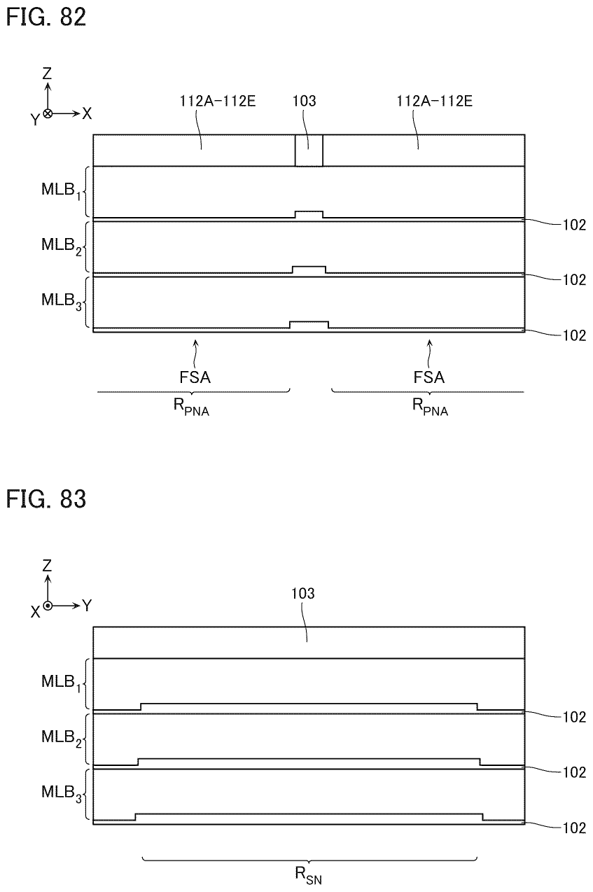

FIG. 80 to FIG. 83 are schematic cross-sectional views illustrating a part of the configuration of the semiconductor memory device according to the second embodiment. FIG. 80 to FIG. 83 illustrate respective cross-sectional surfaces of portions corresponding to FIG. 23 to FIG. 26.

As described above, in manufacturing the semiconductor memory device according to the second embodiment, the process of applying the resist RG6 is executed in all the terrace portion formation process. Accordingly, the configurations in the hook-up region R_{HU2}, between the regions R_{PNA}, and in the non-stacked body region R_{SN} stay in the states before the execution of the terrace portion formation process in the edge region R_{ED}. For example, while the plurality of terrace portions TA as exemplarily illustrated in FIG. 35 are provided in the hook-up region R_{HU2}, no hole portion HA₁ is formed.

### Third Embodiment

As described with reference to FIG. 27, in the first embodiment, the insulating layers 110A, 101 in the structures MLA₁, MLA₂, MLA₃ reach the round region R_{RN}. However, such a configuration is merely an example, and the specific configuration is adjustable as appropriate. For example, in the process described with reference to FIG. 30 to FIG. 35 and the terrace portion formation processes, the insulating layers 110A, 101 in the structures MLA₁, MLA₂, MLA₃ may be removed in the round region R_{RN} and the proximity thereof. Such a process is hereinafter referred to as an edge cut.

An example of performing the edge cut in the terrace portion formation process or the like is described as a semiconductor memory device according to a third embodiment. In the following description, the parts similar to those in the first embodiment are attached by the same reference numerals to omit the descriptions.

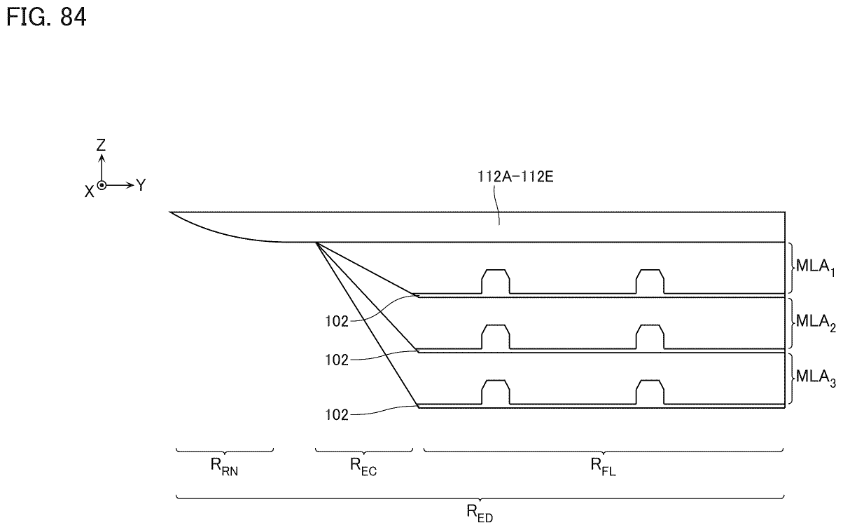

FIG. 84 is a schematic cross-sectional view illustrating a part of the configuration of the semiconductor memory device according to the third embodiment. The semiconductor memory device according to third embodiment is basically configured similarly to the semiconductor memory device according to the first embodiment.

However, in the third embodiment, as illustrated in FIG. 84, the insulating layers 110A, 101 in the structures MLA₁, MLA₂, MLA₃ do not reach the round region R_{RN}. The edge region R_{ED} according to the third embodiment includes an edge cut region R_{EC} provided between the flat region R_{FL} and the round region R_{RN}. The edge cut region R_{EC} is provided with the end portions at a wafer W_{M} outer edge side of the insulating layers 110A, 101 in the structures MLA₁, MLA₂, MLA₃.

### Fourth Embodiment

As described with reference to FIG. 46 and FIG. 47, in the first embodiment, the configurations in the edge region R_{ED} are protected by the resist RG6 in the terrace portion formation process. However, such a method is merely an example, and the method of protecting the configurations in the edge region R_{ED} in the terrace portion formation process is appropriately adjustable. For example, the configurations in the edge region R_{ED} may be protected by using a resist applied in the terrace portion formation process, such as the resist RG5 described with reference to FIG. 44 and FIG. 45.

An example of protecting the configurations in the edge region R_{ED} using the resist RG5 is described as a semiconductor memory device according to a fourth embodiment. In the following description, the parts similar to those in the first embodiment are attached by the same reference numerals to omit the descriptions.

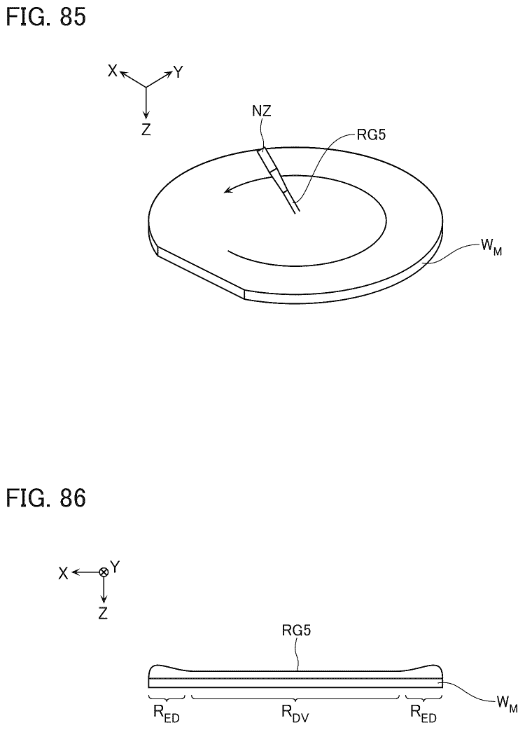

FIG. 85 is a schematic perspective view for describing a manufacturing method according to the fourth embodiment. FIG. 86 is a schematic cross-sectional view for describing the same manufacturing method.

The manufacturing method according to the fourth embodiment is basically executed similarly to the manufacturing method according to the first embodiment.

However, in the manufacturing method according to the fourth embodiment, the method for forming the resist RG5 described with reference to FIG. 44 and FIG. 45 differs from that of the first embodiment. That is, the resist RG5 is, for example, applied in a center portion of the wafer W_{M} with the wafer W_{M} being rotated as illustrated in FIG. 85.

Here, in the first embodiment, the wafer W_{M} is rotated at a relatively high speed. This allows the resist RG5 to be applied with a relatively uniform film thickness on the wafer W_{M}.

On the other hand, in the fourth embodiment, the wafer W_{M} is rotated at a relatively low speed. For example, the wafer W_{M} is rotated at a speed at which the film thickness in the edge region R_{ED} of the resist RG5 is sufficiently thicker than the film thickness in the device region R_{DV} as illustrated in FIG. 86.

Subsequently, patterning is performed by means of photolithography or the like and parts of the resist is removed.

Here, in the first embodiment, the resist RG5 has the relatively uniform film thickness, and therefore, the resist RG5 is removed corresponding to the shot pattern SP (FIG. 31, FIG. 32) over the entire surface of the wafer W_{M}.

On the other hand, in the fourth embodiment, the film thickness in the edge region R_{ED} of the resist RG5 is thicker than the film thickness in the device region R_{DV}. Therefore, only a front surface of the resist RG5 is exposed in the edge region R_{ED}, and thus, the resist RG5 is not removed in the edge region R_{ED}. Accordingly, in the method according to the fourth embodiment, it is possible that the configurations in the edge region R_{ED} is protected by using the resist applied in the terrace portion formation process, such as the resist RG5.

Note that such a method is employable for the application of a resist corresponding to any terrace portion formation process.

In the fourth embodiment, the process described with reference to FIG. 46 and FIG. 47 is not executed. Accordingly, the number of manufacturing processes can be reduced.

### Fifth Embodiment

In the first embodiment, the processes of forming the structures MLB₁, MLB₂, MLB₃ and a plurality of times of the terrace portion formation processes are alternately executed. That is, the structure MLB₁ is formed as described with reference to FIG. 28 and FIG. 29, and the plurality of times of terrace portion formation processes are executed as described with reference to FIG. 36 to FIG. 53. Next, the structure MLB₂ is formed as described with reference to FIG. 57, and the plurality of times of terrace portion formation processes are executed as described with reference to FIG. 58 and FIG. 59. Next, the structure MLB₃ is formed as described with reference to FIG. 61, and the plurality of times of terrace portion formation processes are executed as described with reference to FIG. 62 and FIG. 63.

However, such a method is merely an example, and it is allowed to collectively execute the plurality of times of terrace portion formation processes corresponding to these plurality of structures MLB₁, MLB₂, MLB₃ after forming the plurality of structures MLB₁, MLB₂, MLB₃.

A manufacturing example in which the plurality of times of terrace portion formation processes corresponding to all of these structures MLB₁, MLB₂, MLB₃ are collectively executed after forming all the structures MLB₁, MLB₂, MLB₃ is described as a semiconductor memory device according to a fifth embodiment.

In manufacturing the semiconductor memory device according to the fifth embodiment, for example, the process described with reference to FIG. 28 and FIG. 29 is executed, the processes described with reference to FIG. 30 to FIG. 53 are not executed, the processes described with reference to FIG. 54 to FIG. 57 are executed, the process described with reference to FIG. 58 and FIG. 59 is not executed, and the process described with reference to FIG. 60 and FIG. 61 is executed. Next, the processes described with reference to FIG. 30 to FIG. 35 are executed, the plurality of times of terrace portion formation processes corresponding to all the structures MLB₁, MLB₂, MLB₃ are executed. Thereafter, the processes after the process described with reference to FIG. 64 are executed.

It is appropriately adjustable which terrace portion formation process includes the protection of the configurations in the edge region R_{ED} among the plurality of times of terrace portion formation processes corresponding to all the above-described structures MLB₁, MLB₂, MLB₃. The following description describes an example of protecting the configurations in the edge region R_{ED} by the resist RG6 in the process executed the last among the plurality of times of the terrace portion formation processes corresponding to all the structures MLB₁, MLB₂, MLB₃.

The semiconductor memory device according to the fifth embodiment is basically formed similarly to the semiconductor memory device according to the first embodiment. However, configurations in the edge region R_{ED} of the semiconductor memory device according to the fifth embodiment differs from the configurations in the region R_{ED} of the semiconductor memory device according to the first embodiment.

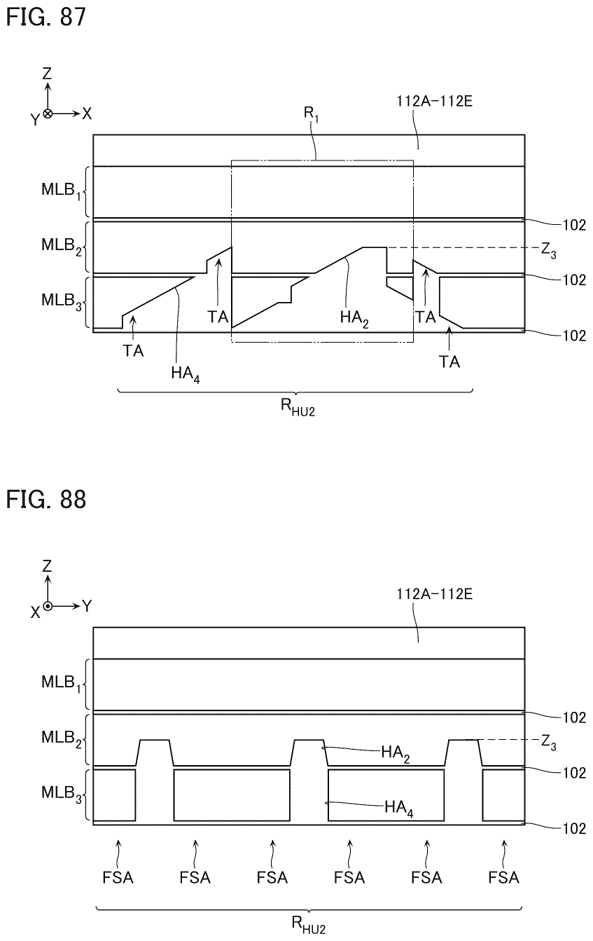

FIG. 87 to FIG. 90 are schematic cross-sectional views illustrating a part of the configuration of the semiconductor memory device according to the fifth embodiment. FIG. 87 to FIG. 90 illustrate respective cross-sectional surfaces of the portions corresponding to FIG. 23 to FIG. 26. Note that, in the following description, the parts similar to those in the first embodiment are attached by the same reference numerals to omit the descriptions.

As illustrated in FIG. 87 and FIG. 88, in the hook-up region R_{HU2} in the edge region R_{ED} of the semiconductor memory device according to the embodiment, all the insulating layers 110A in the structure MLB₃ and approximately a half of the insulating layers 110A in the structure MLB₂ provided below a height position Z₃ include respective terrace portions TA. These plurality of terrace portions TA do not overlap with another insulating layer 110A viewing from below. On the other hand, the rest of the insulating layers 110A in the structure MLB₂ provided above the height position Z₃ and all the insulating layers 110A in the structure MLB₁ do not include the terrace portion TA. These plurality of insulating layers 110A each extend in the X-direction and the Y-direction above the insulating layers 102 in the structures MLB₂, MLB₃.

In the illustrated example, the structure MLB₃ is provided with a hole portion HA₄ penetrating the stacked structure formed of the plurality of insulating layers 110A and the plurality of insulating layers 101. The structure MLB₂ is provided with the hole portions HA₂ not penetrating the stacked structure formed of the plurality of insulating layers 110A and the plurality of insulating layers 101. The structure MLB₁ is not provided with the hole portion HA₁(FIG. 23). A part of the hole portion HA₄ is configured of the terrace portions TA. The hole portion HA₄ is filled with a part of the insulating layer 102.

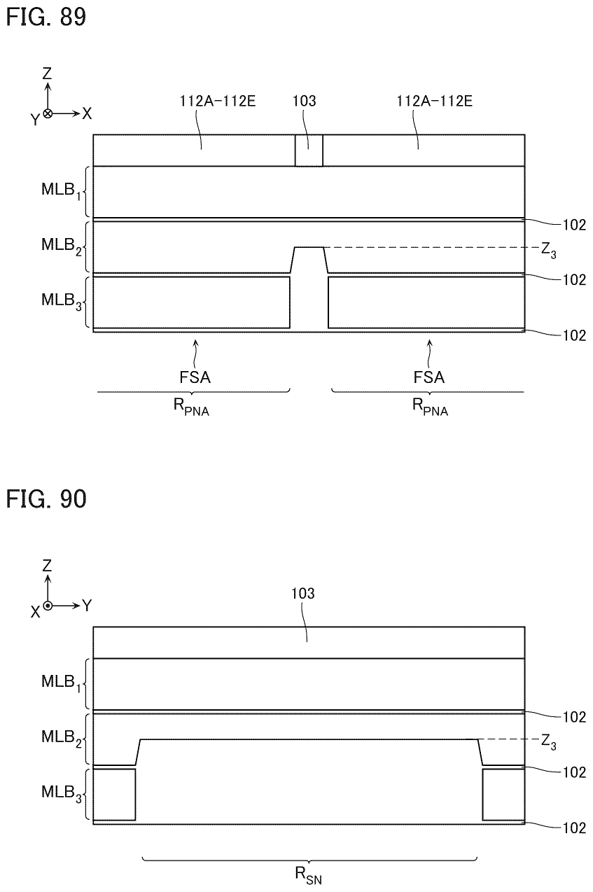

As illustrated in FIG. 89, between the regions R_{PNA} in the edge region R_{ED} of the semiconductor memory device according to the embodiment, all the insulating layers 110A in the structure MLB₃ and approximately a half of the insulating layers 110A in the structure MLB₂ provided below the height position Z₃ are each divided via the insulating layer 102 between two regions R_{PNA} adjacent in the X-direction or the Y-direction. On the other hand, the rest of the insulating layers 110A in the structure MLB₂ provided above the height position Z₃ and all the insulating layers 110A in the structure MLB₁ continue between two regions R_{PNA} adjacent in the X-direction or the Y-direction and each extend in the X-direction and the Y-direction above the insulating layer 102 in the structures MLB₂, MLB₃.

That is, in this embodiment, the structure MLB₃ does not include the insulating layers 110A continuing between two regions R_{PNA} adjacent in the X-direction or the Y-direction. The structure MLB₁ does not include the insulating layers 110A divided via the insulating layer 102 between two regions R_{PNA} adjacent in the X-direction or the Y-direction.

As illustrated in FIG. 90, in the non-stacked body region R_{SN} in the edge region R_{ED} of the semiconductor memory device according to the embodiment, all the insulating layers 110A in the structure MLB₃ and approximately a half of the insulating layers 110A in the structure MLB₂ provided below the height position Z₃ are each removed in the non-stacked body region R_{SN}, and the region in which the insulating layers 110A are removed is provided with the insulating layer 102. On the other hand, the rest of the insulating layers 110A in the structure MLB₂ provided above the height position Z₃ and all the insulating layers 110A in the structure MLB₁ are not removed in the non-stacked body region R_{SN}, and each extend in the X-direction and the Y-direction above the insulating layers 102 in the structures MLB₂, MLB₃.

### OTHER EMBODIMENTS

The semiconductor memory devices according to the first embodiment to the fifth embodiment have been described above. However, the configurations described above are merely examples and the specific configurations are appropriately adjustable.

For example, in the above-described embodiments, the plurality of die regions R_{MD} in the device region R_{DV} are provided with the plurality of conductive layers 110 and the plurality of insulating layers 101 alternately arranged in the Z-direction as described above. The stacked body region R_{SS} in the device region R_{DV}, and the plurality of die regions R_{MD}, the stacked body region R_{SS}, the non-stacked body region R_{SN}, and the like in the edge region R_{ED} (hereinafter referred to as “the plurality of die regions R_{MD} and the like in the edge region R_{ED}”) are provided with the plurality of insulating layers 110A and the plurality of insulating layers 101 alternately arranged in the Z-direction.

Here, in the process described with reference to FIG. 70, the plurality of insulating layers 110A arranged in the Z-direction are removed, and the plurality of cavities 110B arranged in the Z-direction are formed. In the process described with reference to FIG. 71, the plurality of conductive layers 110 arranged in the Z-direction are formed in the plurality of cavities 110B arranged in the Z-direction. Accordingly, the plurality of conductive layers 110 arranged in the Z-direction in the plurality of die regions R_{MD} in the device region R_{DV} and a plurality of layers arranged in the Z-direction corresponding to the plurality of conductive layers 110 in the plurality of die regions R_{MD} and the like in the edge region R_{ED} (hereinafter referred to as “first layers”) include different materials.

On the other hand, the above-described embodiments do not remove the plurality of insulating layers 101 arranged in the Z-direction to form the plurality of cavities arranged in the Z-direction or do not form a plurality of other layers arranged in the Z-direction in these plurality of cavities. Accordingly, the plurality of insulating layers 101 arranged in the Z-direction in the plurality of die regions R_{MD} in the device region R_{DV} and a plurality of layers arranged in the Z-direction corresponding to the plurality of insulating layers 101 in the plurality of die regions R_{MD} and the like in the edge region R_{ED} (hereinafter referred to as “second layers”) include the same materials.

However, such a configuration is merely an example, and is appropriately changeable. For example, the first layer may contain a material similar to that of the conductive layer 110. The second layer may contain a material different from that of the insulating layer 101. The conductive layer 110 may, for example, include a metal oxide film around the barrier conductive film. In the plurality of die regions R_{MD} in the device region R_{D}V, the conductive layers 110 alternately arranged in the Z-direction with the insulating layers 101 may be regarded to be a configuration including such a metal oxide film.

### OTHERS

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a first wafer including a plurality of die regions arranged in a first direction and a second direction intersecting with the first direction;
a plurality of conductive layers and a plurality of insulating layers provided in a device region on the first wafer outside of a predetermined distance range from an outer edge of the first wafer, and alternately stacked in a stacking direction intersecting with the first direction and the second direction; and
a plurality of first layers and a plurality of second layers provided in an edge region on the first wafer within the predetermined distance range from the outer edge of the first wafer, the plurality of first layers being arranged in the stacking direction corresponding to the plurality of conductive layers, the plurality of second layers being arranged in the stacking direction corresponding to the plurality of insulating layers, wherein
a plurality of first die regions positioned within the device region among the plurality of die regions include respective terrace regions in which a part of the plurality of conductive layers are provided and the other part of the plurality of conductive layers are not provided, and
a first number of the plurality of first layers arranged in the stacking direction at positions within a plurality of second die regions among the plurality of die regions corresponding to positions at which the respective plurality of first die regions include at least partial region of the terrace regions within a region in which the plurality of second die regions overlap with the edge region when viewed in the stacking direction is greater than a second number of the plurality of conductive layers provided at the positions at which the respective plurality of first die regions include the at least partial region of the terrace regions and arranged in the stacking direction.

2. The semiconductor device according to claim 1, wherein
the plurality of first die regions include:
semiconductor columns extending in the stacking direction and opposed to the plurality of conductive layers; and
electric charge accumulating films provided between the plurality of conductive layers and the semiconductor columns.

3. The semiconductor device according to claim 1, wherein
each of the plurality of first die regions includes:
a first semiconductor column and a second semiconductor column spaced in the first direction, extending in the stacking direction, and each opposed to the plurality of conductive layers;
a first electric charge accumulating film provided between the plurality of conductive layers and the first semiconductor column; and
a second electric charge accumulating film provided between the plurality of conductive layers and the second semiconductor column, and
at least a part of the plurality of conductive layers in each of the plurality of first die regions include:
a first electrode portion opposed to the first semiconductor column;
a second electrode portion opposed to the second semiconductor column;
a terrace portion provided in the terrace region between the first electrode portion and the second electrode portion; and
a connecting portion provided between the first electrode portion and the second electrode portion, arranged with the terrace portion in the second direction, and connecting the first electrode portion to the second electrode portion.

4. The semiconductor device according to claim 1, wherein
a first structure and a second structure arranged in the stacking direction are provided in the device region,
the first structure includes a part of the plurality of conductive layers and a part of the plurality of insulating layers alternately stacked in the stacking direction, and a first sub semiconductor column extending in the stacking direction and opposed to the part of the plurality of conductive layers,
the second structure includes another part of the plurality of conductive layers and another part of the plurality of insulating layers alternately stacked in the stacking direction, and a second sub semiconductor column extending in the stacking direction, opposed to the another part of the plurality of conductive layers, and electrically connected to the first sub semiconductor column,
the edge region is provided with:
a third structure including a part of the plurality of first layers corresponding to the part of the plurality of conductive layers and a part of the plurality of second layers corresponding to the part of the plurality of insulating layers; and
a fourth structure including another part of the plurality of first layers corresponding to the another part of the plurality of conductive layers and another part of the plurality of second layers corresponding to the another part of the plurality of insulating layers,
terrace portions of the part of the plurality of conductive layers and the another part of the plurality of conductive layers provided in the terrace region do not overlap with any of the plurality of conductive layers when viewed from one side in the stacking direction, and
terrace portions of the part of the plurality of first layers provided at the positions within the plurality of second die regions overlap with any of the layers of the another part of the plurality of first layers when viewed from the one side in the stacking direction.

5. The semiconductor device according to claim 1, wherein
a first structure and a second structure arranged in the stacking direction are provided in the device region,
the first structure includes a part of the plurality of conductive layers and a part of the plurality of insulating layers alternately stacked in the stacking direction, and a first sub semiconductor column extending in the stacking direction and opposed to the part of the plurality of conductive layers,
the second structure includes another part of the plurality of conductive layers and another part of the plurality of insulating layers alternately stacked in the stacking direction, and a second sub semiconductor column extending in the stacking direction, opposed to the another part of the plurality of conductive layers, and electrically connected to the first sub semiconductor column,
the edge region is provided with:
a third structure including a part of the plurality of first layers corresponding to the part of the plurality of conductive layers and a part of the plurality of second layers corresponding to the part of the plurality of insulating layers; and
a fourth structure including another part of the plurality of first layers corresponding to the another part of the plurality of conductive layers and another part of the plurality of second layers corresponding to the another part of the plurality of insulating layers,
terrace portions of the part of the plurality of conductive layers and the another part of the plurality of conductive layers provided in the terrace region do not overlap with any of the plurality of conductive layers when viewed from one side in the stacking direction, and
terrace portions of the part of the plurality of first layers and the another part of the plurality of first layers provided at the position within the plurality of second die regions do not overlap with any of the plurality of first layers when viewed from the one side in the stacking direction.

6. The semiconductor device according to claim 1, wherein
the edge region includes:
a flat region provided outside of another predetermined distance range from the outer edge of the first wafer; and
a round region provided within the another predetermined distance range from the outer edge of the first wafer, and
the plurality of first layers and the plurality of second layers reach the round region.

7. The semiconductor device according to claim 1, wherein
the edge region includes:
a flat region provided outside of another predetermined distance range from the outer edge of the first wafer; and
a round region provided within the another predetermined distance range from the outer edge of the first wafer, and
the plurality of first layers and the plurality of second layers do not reach the round region.

8. The semiconductor device according to claim 1, wherein
the first wafer includes a plurality of first bonding electrodes, and
the device further comprises a second wafer including a plurality of second bonding electrodes bonded to the plurality of first bonding electrodes.

9. The semiconductor device according to claim 1, wherein
each of the plurality of first die regions includes a first plane region and a second plane region arranged in the first direction or the second direction, each of the first plane region and the second plane region including a plurality of finger structures and a plurality of inter-finger structures alternately arranged in the second direction, and a source line provided at a position overlapping with the plurality of finger structures and the plurality of inter-finger structures when viewed in the stacking direction,
each of the plurality of finger structures includes the plurality of conductive layers and the plurality of insulating layers, and a plurality of semiconductor columns extending in the stacking direction, opposed to the plurality of conductive layers, and connected in common to the source line,
the plurality of conductive layers, the plurality of insulating layers, and the source line are divided in the first direction or the second direction between the first plane region and the second plane region,
respective positions within the plurality of second die regions corresponding to positions at which the respective plurality of first die regions include the first plane region and the second plane region within the region in which the plurality of second die regions overlap with the edge region when viewed in the stacking direction are a first region and a second region,
the first region and the second region include the plurality of first layers and the plurality of second layers, respectively, and
at least a part of the plurality of first layers and the plurality of second layers continue between the first region and the second region.

10. The semiconductor device according to claim 9, wherein
each of the first plane region and the second plane region includes:
a first structure including a part of the plurality of conductive layers and a part of the plurality of insulating layers alternately stacked in the stacking direction, and a first sub semiconductor column extending in the stacking direction and opposed to the part of the plurality of conductive layers; and
a second structure provided at one side in the stacking direction with respect to the first structure, the second structure including another part of the plurality of conductive layers and another part of the plurality of insulating layers alternately stacked in the stacking direction, and a second sub semiconductor column extending in the stacking direction, opposed to the another part of the plurality of conductive layers, and electrically connected to the first sub semiconductor column,
each of the first region and the second region includes:
a third structure including a part of the plurality of first layers corresponding to the part of the plurality of conductive layers and a part of the plurality of second layers corresponding to the part of the plurality of insulating layers; and
a fourth structure including another part of the plurality of first layers corresponding to the another part of the plurality of conductive layers and another part of the plurality of second layers corresponding to the another part of the plurality of insulating layers, and
each of the third structure and the fourth structure includes the plurality of first layers and the plurality of second layers divided in the first direction or the second direction between the first region and the second region and the plurality of first layers and the plurality of second layers continuing between the first region and the second region, among the plurality of first layers and the plurality of second layers.

11. The semiconductor device according to claim 9, wherein
each of the first plane region and the second plane region includes:
a first structure including a part of the plurality of conductive layers and a part of the plurality of insulating layers alternately stacked in the stacking direction, and a first sub semiconductor column extending in the stacking direction and opposed to the part of the plurality of conductive layers; and
a second structure provided at one side in the stacking direction with respect to the first structure, the second structure including another part of the plurality of conductive layers and another part of the plurality of insulating layers alternately stacked in the stacking direction, and a second sub semiconductor column extending in the stacking direction, opposed to the another part of the plurality of conductive layers, and electrically connected to the first sub semiconductor column,
each of the first region and the second region includes:
a third structure including a part of the plurality of first layers corresponding to the part of the plurality of conductive layers and a part of the plurality of second layers corresponding to the part of the plurality of insulating layers; and
a fourth structure including another part of the plurality of first layers corresponding to the another part of the plurality of conductive layers and another part of the plurality of second layers corresponding to the another part of the plurality of insulating layers, and
only one of the third structure and the fourth structure includes the plurality of first layers and the plurality of second layers continuing between the first region and the second region among the plurality of first layers and the plurality of second layers.

12. The semiconductor device according to claim 9, wherein
each of the first plane region and the second plane region includes:
a first structure including a part of the plurality of conductive layers and a part of the plurality of insulating layers alternately stacked in the stacking direction, and a first sub semiconductor column extending in the stacking direction and opposed to the part of the plurality of conductive layers; and
a second structure provided at one side in the stacking direction with respect to the first structure, the second structure including another part of the plurality of conductive layers and another part of the plurality of insulating layers alternately stacked in the stacking direction, and a second sub semiconductor column extending in the stacking direction, opposed to the another part of the plurality of conductive layers, and electrically connected to the first sub semiconductor column,
each of the first region and the second region includes:
a third structure including a part of the plurality of first layers corresponding to the part of the plurality of conductive layers and a part of the plurality of second layers corresponding to the part of the plurality of insulating layers; and
a fourth structure including another part of the plurality of first layers corresponding to the another part of the plurality of conductive layers and another part of the plurality of second layers corresponding to the another part of the plurality of insulating layers, and
only one of the third structure and the fourth structure includes the plurality of first layers and the plurality of second layers divided in the first direction or the second direction between the first region and the second region, among the plurality of first layers and the plurality of second layers.

13. A semiconductor device comprising:
a first wafer including a plurality of die regions arranged in a first direction and a second direction intersecting with the first direction;
a plurality of conductive layers and a plurality of insulating layers provided in a device region on the first wafer outside of a predetermined distance range from an outer edge of the first wafer, and alternately stacked in a stacking direction intersecting with the first direction and the second direction; and
a plurality of first layers and a plurality of second layers provided in an edge region on the first wafer within the predetermined distance range from the outer edge of the first wafer, the plurality of first layers being arranged in the stacking direction corresponding to the plurality of conductive layers, the plurality of second layers being arranged in the stacking direction corresponding to the plurality of insulating layers, wherein
each of a plurality of first die regions positioned within the device region among the plurality of die regions includes a first plane region and a second plane region arranged in the first direction or the second direction, each of the first plane region and the second plane region including a plurality of finger structures and a plurality of inter-finger structures alternately arranged in the second direction, and a source line provided at a position overlapping with the plurality of finger structures and the plurality of inter-finger structures when viewed in the stacking direction,
each of the plurality of finger structures includes the plurality of conductive layers and the plurality of insulating layers, and a plurality of semiconductor columns extending in the stacking direction, opposed to the plurality of conductive layers, and connected in common to the source line,
the plurality of conductive layers, the plurality of insulating layers, and the source line are divided in the first direction or the second direction between the first plane region and the second plane region,
respective positions within a plurality of second die regions among the plurality of die regions corresponding to positions at which the respective plurality of first die regions include the first plane region and the second plane region within a region in which the plurality of second die regions overlap with the edge region when viewed in the stacking direction are a first region and a second region,
the first region and the second region include the plurality of first layers and the plurality of second layers, respectively, and
at least a part of the plurality of first layers and the plurality of second layers continue between the first region and the second region.

14. The semiconductor device according to claim 13, wherein
each of the first plane region and the second plane region includes:
a first structure including a part of the plurality of conductive layers and a part of the plurality of insulating layers alternately stacked in the stacking direction, and a first sub semiconductor column extending in the stacking direction and opposed to the part of the plurality of conductive layers; and
a second structure provided at one side in the stacking direction with respect to the first structure, the second structure including another part of the plurality of conductive layers and another part of the plurality of insulating layers alternately stacked in the stacking direction, and a second sub semiconductor column extending in the stacking direction, opposed to the another part of the plurality of conductive layers, and electrically connected to the first sub semiconductor column,
each of the first region and the second region includes:
a third structure including a part of the plurality of first layers corresponding to the part of the plurality of conductive layers and a part of the plurality of second layers corresponding to the part of the plurality of insulating layers; and
a fourth structure including another part of the plurality of first layers corresponding to the another part of the plurality of conductive layers and another part of the plurality of second layers corresponding to the another part of the plurality of insulating layers, and
each of the third structure and the fourth structure includes the plurality of first layers and the plurality of second layers divided in the first direction or the second direction between the first region and the second region and the plurality of first layers and the plurality of second layers continuing between the first region and the second region, among the plurality of first layers and the plurality of second layers.

15. The semiconductor device according to claim 13, wherein
each of the first plane region and the second plane region includes:
a first structure including a part of the plurality of conductive layers and a part of the plurality of insulating layers alternately stacked in the stacking direction, and a first sub semiconductor column extending in the stacking direction and opposed to the part of the plurality of conductive layers; and
a second structure provided at one side in the stacking direction with respect to the first structure, the second structure including another part of the plurality of conductive layers and another part of the plurality of insulating layers alternately stacked in the stacking direction, and a second sub semiconductor column extending in the stacking direction, opposed to the another part of the plurality of conductive layers, and electrically connected to the first sub semiconductor column,
each of the first region and the second region includes:
a third structure including a part of the plurality of first layers corresponding to the part of the plurality of conductive layers and a part of the plurality of second layers corresponding to the part of the plurality of insulating layers; and
a fourth structure including another part of the plurality of first layers corresponding to the another part of the plurality of conductive layers and another part of the plurality of second layers corresponding to the another part of the plurality of insulating layers, and
only one of the third structure and the fourth structure includes the plurality of first layers and the plurality of second layers continuing between the first region and the second region among the plurality of first layers and the plurality of second layers.

16. The semiconductor device according to claim 13, wherein
each of the first plane region and the second plane region includes:
a first structure including a part of the plurality of conductive layers and a part of the plurality of insulating layers alternately stacked in the stacking direction, and a first sub semiconductor column extending in the stacking direction and opposed to the part of the plurality of conductive layers; and
a second structure provided at one side in the stacking direction with respect to the first structure, the second structure including another part of the plurality of conductive layers and another part of the plurality of insulating layers alternately stacked in the stacking direction, and a second sub semiconductor column extending in the stacking direction, opposed to the another part of the plurality of conductive layers, and electrically connected to the first sub semiconductor column,
each of the first region and the second region includes:
a third structure including a part of the plurality of first layers corresponding to the part of the plurality of conductive layers and a part of the plurality of second layers corresponding to the part of the plurality of insulating layers; and
a fourth structure including another part of the plurality of first layers corresponding to the another part of the plurality of conductive layers and another part of the plurality of second layers corresponding to the another part of the plurality of insulating layers, and
only one of the third structure and the fourth structure includes the plurality of first layers and the plurality of second layers divided in the first direction or the second direction between the first region and the second region among the plurality of first layers and the plurality of second layers.

17. The semiconductor device according to claim 13, wherein
each of the first plane region and the second plane region includes:
a first structure including a part of the plurality of conductive layers and a part of the plurality of insulating layers alternately stacked in the stacking direction, and a first sub semiconductor column extending in the stacking direction and opposed to the part of the plurality of conductive layers; and
a second structure provided at one side in the stacking direction with respect to the first structure, the second structure including another part of the plurality of conductive layers and another part of the plurality of insulating layers alternately stacked in the stacking direction, and a second sub semiconductor column extending in the stacking direction, opposed to the another part of the plurality of conductive layers, and electrically connected to the first sub semiconductor column,
each of the first region and the second region includes:
a third structure including a part of the plurality of first layers corresponding to the part of the plurality of conductive layers and a part of the plurality of second layers corresponding to the part of the plurality of insulating layers; and
a fourth structure including another part of the plurality of first layers corresponding to the another part of the plurality of conductive layers and another part of the plurality of second layers corresponding to the another part of the plurality of insulating layers,
one of the third structure and the fourth structure does not include the plurality of first layers and the plurality of second layers divided in the first direction or the second direction between the first region and the second region among the plurality of first layers and the plurality of second layers, and
the other one of the third structure and the fourth structure does not include the plurality of first layers and the plurality of second layers continuing between the first region and the second region among the plurality of first layers and the plurality of second layers.

18. The semiconductor device according to claim 13, wherein
the edge region includes:
a flat region provided outside of another predetermined distance range from the outer edge of the first wafer; and
a round region provided within the another predetermined distance range from the outer edge of the first wafer, and
the plurality of first layers and the plurality of second layers reach the round region.

19. The semiconductor device according to claim 13, wherein
the edge region includes:
a flat region provided outside of another predetermined distance range from the outer edge of the first wafer; and
a round region provided within the another predetermined distance range from the outer edge of the first wafer, and
the plurality of first layers and the plurality of second layers do not reach the round region.

20. The semiconductor device according to claim 13, wherein
the first wafer includes a plurality of first bonding electrodes, and
the device further comprises a second wafer including a plurality of second bonding electrodes bonded to the plurality of first bonding electrodes.
